(19) United States
(12) Patent Application Publication
(10) Pub. No.: US 2025/0386614 A1
(43) Pub. Date: Dec. 18, 2025

(54) SEMICONDUCTOR DEVICE AND ELECTRONIC DEVICE

(71) Applicant: SONY SEMICONDUCTOR SOLUTIONS CORPORATION, KANAGAWA (JP)

(72) Inventors: TATSUYA HORIKIRI, KANAGAWA (JP); YOSUKE FUJII, KANAGAWA (JP); TAKUHIRO MIYAWAKI, KANAGAWA (JP); SOTETSU SAITO, KANAGAWA (JP); MASANARI YAMAGUCHI, KANAGAWA (JP); YUKAKO MURAKAMI, KANAGAWA (JP); TAKASHI OINOUE, KANAGAWA (JP); NAOKI OGAWA; TATSUMASA HIRATSUKA, KANAGAWA (JP); TAKUMI ONODERA, KANAGAWA (JP); HOKUTO MIKI, KANAGAWA (JP); TAKAAKI HIRANO; YOICHI NEGORO, KANAGAWA (JP); ATSUSHI OKUYAMA

(21) Appl. No.: 18/878,642

(22) PCT Filed: Jun. 29, 2023
(86) PCT No.: PCT/JP2023/024297

§ 371 Date: Dec. 23, 2024

(30) Foreign Application Priority Data
Jun. 29, 2022 (JP) 2022-104297

(51) Int. Cl. H10F 39/00; H01L 23/00

(52) U.S. Cl. CPC H10F 39/811; H01L 23/562; H10F 39/028; H10F 39/809

(57) ABSTRACT

To improve a manufacturing yield. A semiconductor device includes: a base member having a first bonding surface; and a semiconductor chip having a second bonding surface having a quadrangular shape, and the second bonding surface of the semiconductor chip and the first bonding surface of the base member are bonded by direct bonding. Then, the semiconductor chip includes a multilayer wiring layer including the second bonding surface, and a semiconductor layer provided on an opposite side to a side of the second bonding surface of the multilayer wiring layer. Then, the multilayer wiring layer includes a warp suppression film that extends along at least one side of the second bonding surface and suppresses warp of the semiconductor chip.

### TECHNICAL FIELD

The present technology (technology according to the present disclosure) relates to a semiconductor device and an electronic device, and particularly relates to a technology effective when applied to a semiconductor device having a semiconductor chip directly bonded to a base member, and an electronic device including the semiconductor device.

### BACKGROUND ART

As a semiconductor device, a photodetection device such as a solid-state imaging device or a distance measuring device is known. In this photodetection device, a three-dimensional structure is adopted in order to realize miniaturization and high density of pixels. As a method for realizing a three-dimensional structure, a method of directly bonding two semiconductor wafers is known.

Meanwhile, Patent Document 1 discloses a technique for suppressing a warp due to bonding of substrates.

### CITATION LIST

### Patent Document

Patent Document 1: Japanese Patent Application Laid-Open No. 2016-001681

### SUMMARY OF THE INVENTION

### Problems to be Solved by the Invention

By the way, as a method of realizing a three-dimensional structure, a method of directly bonding a rectangular semiconductor chip to a base member (bonding member) such as a semiconductor wafer or a semiconductor chip (chip bonding method) is also known. In this chip bonding method, an outer peripheral edge portion of the semiconductor chip may float from the base member due to the warp of the semiconductor chip, and defects such as cracking and chipping of the semiconductor chip easily occur, which causes a decrease in manufacturing yield of the semiconductor device.

In particular, to reduce the thickness of the semiconductor device, thickness of a substrate of the semiconductor chip may be reduced after the semiconductor chip is directly bonded to the base member. In such a case, rigidity of the semiconductor chip becomes weak, and floating of the semiconductor chip easily occurs.

An object of the present technology is to improve a manufacturing yield.

### Solutions to Problems

(1) A semiconductor device according to an aspect of the present technology includes a base member having a first bonding surface, and a semiconductor chip having a second bonding surface having a quadrangular shape.

Then, the second bonding surface of the semiconductor chip and the first bonding surface of the base member are bonded by direct bonding.

Then, the semiconductor chip includes a multilayer wiring layer including the second bonding surface, and a semiconductor layer provided on an opposite side to a side of the second bonding surface of the multilayer wiring layer.

Then, the multilayer wiring layer includes a warp suppression film that extends along at least one side of the second bonding surface and suppresses warp of the semiconductor chip.
(2) A semiconductor device according to another aspect of the present technology includes:
a base member having a first bonding surface; and
a semiconductor chip having a second bonding surface having a quadrangular shape, the second bonding surface being directly bonded to the first bonding surface of the base member, in which
the semiconductor chip includes
a multilayer wiring layer including the second bonding surface,
a semiconductor layer provided on an opposite side to a side of the second bonding surface of the multilayer wiring layer, and
a warp suppression portion that is provided in the multilayer wiring layer and suppresses warp of the semiconductor chip, and
the warp suppression portion is selectively provided on a peripheral edge portion side of the second bonding surface in plan view.
(3) A semiconductor device according to another aspect of the present technology includes:
a base member having a first bonding surface; and
a semiconductor chip having a second bonding surface having a quadrangular shape, the second bonding surface being directly bonded to the first bonding surface of the base member, in which
the semiconductor chip includes
a multilayer wiring layer including the second bonding surface,
a semiconductor layer provided on an opposite side to a side of the second bonding surface of the multilayer wiring layer, and having, on an opposite side to a side of the multilayer wiring layer, a back surface having a quadrangular shape, and
a warp suppression portion that is provided in the semiconductor layer and suppresses warp of the semiconductor chip, and
the warp suppression portion is selectively provided on a peripheral edge portion side of the back surface of the semiconductor layer in plan view.
(4) A semiconductor device according to another aspect of the present technology includes:
a base member having a first bonding surface; and
a semiconductor chip having a second bonding surface having a quadrangular shape, the second bonding surface being directly bonded to the first bonding surface of the base member, in which
the semiconductor chip includes
a multilayer wiring layer including the second bonding surface, and
a semiconductor layer provided on an opposite side to a side of the second bonding surface of the multilayer wiring layer,
the second bonding surface includes an insulating layer included in the multilayer wiring layer and a weak bonding portion having weaker bonding force with the first bonding surface than the insulating layer, and
the weak bonding portion is provided on a peripheral edge portion side of the second bonding surface.
(5)
A semiconductor device according to another aspect of the present technology includes:
a base member having a first bonding surface having a quadrangular shape; and
a semiconductor chip having a second bonding surface having a quadrangular shape, the second bonding surface being directly bonded to the first bonding surface of the base member, in which
at least one bonding surface of the first bonding surface or the second bonding surface includes a weak bonding region and a strong bonding region having bonding forces relatively different from the other bonding surfaces, and the one weak bonding region is provided in the one bonding surface on a peripheral edge portion side.
(6) An electronic device according to another aspect of the present technology includes the semiconductor device, an optical system that forms an image of image light from a subject on the semiconductor device, and a signal processing circuit that performs signal processing for a signal output from the semiconductor device.

### BRIEF DESCRIPTION OF DRAWINGS

FIG. 1 is a block diagram illustrating a configuration example of a solid-state imaging device according to a first embodiment of the present technology.

FIG. 2 is an equivalent circuit diagram illustrating a configuration example of a pixel and a pixel circuit of the solid-state imaging device according to the first embodiment of the present technology.

FIG. 3 is a plan layout diagram schematically illustrating a configuration example of a solid-state imaging device according to a first embodiment of the present technology.

FIG. 4 is a longitudinal cross-sectional view schematically illustrating a longitudinal cross-sectional structure taken along cutting line a3-a3 in FIG. 1.

FIG. 5 is a developed view of FIG. 4.

FIG. 6 is a bottom view schematically illustrating a bottom surface side of the solid-state imaging device in FIG. 3.

FIG. 7 is a plan view schematically illustrating a state in which a second semiconductor chip is bonded to a first semiconductor chip when viewed from the second semiconductor chip side, with illustration of a sealing body omitted.

FIG. 8 is a longitudinal cross-sectional view schematically illustrating a longitudinal cross-sectional structure taken along cutting line a7-a7 in FIG. 7.

FIG. 9 is a longitudinal cross-sectional view schematically illustrating a longitudinal cross-sectional structure taken along cutting line b7-b7 in FIG. 7.

FIG. 10 is a plan view schematically illustrating a bonding surface side of the first semiconductor chip.

FIG. 11 is a plan view schematically illustrating a bonding surface side of the second semiconductor chip.

FIG. 12A is a longitudinal cross-sectional view schematically illustrating a longitudinal cross-sectional structure taken along cutting line all-all in FIG. 11.

FIG. 12B is a partially enlarged longitudinal cross-sectional view of FIG. 12A.

FIG. 13 is a longitudinal cross-sectional view schematically illustrating a longitudinal cross-sectional structure taken along cutting line b11-b11 in FIG. 11.

FIG. 14 is a plan view schematically illustrating a semiconductor wafer for describing a method of manufacturing the second semiconductor chip included in the solid-state imaging device according to the first embodiment of the present technology.

FIG. 15 is a view illustrating a configuration of a chip formation region by enlarging a region A in FIG. 14.

FIG. 16 is a longitudinal cross-sectional view schematically illustrating a longitudinal cross-sectional structure taken along cutting line a15-a15 in FIG. 15.

FIG. 17 is a plan view schematically illustrating a state in which a dicing process is performed for the semiconductor wafer in the method of manufacturing the second semiconductor chip.

FIG. 18 is a longitudinal cross-sectional view schematically illustrating a longitudinal cross-sectional structure taken along cutting line a17-a17 in FIG. 17.

FIG. 19 is a longitudinal cross-sectional view schematically illustrating a state in which a ring CMP process is performed in the method of manufacturing the second semiconductor chip.

FIG. 20 is process cross-sectional views schematically illustrating formation of a warp suppression film and a bonding metal pad in the method of manufacturing the second semiconductor chip.

FIG. 21 is process cross-sectional views schematically illustrating formation of a warp suppression film and a bonding metal pad in the method of manufacturing the second semiconductor chip.

FIG. 22 is a plan view schematically illustrating a wafer stacked body for describing a method of manufacturing the first semiconductor chip included in the solid-state imaging device according to the first embodiment of the present technology.

FIG. 23 is a longitudinal cross-sectional view schematically illustrating a longitudinal cross-sectional structure of the wafer stacked body in FIG. 22.

FIG. 24 is a view illustrating a configuration of a chip formation region by enlarging a region B in FIG. 22.

FIG. 25 is a plan view schematically illustrating a process of the method of manufacturing the solid-state imaging device according to the first embodiment of the present technology.

FIG. 26 is a longitudinal cross-sectional view schematically illustrating a longitudinal cross-sectional structure taken along cutting line a25-a25 in FIG. 25.

FIG. 27 is a plan view schematically illustrating a process subsequent to FIG. 25.

FIG. 28 is a longitudinal cross-sectional view schematically illustrating a longitudinal cross-sectional structure taken along cutting line a27-a27 in FIG. 27.

FIG. 29 is a partially enlarged longitudinal cross-sectional view of FIG. 28.

FIG. 30 is a longitudinal cross-sectional view schematically illustrating a process subsequent to FIG. 27.

FIG. 31 is a plan view schematically illustrating a process subsequent to FIG. 27.

FIG. 32 is a longitudinal cross-sectional view schematically illustrating a longitudinal cross-sectional structure taken along cutting line a31-a31 in FIG. 31.

FIG. 33 is a longitudinal cross-sectional view schematically illustrating a process subsequent to FIG. 31.

FIG. 34 is a plan view schematically illustrating a process subsequent to FIG. 33.

FIG. 35 is a plan view schematically illustrating a configuration of a second semiconductor chip according to Modification 1-1 of the first embodiment of the present technology.

FIG. 36 is a plan view schematically illustrating a configuration of a second semiconductor chip according to Modification 1-2 of the first embodiment of the present technology.

FIG. 37 is a plan view schematically illustrating a configuration of a second semiconductor chip according to Modification 1-3 of the first embodiment of the present technology.

FIG. 38 is a plan view schematically illustrating a configuration of a second semiconductor chip according to Modification 1-4 of the first embodiment of the present technology.

FIG. 39 is a plan view schematically illustrating a configuration of a second semiconductor chip according to Modification 1-5 of the first embodiment of the present technology.

FIG. 40 is a plan view schematically illustrating a configuration of a second semiconductor chip according to Modification 1-6 of the first embodiment of the present technology.

FIG. 41 is a plan view schematically illustrating a configuration of a second semiconductor chip according to Modification 1-7 of the first embodiment of the present technology.

FIG. 42 is a plan view schematically illustrating a configuration of a second semiconductor chip according to Modification 1-8 of the first embodiment of the present technology.

FIG. 43 is a plan view schematically illustrating a configuration of a second semiconductor chip according to Modification 1-9 of the first embodiment of the present technology.

FIG. 44 is a plan view schematically illustrating a configuration of a second semiconductor chip according to Modification 1-10 of the first embodiment of the present technology.

FIG. 45 is a view schematically illustrating a film state of a warp suppression film according to Modification 1-11 of the first embodiment of the present technology.

FIG. 46 is a view schematically illustrating a film state of a warp suppression film according to Modification 1-12 of the first embodiment of the present technology.

FIG. 47 is a view schematically illustrating a film state of a warp suppression film according to Modification 1-13 of the first embodiment of the present technology.

FIG. 48 is a view schematically illustrating a film state of a warp suppression film according to Modification 1-14 of the first embodiment of the present technology.

FIG. 49 is a plan view schematically illustrating a configuration of a second semiconductor chip according to Modification 1-15 of the first embodiment of the present technology.

FIG. 50 is a plan view schematically illustrating a configuration of a second semiconductor chip according to Modification 1-16 of the first embodiment of the present technology.

FIG. 51 is a plan view of a main part schematically illustrating a configuration of the second semiconductor chip according to Modification 1-17 of the first embodiment of the present technology.

FIG. 52 is a plan view schematically illustrating a configuration of a second semiconductor chip according to Modification 1-18 of the first embodiment of the present technology.

FIG. 53 is cross-sectional views schematically illustrating a configuration of a second semiconductor chip according to Modification 1-18 of the first embodiment of the present technology (FIG. 53(a) is a longitudinal cross-sectional view schematically illustrating a longitudinal cross-sectional structure taken along cutting line a52-a52 in FIG. 52, and FIG. 53(b) is a longitudinal cross-sectional view schematically illustrating a longitudinal cross-sectional structure taken along cutting line b52-b52 in FIG. 52).

FIG. 54 is a longitudinal cross-sectional view schematically illustrating a longitudinal cross-sectional structure at the same position as cutting line b52-b52 illustrated in FIG. 52 in a second semiconductor chip according to Modification 1-19 of the first embodiment of the present technology.

FIG. 55 is a plan view of a main part schematically illustrating a configuration example of a solid-state imaging device according to a second embodiment of the present technology.

FIG. 56 is a longitudinal cross-sectional view schematically illustrating a longitudinal cross-sectional structure taken along cutting line a55-a55 in FIG. 55.

FIG. 57 is a plan view schematically illustrating a bonding surface side of the second semiconductor chip.

FIG. 58A is a longitudinal cross-sectional view schematically illustrating a longitudinal cross-sectional structure taken along cutting line a57-a57 in FIG. 57.

FIG. 58B is a partially enlarged longitudinal cross-sectional view of FIG. 58A.

FIG. 59 is a plan view schematically illustrating a planar shape of a warp suppression film provided in an inner layer of a multilayer wiring layer of a second semiconductor chip.

FIG. 60A is a plan view schematically illustrating a planar pattern of a warp suppression film provided in a bonding surface of a multilayer wiring layer in a second semiconductor chip according to Modification 2-1 of the second embodiment of the present technology.

FIG. 60B is a plan view schematically illustrating a planar pattern of the warp suppression film provided in an inner layer of the multilayer wiring layer in the second semiconductor chip according to Modification 2-1 of the second embodiment of the present technology.

FIG. 61A is a plan view schematically illustrating a planar pattern of a warp suppression film provided in a bonding surface of a multilayer wiring layer in a second semiconductor chip according to Modification 2-2 of the second embodiment of the present technology.

FIG. 61B is a plan view schematically illustrating a planar pattern of the warp suppression film provided in an inner layer of the multilayer wiring layer in the second semiconductor chip according to Modification 2-2 of the second embodiment of the present technology.

FIG. 62 is a plan view of a main part schematically illustrating a configuration example of a solid-state imaging device according to a third embodiment of the present technology.

FIG. 63 is a longitudinal cross-sectional view schematically illustrating a longitudinal cross-sectional structure taken along cutting line a62-a62 in FIG. 62.

FIG. 64 is a plan view schematically illustrating a bonding surface side of the second semiconductor chip.

FIG. 65A is a longitudinal cross-sectional view schematically illustrating a longitudinal cross-sectional structure taken along cutting line a62-a62 in FIG. 62.

FIG. 65B is a partially enlarged longitudinal cross-sectional view of FIG. 65A.

FIG. 66 is a longitudinal cross-sectional view schematically illustrating a longitudinal cross-sectional structure of the second semiconductor chip according to Modification 3-1 of the third embodiment of the present technology.

FIG. 67 is a longitudinal cross-sectional view schematically illustrating a configuration example of a solid-state imaging device according to a fourth embodiment of the present technology.

FIG. 68 is a plan view schematically illustrating a bonding surface side of the second semiconductor chip.

FIG. 69 is a plan view schematically illustrating a bonding surface side of the first semiconductor chip.

FIG. 70 is a plan view of a main part schematically illustrating a configuration example of a solid-state imaging device according to a fifth embodiment of the present technology.

FIG. 71 is a longitudinal cross-sectional view schematically illustrating a longitudinal cross-sectional structure taken along cutting line a70-a70 in FIG. 70.

FIG. 72 is a longitudinal cross-sectional view schematically illustrating a longitudinal cross-sectional structure taken along cutting line b70-b70 in FIG. 70.

FIG. 73 is a longitudinal cross-sectional view schematically illustrating a longitudinal cross-sectional structure of a solid-state imaging device according to Modification 5-1 of the fifth embodiment of the present technology.

FIG. 74 is a plan view of a main part schematically illustrating a configuration example of a solid-state imaging device according to a sixth embodiment of the present technology.

FIG. 75 is a longitudinal cross-sectional view schematically illustrating a longitudinal cross-sectional structure taken along cutting line a75-a75 in FIG. 75.

FIG. 76 is a longitudinal cross-sectional view schematically illustrating a longitudinal cross-sectional structure taken along cutting line b75-b75 in FIG. 75.

FIG. 77A is a plan view of a main part schematically illustrating a configuration example of the solid-state imaging device according to Modification 6-1 of the sixth embodiment of the present technology.

FIG. 77B is a longitudinal cross-sectional view schematically illustrating a longitudinal cross-sectional structure taken along cutting line b77-b77 in FIG. 77A.

FIG. 78A is a plan view of a main part schematically illustrating a configuration example of the solid-state imaging device according to Modification 6-2 of the sixth embodiment of the present technology.

FIG. 78B is a longitudinal cross-sectional view schematically illustrating a longitudinal cross-sectional structure taken along cutting line a78-a78 in FIG. 78A.

FIG. 78C is a longitudinal cross-sectional view schematically illustrating a longitudinal cross-sectional structure taken along cutting line b78-b78 in FIG. 78A.

FIG. 79A is a plan view of a main part schematically illustrating a configuration example of the solid-state imaging device according to Modification 6-3 of the sixth embodiment of the present technology.

FIG. 79B is a longitudinal cross-sectional view schematically illustrating a longitudinal cross-sectional structure taken along cutting line b79-b79 in FIG. 79A.

FIG. 80A is a plan view of a main part schematically illustrating a configuration example of the solid-state imaging device according to Modification 6-4 of the sixth embodiment of the present technology.

FIG. 80B is a longitudinal cross-sectional view schematically illustrating a longitudinal cross-sectional structure taken along cutting line b80-b80 in FIG. 80A.

FIG. 81A is a plan view of a main part schematically illustrating a configuration example of the solid-state imaging device according to Modification 6-5 of the sixth embodiment of the present technology.

FIG. 81B is a longitudinal cross-sectional view schematically illustrating a longitudinal cross-sectional structure taken along cutting line a81-a81 in FIG. 81A.

FIG. 82 is a plan view of a main part schematically illustrating a configuration example of a solid-state imaging device according to a seventh embodiment of the present technology.

FIG. 83 is a longitudinal cross-sectional view schematically illustrating a longitudinal cross-sectional structure taken along cutting line a82-a782 in FIG. 82.

FIG. 84 is a plan view schematically illustrating a bonding surface side of the second semiconductor chip.

FIG. 85A is a plan view schematically illustrating a bonding surface side of a second semiconductor chip according to Modification 7-1 of the seventh embodiment of the present technology.

FIG. 85B is a longitudinal cross-sectional view schematically illustrating a configuration example of a solid-state imaging device according to Modification 7-2 of the seventh embodiment of the present technology.

FIG. 86 is a plan view of a main part schematically illustrating a configuration example of a solid-state imaging device according to an eighth embodiment of the present technology.

FIG. 87A is a longitudinal cross-sectional view schematically illustrating a longitudinal cross-sectional structure taken along cutting line a86a-a86a in FIG. 86.

FIG. 87B is a longitudinal cross-sectional view schematically illustrating a longitudinal cross-sectional structure taken along cutting line a86b-a86b in FIG. 86.

FIG. 88 is a plan view schematically illustrating a bonding surface side of the second semiconductor chip.

FIG. 89 is a longitudinal cross-sectional view schematically illustrating a configuration example of a solid-state imaging device according to Modification 8-1 of the eighth embodiment of the present technology.

FIG. 90 is a plan view of a main part schematically illustrating a configuration example of a solid-state imaging device according to a ninth embodiment of the present technology.

FIG. 91A is a longitudinal cross-sectional view schematically illustrating a longitudinal cross-sectional structure taken along cutting line a90a-a90a in FIG. 90.

FIG. 91B is a longitudinal cross-sectional view schematically illustrating a longitudinal cross-sectional structure taken along cutting line a90b-a90b in FIG. 90.

FIG. 92 is a plan view schematically illustrating a bonding surface side of the second semiconductor chip.

FIG. 93 is a plan view of a main part schematically illustrating a configuration example of a solid-state imaging device according to a tenth embodiment of the present technology.

FIG. 94 is a longitudinal cross-sectional view schematically illustrating a longitudinal cross-sectional structure taken along cutting line a93-a93 in FIG. 93.

FIG. 95 is a plan view schematically illustrating a bonding surface side of the second semiconductor chip.

FIG. 96 is a longitudinal cross-sectional view schematically illustrating a longitudinal cross-sectional structure taken along cutting line b95-b95 in FIG. 95.

FIG. 97 is a plan view schematically illustrating a bonding surface side of the first semiconductor chip.

FIG. 98 is diagrams illustrating types of arrangement patterns of weak bonding regions in Modification 10-1 of the tenth embodiment of the present technology.

FIG. 99 is longitudinal cross-sectional views schematically illustrating Modification 10-2 of the tenth embodiment of the present technology.

FIG. 100 is longitudinal cross-sectional views schematically illustrating Modification 10-3 of the tenth embodiment of the present technology.

FIG. 101 is a longitudinal cross-sectional view schematically illustrating Modification 10-4 of the tenth embodiment of the present technology.

FIG. 102 is a longitudinal cross-sectional view schematically illustrating Modification 10-5 of the tenth embodiment of the present technology.

FIG. 103 is a longitudinal cross-sectional view schematically illustrating Modification 10-6 of the tenth embodiment of the present technology.

FIG. 104 is a longitudinal cross-sectional view schematically illustrating Modification 10-7 of the tenth embodiment of the present technology.

FIG. 105 is a longitudinal cross-sectional view schematically illustrating Modification 10-8 of the tenth embodiment of the present technology.

FIG. 106 is a longitudinal cross-sectional view schematically illustrating Modification 10-9 of the tenth embodiment of the present technology.

FIG. 107 is a longitudinal cross-sectional view schematically illustrating Modification 10-10 of the tenth embodiment of the present technology.

FIG. 108 is a longitudinal cross-sectional view schematically illustrating Modification 10-11 of the tenth embodiment of the present technology.

FIG. 109 is a longitudinal cross-sectional view schematically illustrating Modification 10-12 of the tenth embodiment of the present technology.

FIG. 110 is a longitudinal cross-sectional view schematically illustrating Modification 10-13 of the tenth embodiment of the present technology.

FIG. 111 is a longitudinal cross-sectional view schematically illustrating Modification 10-14 of the tenth embodiment of the present technology.

FIG. 112 is a longitudinal cross-sectional view schematically illustrating Modification 10-15 of the tenth embodiment of the present technology.

FIG. 113 is a longitudinal cross-sectional view schematically illustrating Modification 10-16 of the tenth embodiment of the present technology.

FIG. 114 is a longitudinal cross-sectional view schematically illustrating Modification 10-17 of the tenth embodiment of the present technology.

FIG. 115 is a diagram illustrating a schematic configuration of an electronic device according to an eleventh embodiment of the present technology.

### MODE FOR CARRYING OUT THE INVENTION

Hereinafter, embodiments of the present technology will be described in detail with reference to the drawings.

Note that, in illustration of the drawings to be referred to in the following description, the same or similar portions are denoted by the same or similar reference signs. It should be noted that the drawings are schematic, and a relationship between a thickness and a planar dimension, a ratio of the thicknesses between layers, and the like are different from actual ones. Therefore, specific thicknesses and dimensions should be determined in consideration of the following description.

Furthermore, it goes without saying that dimensional relationships and ratios are partly different between the drawings. Furthermore, the effects described herein are merely examples and are not limited, and other effects may be provided.

Furthermore, the following embodiments illustrate a device and a method for embodying the technical idea of the present technology, and do not specify the configuration as follows. That is, various modifications can be made to the technical idea of the present technology within the technical scope described in the claims.

In addition, the definitions of directions such as up and down in the following description are merely defined for convenience of description, and do not limit the technical idea of the present technology. It is obvious that, for example, when an object is rotated by 90° and observed, the vertical direction is converted and read as the horizontal direction, and when an object is rotated by 180° and observed, the top side is read as the bottom side, and the bottom side is read as the top side.

Furthermore, in the following embodiments, a case will be exemplarily described where a first conductivity type is p-type and a second conductivity type is n-type, but the relationship between the conductivity types may be inversed, that is, the first conductivity type may be n-type and the second conductivity type may be p-type.

Furthermore, in the following embodiments, in three directions orthogonal to each other in a space, a first direction and a second direction orthogonal to each other in the same plane are defined as an X direction and a Y direction, respectively, and a third direction orthogonal to the first direction and the second direction is defined as a Z direction. Then, in the following embodiments, a thickness direction of a first semiconductor chip 20 and a second semiconductor chip 40 to be described below will be described as a Z direction.

### First Embodiment

In a first embodiment, an example where the present technology is applied to a solid-state imaging device 1A that is called back-illuminated complementary metal-oxide-semiconductor (CMOS) image sensor will be described as a semiconductor device.

Furthermore, in the first embodiment, an example in which a warp suppression film is provided in a multilayer wiring layer of a second semiconductor chip as a warp suppression portion that suppresses warp of the second semiconductor chip will be described.

### «Overall Configuration of Solid-state Imaging Device»

First, an overall configuration of a solid-state imaging device 1A will be described.

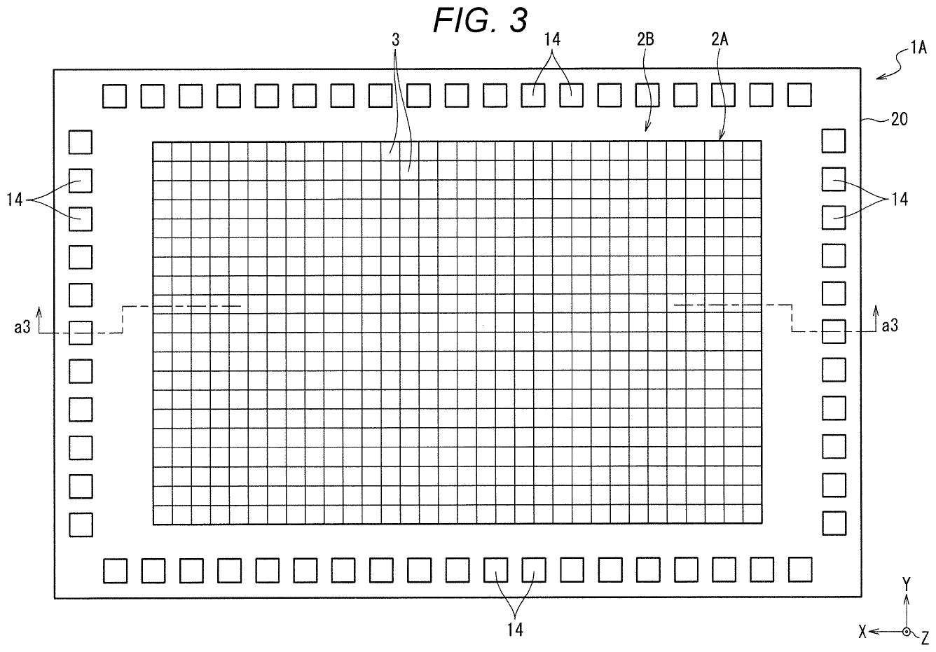

As illustrated in FIGS. 3 to 6, the solid-state imaging device 1A according to the first embodiment of the present technology includes a first semiconductor chip 20 having a bonding surface 20a as an example of a base member, and a second semiconductor chip 40 having a quadrangular bonding surface 40a. Then, the bonding surface 20a of the first semiconductor chip 20 and the bonding surface 40a of the second semiconductor chip 40 are bonded by direct bonding.

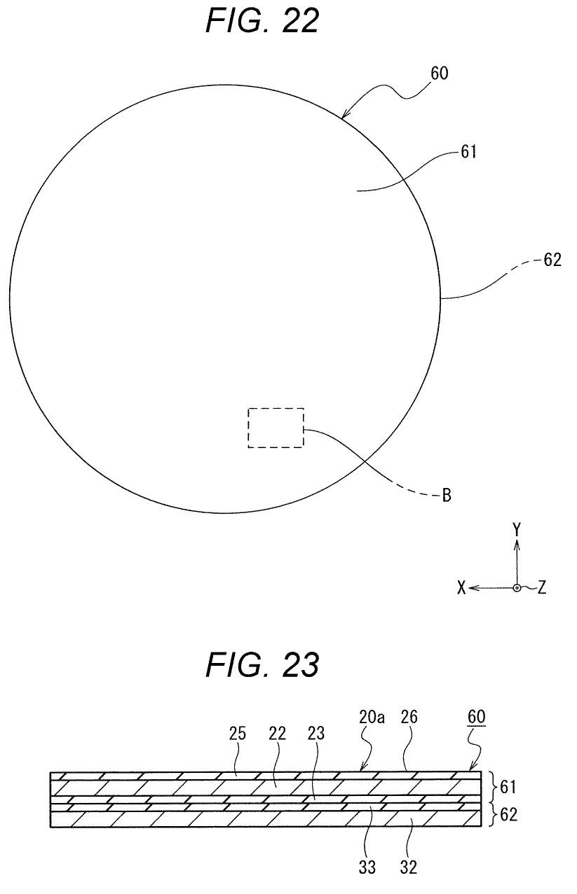

In the first embodiment, two second semiconductor chips 40 and 40 having a planar size smaller than the planar size of the first semiconductor chip 20 are provided although not limited thereto. The two second semiconductor chips 40 are disposed apart from each other in a two-dimensional plane of the first semiconductor chip 20. Each of the first semiconductor chip 20 and the second semiconductor chip 40 has a quadrangular two-dimensional planar shape in plan view. As the direct bonding of the second semiconductor chip 40, for example, surface activation bonding can be used. The direct bonding of the second semiconductor chip 40 is performed in a state of a wafer stacked body 60 before the first semiconductor chip 20 is formed (see FIGS. 22 and 23), the wafer stack body 60 being obtained by dividing a chip formation region 65 (see FIG. 24) into small pieces.

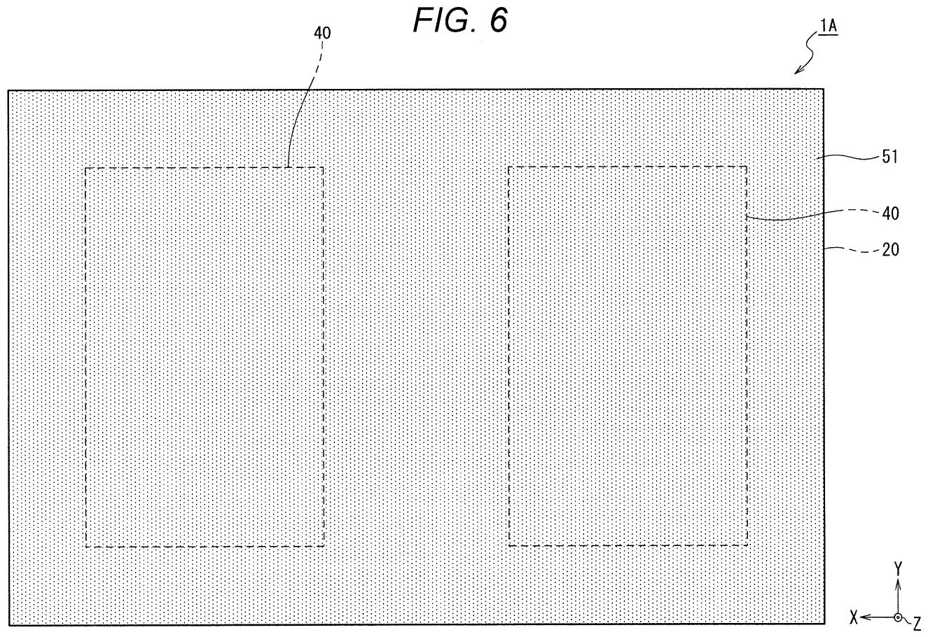

Furthermore, the solid-state imaging device 1A according to the first embodiment of the present technology further includes a sealing body 51 provided on a side of the bonding surface 20a of the first semiconductor chip 20 so as to cover the second semiconductor chip 40. As the sealing body 51, for example, an epoxy-based thermosetting insulating resin or a polyimide-based thermoplastic insulating resin can be used. As illustrated in FIG. 6, the sealing body 51 has a quadrangular planar shape in plan view, and has a rectangular shape similar to the first semiconductor chip 20 in the first embodiment, for example.

Here, in the first embodiment, the first semiconductor chip 20 corresponds to a specific example of a “base member” of the present technology. Furthermore, the second semiconductor chip 40 corresponds to a specific example of a “semiconductor chip” of the present technology.

Furthermore, the bonding surface 20a of the first semiconductor chip 20 corresponds to a specific example of a “first bonding surface” of the present technology, and the bonding surface 40a of the second semiconductor chip 40 corresponds to a specific example of a “second bonding surface” of the present technology.

Furthermore, the plan view refers to a case of being viewed from a direction along a thickness direction (Z direction) of the semiconductor chips 20 and 40. Furthermore, a cross-sectional view refers to a case where a cross section along the thickness direction (Z direction) of the semiconductor chips 20 and 40 is viewed from a direction (X direction or Y direction) orthogonal to the thickness direction (Z direction) of the semiconductor chips 20 and 40.

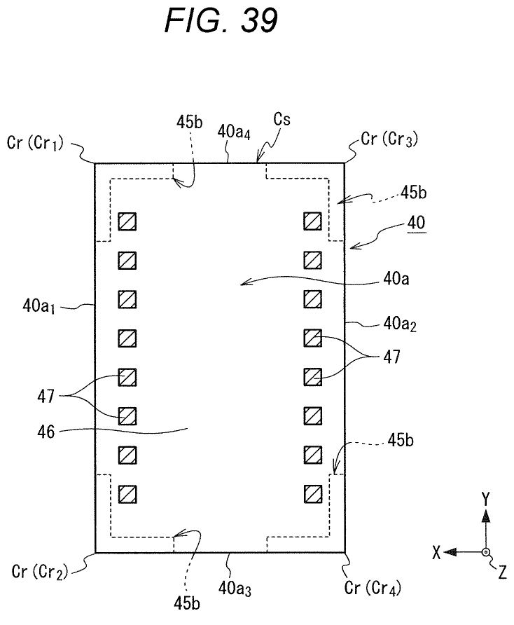

As illustrated in FIG. 39, the solid-state imaging device 1A (101) according to the first embodiment receives image light (incident light 106) from a subject through an optical lens 102, converts an amount of the incident light 106 formed as an image on an imaging surface into an electrical signal for each pixel, and outputs the electrical signal as a pixel signal (image signal).

As illustrated in FIG. 3, the first semiconductor chip 20 includes, in a two-dimensional plane including the X direction and the Y direction orthogonal to each other, a quadrangular pixel array unit 2A provided in a central portion, and a peripheral portion 2B provided outside the pixel array unit 2A so as to surround the pixel array unit 2A.

The pixel array unit 2A is, for example, a light receiving surface that receives light condensed by the optical lens (optical system) 102 illustrated in FIG. 39. Then, in the pixel array unit 2A, a plurality of pixels 3 is arranged in a matrix in the two-dimensional plane including the X direction and the Y direction. In other words, the pixels 3 are repeatedly arranged in the X direction and the Y direction orthogonal to each other in the two-dimensional plane.

As illustrated in FIG. 3, a plurality of bonding pads 14 is arranged in the peripheral portion 2B. Each bonding pad of the plurality of bonding pads 14 is disposed along each of four sides of the two-dimensional plane of the first semiconductor chip 20, for example. Each of the plurality of bonding pads 14 functions as an input/output terminal that electrically connects the first semiconductor chip 20 and an external device to each other.

### <Logic Circuit>

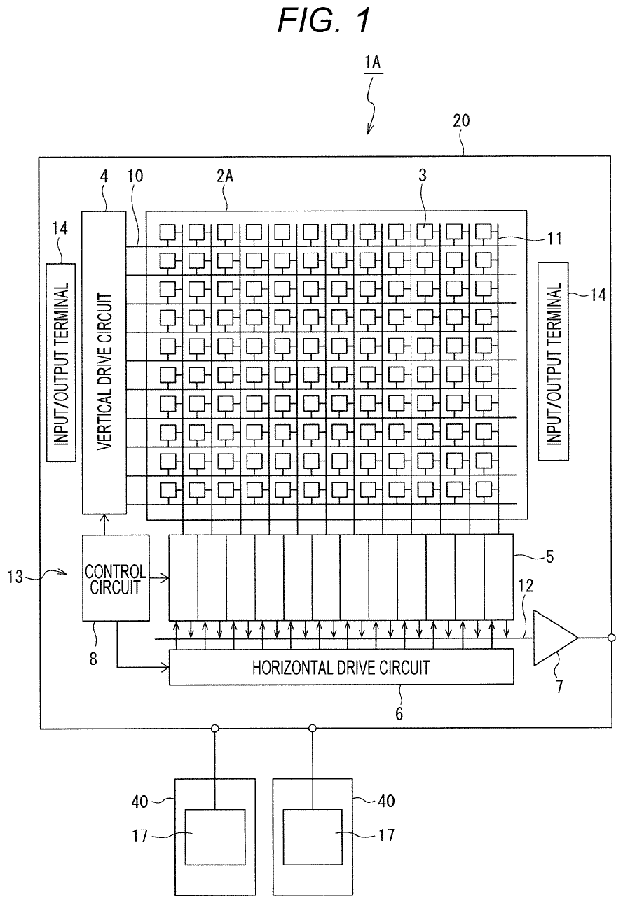

The first semiconductor chip 20 includes a logic circuit 13 illustrated in FIG. 1. As illustrated in FIG. 1, the logic circuit 13 includes a vertical drive circuit 4, column signal processing circuits 5, a horizontal drive circuit 6, an output circuit 7, a control circuit 8, and the like. The logic circuit 13 includes, for example, a complementary MOS (CMOS) circuit including an n-channel conductive metal oxide semiconductor field effect transistor (MOSFET) and a p-channel conductive MOSFET as field effect transistors.

The vertical drive circuit 4 includes a shift register, for example. The vertical drive circuit 4 sequentially selects desired pixel drive lines 10 and supplies pulses for driving the pixels 3 to the selected pixel drive line 10 to drive the individual pixels 3 on a row-by-row basis. That is, the vertical drive circuit 4 selectively scans the individual pixels 3 in the pixel array unit 2A sequentially in a vertical direction on a row-by-row basis and supplies a pixel signal from each of the pixels 3 based on signal charge generated by a photoelectric conversion unit (photoelectric conversion element) of the pixel 3 in accordance with the amount of light received to the column signal processing circuit 5 through a vertical signal line 11.

The column signal processing circuit 5 is disposed for each column of the pixels 3, for example, and performs, for each pixel column, signal processing such as noise removal for the signals output from the pixels 3 of one row. For example, the column signal processing circuit 5 performs the signal processing such as correlated double sampling (CDS) for removing pixel-specific fixed pattern noise, and analog-to-digital (AD) conversion.

The horizontal drive circuit 6 includes a shift register, for example. The horizontal drive circuit 6 sequentially outputs horizontal scanning pulses to the column signal processing circuits 5 to sequentially select the column signal processing circuits 5 in order, and causes each of the column signal processing circuits 5 to output the pixel signal for which the signal processing has been performed to a horizontal signal line 12.

The output circuit 7 performs signal processing for the pixel signals sequentially supplied from the individual column signal processing circuits 5 through the horizontal signal line 12, and outputs the pixel signals. As the signal processing, buffering, black level adjustment, column variation correction, various types of digital signal processing, and the like can be used, for example.

The control circuit 8 generates a clock signal and a control signal that are references for operations of the vertical drive circuit 4, the column signal processing circuits 5, the horizontal drive circuit 6, and the like, on the basis of a vertical synchronization signal, a horizontal synchronization signal, and a master clock signal. Then, the control circuit 8 then outputs the generated clock signal and control signal to the vertical drive circuit 4, the column signal processing circuits 5, the horizontal drive circuit 6, and the like.

### <Circuit Configuration of Pixels>

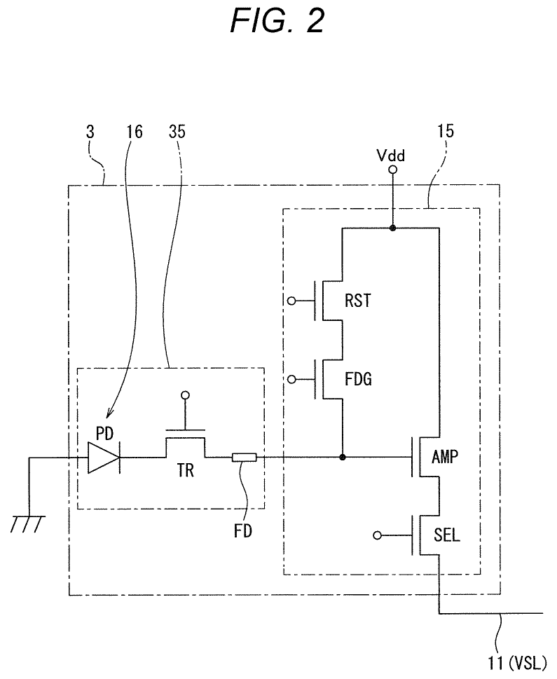

As illustrated in FIG. 2, each of the plurality of pixels 3 includes a photoelectric conversion region 35 and a pixel circuit (readout circuit) 15. The photoelectric conversion region 35 includes a photoelectric conversion unit 16, a transfer transistor TR, and a charge holding region (floating diffusion) FD. The pixel circuit 15 is electrically connected to the charge holding region FD of the photoelectric conversion region 35. The first embodiment has, as an example, a circuit configuration where one pixel circuit 15 is allocated to one pixel 3, but the circuit configuration is not limited thereto, and a circuit configuration where one pixel circuit 15 is shared by a plurality of pixels 3 may be employed. For example, a circuit configuration where one pixel circuit 15 is shared by four pixels 3 (one pixel block) arranged in a 2×2 layout, that is, two pixels 3 are arranged in the X direction and two pixels 3 are arranged in the Y direction, may be employed.

The photoelectric conversion unit 16 illustrated in FIG. 2 includes, for example, a pn junction photodiode (PD), and generates a signal charge in accordance with the amount of light received. The photoelectric conversion unit 16 has a cathode side electrically connected to a source region of the transfer transistor TR and an anode side electrically connected to a reference potential line (e.g., ground).

The transfer transistor TR illustrated in FIG. 2 transfers the signal charge generated by the photoelectric conversion by the photoelectric conversion unit 16 to the charge holding region FD. The source region of the transfer transistor TR is electrically connected to the cathode side of the photoelectric conversion unit 16, and a drain region of the transfer transistor TR is electrically connected to the charge holding region FD. Then, a gate electrode of the transfer transistor TR is electrically connected to a transfer transistor drive line among the pixel drive lines 10 (see FIG. 1).

The charge holding region FD illustrated in FIG. 2 temporarily holds (accumulates) the signal charge transferred from the photoelectric conversion unit 16 via the transfer transistor TR.

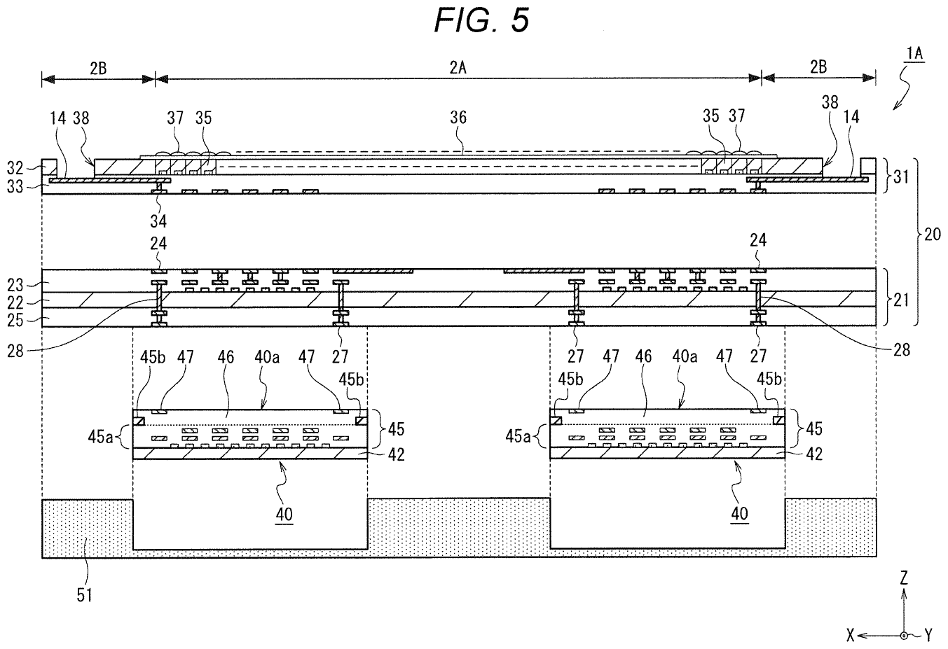

The photoelectric conversion region 35 including the photoelectric conversion unit 16, the transfer transistor TR, and the charge holding region FD is provided in a semiconductor layer 32 (see FIG. 5) to be described below. Furthermore, for example, pixel transistors (AMP, SEL, RST, FDG) included in the pixel circuit 15 are also provided in the semiconductor layer 32, but are not limited to such a configuration.

The pixel circuit 15 illustrated in FIG. 2 reads the signal charge held in the charge holding region FD, converts the read signal charge into a pixel signal, and outputs the pixel signal. In other words, the pixel circuit 15 converts the photoelectrically converted signal charge generated by the photoelectric conversion unit 16 (photoelectric conversion element PD) into the pixel signal based on the signal charge and outputs the pixel signal. The pixel circuit 15 includes, but not limited to, an amplification transistor AMP, a selection transistor SEL, a reset transistor RST, and a switching transistor FDG as the pixel transistors, for example. Such pixel transistors (AMP, SEL, RST, and FDG) and the above-described transfer transistor TR are each includes, for example, a MOSFET as a field effect transistor. Alternatively, these transistors may be MISFETs.

Among the pixel transistors included in the pixel circuit 15, each of the selection transistor SEL, the reset transistor RST, and the switching transistor FDG functions as a switching element, and the amplification transistor AMP functions as an amplification element.

As illustrated in FIG. 2, the amplification transistor AMP has a source region electrically connected to a drain region of the selection transistor SEL and a drain region electrically connected to a power supply line Vdd and a drain region of the reset transistor RST. Then, a gate electrode of the amplification transistor AMP is electrically connected to the charge holding region FD and a source region of the switching transistor FDG.

The selection transistor SEL has a source region electrically connected to the vertical signal line 11 (VSL), and the drain region electrically connected to the source region of the amplification transistor AMP. Furthermore, a gate electrode of the selection transistor SEL is electrically connected to a selection transistor drive line among the pixel drive lines 10 (see FIG. 1).

The reset transistor RST has a source region electrically connected to a drain region of the switching transistor FDG and the drain region electrically connected to the power supply line Vdd and the drain region of the amplification transistor AMP. Then, a gate electrode of the reset transistor RST is electrically connected to a reset transistor drive line among the pixel drive lines 10 (see FIG. 1).

The switching transistor FDG has a source region electrically connected to the charge holding region FD and the gate electrode of the amplification transistor AMP and the drain region electrically connected to the power supply line Vdd and the drain region of the amplification transistor AMP. Further, a gate electrode of the switching transistor FDG is electrically connected to a switching transistor drive line of the pixel drive line 10 (see FIG. 1).

Note that the selection transistor SEL and the switching transistor FDG may be omitted as necessary. Note that in a case where the selection transistor SEL is omitted, the source region of the amplification transistor AMP is electrically connected to the vertical signal line 11 (VSL). Furthermore, in a case where the switching transistor FDG is omitted, the source region of the reset transistor RST is electrically connected to the gate electrode of the amplification transistor AMP and the charge holding region FD.

When the transfer transistor TR illustrated in FIG. 2 is turned on, the transfer transistor TR transfers the signal charge generated by the photoelectric conversion unit 16 to the charge holding region FD.

When the reset transistor RST illustrated in FIG. 2 is turned on, the reset transistor RST resets a potential (signal charge) of the charge holding region FD to the potential of the power supply line Vdd. The selection transistor SEL controls output timing of the pixel signal from the pixel circuit 15.

The amplification transistor AMP generates a signal of a voltage corresponding to a level of the signal charge held in the charge holding region FD as the pixel signal. The amplification transistor AMP constitutes a source follower amplifier and outputs the pixel signal of the voltage corresponding to the level of the signal charge generated by the photoelectric conversion unit 16. When the selection transistor SEL is turned on, the amplification transistor AMP amplifies the potential of the charge holding region FD, and outputs the voltage corresponding to the potential to the column signal processing circuit 5 via the vertical signal line (VSL) 11.

The switching transistor FDG illustrated in FIG. 2 controls charge holding of the charge holding region FD and adjusts an amplification factor of the voltage according to the potential amplified by the amplification transistors AMP.

As will be described with reference to FIG. 2, during the operation of the solid-state imaging device 1A according to the first embodiment, the signal charge generated in the photoelectric conversion unit 16 of the pixel 3 is held (accumulated) in the charge holding region FD via the transfer transistor TR of the pixel 3. Then, the signal charge held in the charge holding region FD is read out by the pixel circuit 15 and applied to the gate electrode of the amplification transistor AMP of the pixel circuit 15. A vertical shift register supplies a horizontal line selection control signal to the gate electrode of the selection transistor SEL of the pixel circuit 15. Then, setting the selection control signal to a high (H) level brings the selection transistor SEL into conduction to allow a current corresponding to the potential of the charge holding region FD, which has been amplified by the amplification transistor AMP, to flow in the vertical signal line 11. Furthermore, setting a reset control signal to be applied to the gate electrode of the reset transistor RST of the pixel circuit 15 to the high (H) level brings the reset transistor RST into conduction to reset the signal charge accumulated in the charge holding region FD.

As illustrated in FIG. 1, the second semiconductor chip 40 includes an internal circuit 17 electrically connected to the logic circuit 13 of the first semiconductor chip 20. Examples of the internal circuit 17 include a storage circuit such as a DRAM or a flash memory, and a control circuit.

### «Specific Configuration of Solid-State Imaging Device»

Next, a specific configuration of the solid-state imaging device 1A will be described with reference to FIGS. 3 to 13.

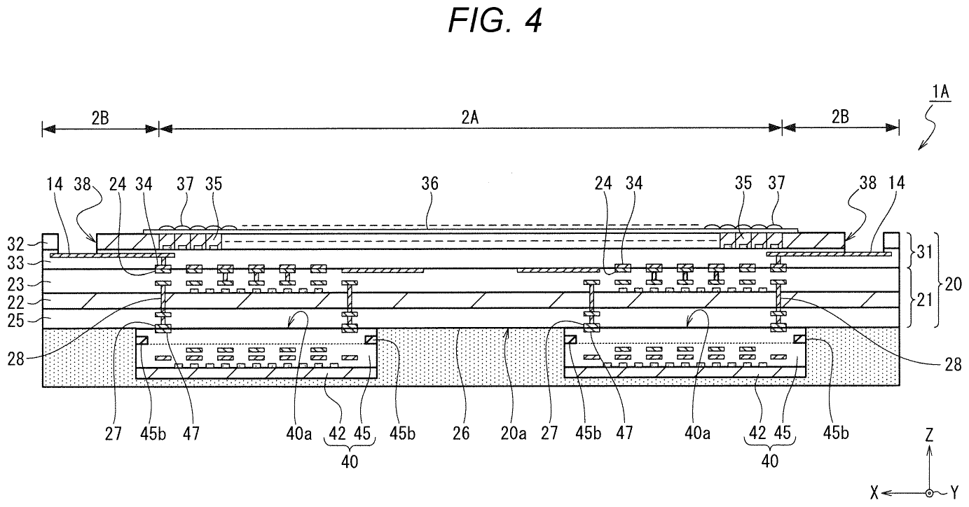

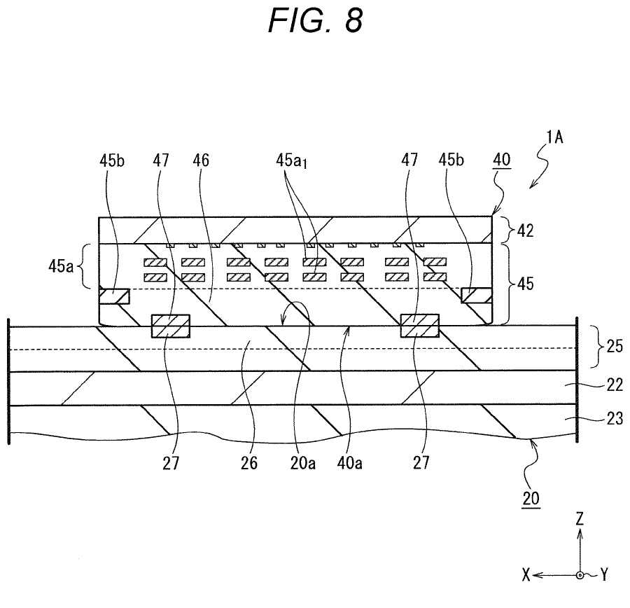

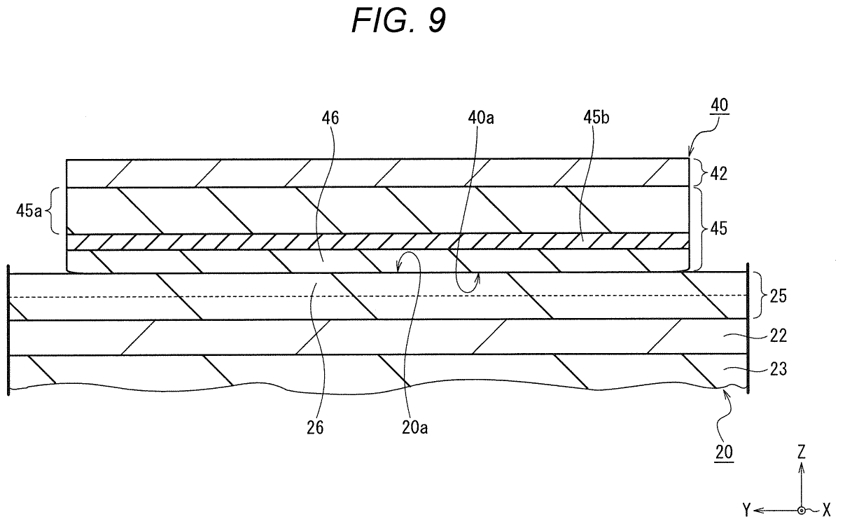

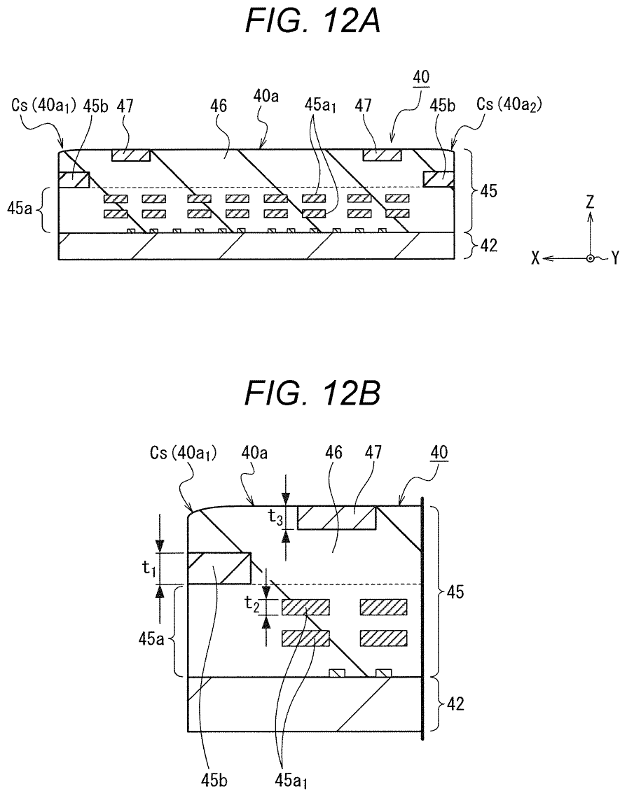

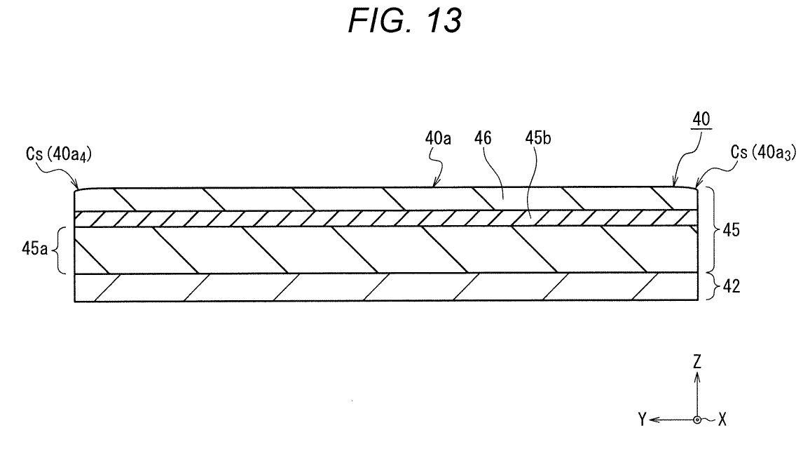

Note that FIGS. 8 and 9 are vertically inverted from FIGS. 4 and 5. Furthermore, FIGS. 12A, 12B, and 13 are vertically inverted from FIGS. 8 and 9.

As illustrated in FIGS. 3 to 6, the solid-state imaging device 1A has a chip stacked structure in which the first semiconductor chip 20 and the second semiconductor chip 40 are stacked in a state where bonding surfaces thereof face each other. That is, the solid-state imaging device 1A includes a chip stacked body including the first semiconductor chip 20 and the second semiconductor chip 40.

### <First Semiconductor Chip>

As illustrated in FIGS. 4 and 5, the first semiconductor chip 20 includes a first substrate unit 21 and a second substrate unit 31 that are stacked to face each other in the thickness direction (Z direction) of the substrate units. The first substrate unit 21 is provided with the logic circuit 13 and the like described above. The second substrate unit 31 is provided with the pixel array unit 2A, the peripheral portion 2B, the pixel transistors included in the pixel circuit 15, the bonding pads 14, and the like described above. Each of the first substrate unit 21 and the second substrate unit 31 can also be expressed as a semiconductor chip.

### <Second Substrate Unit>

As illustrated in FIGS. 4 and 5, the second substrate unit 31 includes the semiconductor layer 32 having a first surface (element formation surface or main surface) and a second surface (light incident surface or back surface) located on opposite sides to each other in the thickness direction (Z), and a multilayer wiring layer 33 provided on a first surface side of the semiconductor layer 32. Furthermore, the second substrate unit 31 includes an optical filter layer 36 and a microlens 37 provided in order from a side of the semiconductor layer 32 on the light incident surface side (second surface side) of the semiconductor layer 32 on an opposite side to a side of the multilayer wiring layer 33 (first surface side). As illustrated in FIGS. 3 and 6, the first semiconductor chip 20 has a quadrangular planar shape in plan view, and is formed in a rectangular shape, for example, in the first embodiment.

### <Semiconductor Layer>

As illustrated in FIGS. 4 and 5, the semiconductor layer 32 two-dimensionally extends over the pixel array unit 2A and the peripheral portion 2B, and overlaps with the pixel array unit 2A and the peripheral portion 2B in plan view. As the semiconductor layer 32, a Si substrate, a SiGe substrate, an InGaAs substrate, or the like may be used. Although not limited to this configuration, in the first embodiment, a semiconductor substrate is used for the semiconductor layer 32, in which silicon (Si) is used as a semiconductor material, for example, single crystal is adopted as crystallinity, for example, and a p-type is adopted as a conductivity type, for example.

As illustrated in FIGS. 4 and 5, the above-described photoelectric conversion region 35 is provided in the semiconductor layer 32. Although not illustrated in detail, the photoelectric conversion region 35 is repeatedly arranged for each pixel 3 in each of the X direction and the Y direction orthogonal to each other in a two-dimensional plane, for example. Furthermore, as described with reference to FIG. 3, the charge holding region FD that holds the signal charge photoelectrically converted by the photoelectric conversion unit 16 and the transfer transistor TR that transfers the signal charge photoelectrically converted by the photoelectric conversion unit 16 to the charge holding region are provided in a surface layer portion of the semiconductor layer 32 on the opposite side to the multilayer wiring layer 33 side. The photoelectric conversion unit 16, the charge holding region FD, and the transfer transistor TR are provided in the semiconductor layer 32 for each pixel 3 (photoelectric conversion region 35).

### <Multilayer Wiring Layer>

Although not illustrated in detail, as described with reference to FIGS. 4 and 5, the multilayer wiring layer 33 has a stacked structure in which the insulating layer and the wiring layer are alternately stacked in a plurality of stages. Then, the multilayer wiring layer 33 includes wiring provided in each wiring layer and a bonding metal pad 34. As a material of the insulating layer, for example, silicon oxide (SiO₂) can be used. As a material of the wiring layer and the bonding metal pad 34, for example, a metal such as aluminum (Al) or copper (Cu), an alloy mainly containing Al or Cu, or the like can be used.

The wiring provided in the uppermost wiring layer of the multilayer wiring layer 33 is covered with the uppermost insulating layer. The bonding metal pad 34 is provided on a surface layer portion of the multilayer wiring layer 33 on the opposite side to the semiconductor layer 32 side, and is provided in the insulating layer in a state where a surface is exposed from the uppermost insulating layer. The bonding metal pad 34 is electrically connected to wiring in a layer lower than the bonding metal pad 34. Then, the wiring in the lower layer is electrically connected to the charge holding region FD and the transfer transistor TR.

### <Optical Filter Layer and Microlens>

The optical filter layer 36 separates color of incident light incident from a light incident surface side (back surface side) of the first semiconductor chip 20. The optical filter layer 36 includes, for example, a red (R) first color filter, a green (G) second color filter, and a blue (B) third color filter.

The microlens 37 is provided for each photoelectric conversion region 35 on the optical filter layer 36 on the opposite side (light incident surface side) to the semiconductor layer 32 side. The microlens 37 condenses irradiation light and allows the condensed light to efficiently enter the photoelectric conversion unit 16.

### <First Substrate Unit>

As illustrated in FIGS. 4 and 5, the first substrate unit 21 includes a semiconductor layer 22 having a first surface (element formation surface) and a second surface (back surface) located on opposite sides in the thickness direction (Z direction), a multilayer wiring layer 23 provided on the first surface side of the semiconductor layer 22, and a multilayer wiring layer 25 provided on the second surface side of the semiconductor layer 22.

### <Semiconductor Layer>

The semiconductor layer 22 two-dimensionally extends over the pixel array unit 2A and the peripheral portion 2B, and overlaps with the pixel array unit 2A and the peripheral portion 2B in plan view. As the semiconductor layer 22, a Si substrate, a SiGe substrate, an InGaAs substrate, or the like may be used. Although not limited to this configuration, in the first embodiment, a semiconductor substrate is used for the semiconductor layer 22, in which silicon (Si) is used as a semiconductor material, for example, single crystal is adopted as crystallinity, for example, and a p-type is adopted as a conductivity type, for example.

Although not illustrated in detail in FIGS. 4 and 5, for example, a metal oxide semiconductor field effect transistor (MOSFET) is provided on the first surface (element shape surface) of the semiconductor layer 22 as a transistor element constituting the logic circuit 13 (see FIG. 1).

### <Multilayer Wiring Layer>

Although not illustrated in detail, the multilayer wiring layer 23 has a stacked structure in which an insulating layer and a wiring layer are alternately stacked in a plurality of stages. Then, the multilayer wiring layer 23 includes wiring provided in each wiring layer and a bonding metal pad 24. As a material of the insulating layer, for example, silicon oxide (SiO₂) can be used. As a material of the wiring layer and the bonding metal pad 24, for example, a metal such as aluminum (Al) or copper (Cu), an alloy mainly containing Al or Cu, or the like can be used.

The wiring provided in the uppermost wiring layer of the multilayer wiring layer 23 is covered with the uppermost insulating layer. The bonding metal pad 24 is provided on a surface layer portion of the multilayer wiring layer 23 on the opposite side to a side of the semiconductor layer 22, and a surface of the bonding metal pad 24 is exposed from the uppermost insulating layer. The bonding metal pad 24 is electrically connected to wiring in a layer lower than the bonding metal pad 24.

### <Multilayer Wiring Layer>

Although not illustrated in detail, the multilayer wiring layer 25 has a stacked structure in which an insulating layer and a wiring layer are alternately stacked in a plurality of stages. Then, the multilayer wiring layer 25 includes wiring provided in each wiring layer and a bonding metal pad 27. As a material of the insulating layer, for example, silicon oxide (SiO₂) can be used. As a material of the wiring layer and the bonding metal pad 27, for example, a metal such as aluminum (Al) or copper (Cu), an alloy mainly containing Al or Cu, or the like can be used.

The wiring provided in the uppermost wiring layer of the multilayer wiring layer 25 is covered with an uppermost insulating layer 26 (see FIGS. 8 and 9) of the multilayer wiring layer 25. Then, the bonding metal pad 27 is provided on a surface layer portion of the multilayer wiring layer 25 on the opposite side to the semiconductor layer 22 side, and is provided in the insulating layer 26 in a state where a surface is exposed from the uppermost insulating layer 26. The bonding metal pad 27 is electrically connected to wiring in a layer lower than the bonding metal pad 27.

The wiring of the multilayer wiring layer 25 is electrically connected to the wiring of the multilayer wiring layer 23 via a contact electrode 28 illustrated in FIGS. 4 and 5. The contact electrode 28 penetrates the semiconductor layer 22 in the thickness direction of the semiconductor layer 22 and extends over the multilayer wiring layer 23, the semiconductor layer 22, and the multilayer wiring layer 25. As a material of the contact electrode 28, for example, a high melting point metal such as titanium (Ti) or tungsten (W) can be used.

### <Bonding Pad and Bonding Opening>

As illustrated in FIGS. 4 and 5, the bonding pad 14 is provided in the multilayer wiring layer 33 on the semiconductor layer 32 side. Specifically, the bonding pad 14 is provided in, for example, in the first wiring layer of the multilayer wiring layer 33.

As illustrated in FIGS. 4 and 5, the first semiconductor chip 20 is provided with a bonding opening 38 that exposes the surface of the bonding pad 14. The bonding opening 38 penetrates the semiconductor layer 32 in the thickness direction (Z direction) of the semiconductor layer 32 and extends over the semiconductor layer 32 and the multilayer wiring layer 33. Connection members such as a bonding wire and a bump electrode are electrically and mechanically connected to the bonding pad 14 through the bonding opening 38.

### <Bonding Between First Substrate Unit and Second Substrate Unit>

As illustrated in FIGS. 4 and 5, in the first substrate unit 21, the bonding metal pad 24 is provided in the surface layer portion of the multilayer wiring layer 23 on the opposite side to the semiconductor layer 22 side. The bonding metal pad 24 is provided in the uppermost insulating layer of the multilayer wiring layer 23 in a state where a bonding surface is exposed.

As described above, in the second substrate unit 31, the bonding metal pad 34 is provided in the surface layer portion of the multilayer wiring layer 33 on the opposite side to the semiconductor layer 32 side. The bonding metal pad 34 is provided in the uppermost insulating layer of the multilayer wiring layer 33 in a state where a bonding surface is exposed.

Then, the bonding metal pad 24 of the 1 substrate unit 21 and the bonding metal pad 34 of the second substrate unit 31 are electrically and mechanically connected by metal-to-metal bonding with their respective bonding surfaces facing each other. Then, the metal-to-metal bonding between the bonding metal pad 24 and the bonding metal pad 34 makes the wiring of the multilayer wiring layer 23 of the first substrate unit 21 and the wiring of the multilayer wiring layer 33 of the second substrate unit 31 electrically conducted.

The bonding metal pad 24 of the first substrate unit 21 and the bonding metal pad 34 of the second substrate unit 31 are bonded to each other by direct bonding at their bonding surfaces. Furthermore, the uppermost insulating layer of the multilayer wiring layer of the first substrate unit 21 and the uppermost insulating layer of the multilayer wiring layer of the second substrate unit 31 are bonded to each other by direct bonding at their bonding surfaces. As the direct bonding, for example, surface activation bonding can be used.

### <Bonding Surface of First Semiconductor Chip>

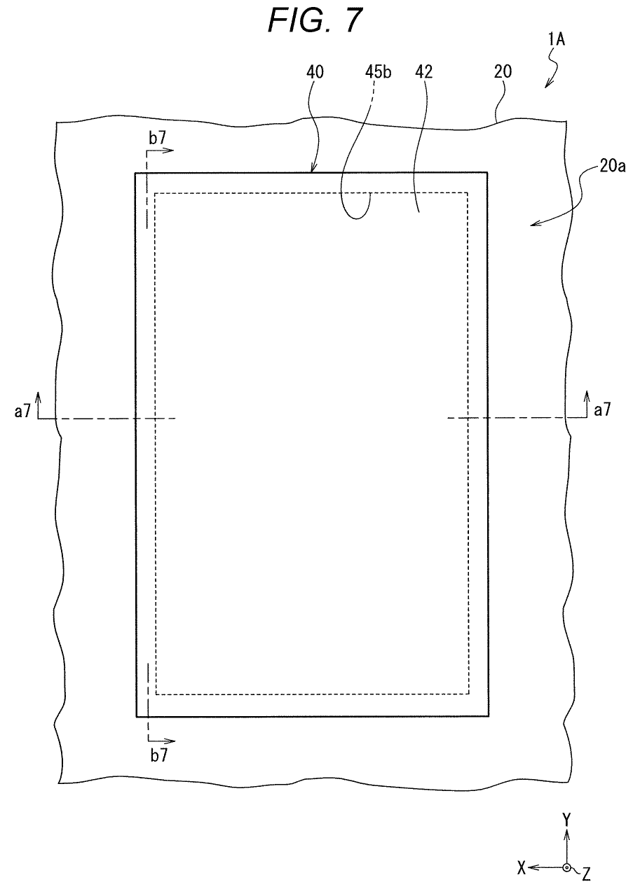

As illustrated in FIGS. 4 and 5, the bonding surface 20a of the first semiconductor chip 20 is provided on the multilayer wiring layer 25 on a side of the insulating layer 26. Then, as illustrated in FIGS. 7 to 10, the bonding surface 20a of the first semiconductor chip 20 includes the insulating layer 26 located in the uppermost layer of the multilayer wiring layer 25 of the first semiconductor chip 20, and further includes the bonding metal pads 27 interspersed with the insulating layer 26.

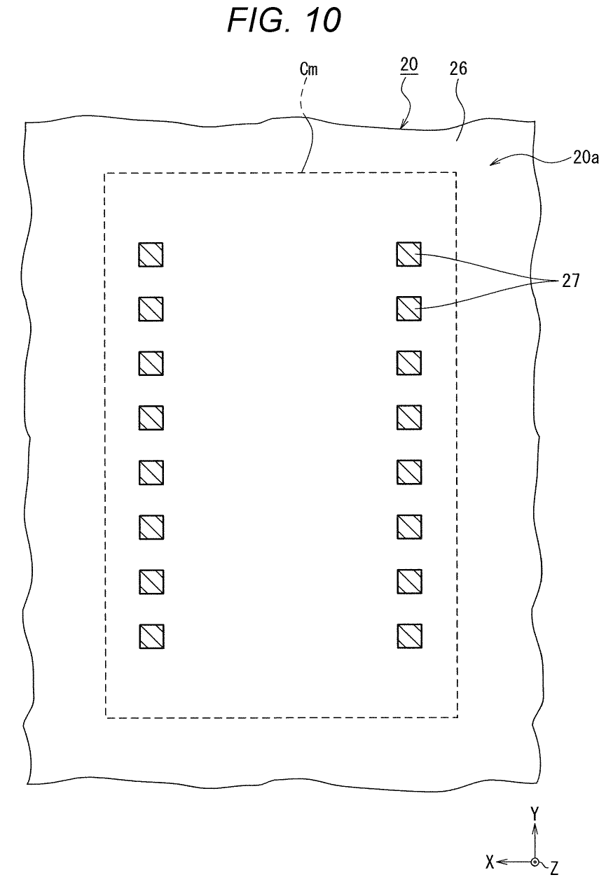

As illustrated in FIG. 10, the bonding metal pads 27 are interspersed with a chip mounting region Cm of the bonding surface 20a. Then, the second semiconductor chip 40 is mounted on the chip mounting region Cm, and the bonding surface 40a of the second semiconductor chip 40 is directly bonded.

Here, in the first embodiment, the insulating layer 26 of the multilayer wiring layer 25 corresponds to a specific example of a “first insulating layer” of the present technology, and the bonding metal pad 27 of the multilayer wiring layer 25 corresponds to a specific example of a “first bonding metal pad” of the present technology.

### <Second Semiconductor Chip>

As illustrated in FIGS. 4 and 5, each of the two second semiconductor chips 40 includes a semiconductor layer 42 having the first surface (element formation surface or main surface) and the second surface (back surface) located on opposite sides to each other in the thickness direction (Z), and a multilayer wiring layer 45 provided on the first surface side of the semiconductor layer 42. That is, each of the two second semiconductor chips 40 includes the multilayer wiring layer 45 including the second bonding surface 40a, and the semiconductor layer 42 provided on the multilayer wiring layer 45 on the opposite side to the second bonding surface 40a side.

### <Semiconductor Layer>

As the semiconductor layer 42, a Si substrate, a SiGe substrate, an InGaAs substrate, or the like may be used. Although not limited to this configuration, in the first embodiment, a semiconductor substrate is used for the semiconductor layer 42, in which silicon (Si) is used as a semiconductor material, for example, single crystal is adopted as crystallinity, for example, and a p-type is adopted as a conductivity type, for example.

For example, a metal oxide semiconductor field effect transistor (MOSFET) is provided on the first surface (element formation surface) of the semiconductor layer 42 as a transistor element constituting the internal circuit 17 (see FIG. 2).

### <Multilayer Wiring Layer>

As illustrated in FIGS. 8 and 9, the multilayer wiring layer 45 includes a multistage stacked portion 45a in which an insulating layer and a wiring layer are alternately stacked in a plurality of stages, and a warp suppression film 45b provided as a warp suppression portion on the multistage stacked portion 45a on the opposite side to a side of the semiconductor layer 42. Furthermore, the multilayer wiring layer 45 includes the insulating layer 46 provided on the multistage stacked portion 45a on the opposite side to the semiconductor layer 42 side so as to cover the warp suppression film 45b, and the bonding metal pad 47 provided interspersed with a surface layer portion of the insulating layer 46 on the opposite side to a side of the multistage stacked portion 45a and having a surface exposed from the insulating layer 46. The insulating layer 46 is the uppermost insulating layer of the multilayer wiring layer 45, and the surface of the insulating layer 46 is the bonding surface 40a of the second semiconductor chip 40. That is, the bonding surface 40a of the second semiconductor chip 40 includes the uppermost insulating layer 46 of the multilayer wiring layer 45 and the bonding metal pads 47 interspersed with the insulating layer 46. The bonding metal pad 47 is provided in the insulating layer 46 of the multilayer wiring layer 45 in a state where the bonding surface is exposed. Then, the bonding surface 40a is substantially flat where a step between the bonding metal pad 47 and the insulating layer 46 is as small as possible.

As a material of the insulating layer and the uppermost insulating layer 46 of the multistage stacked portion 45a, for example, a silicon oxide (SiO₂) film can be used. Furthermore, as a material of the wiring layer and the bonding metal pad 47 of the multistage stacked portion 45a, for example, a metal such as aluminum (Al) or copper (Cu), an alloy mainly containing Al or Cu, or the like can be used.

The bonding metal pad 47 is electrically connected to wiring in a layer lower than the bonding metal pad 47. Then, the wiring in the lower layer is electrically connected to the transistor provided on the first surface side of the semiconductor layer 42.

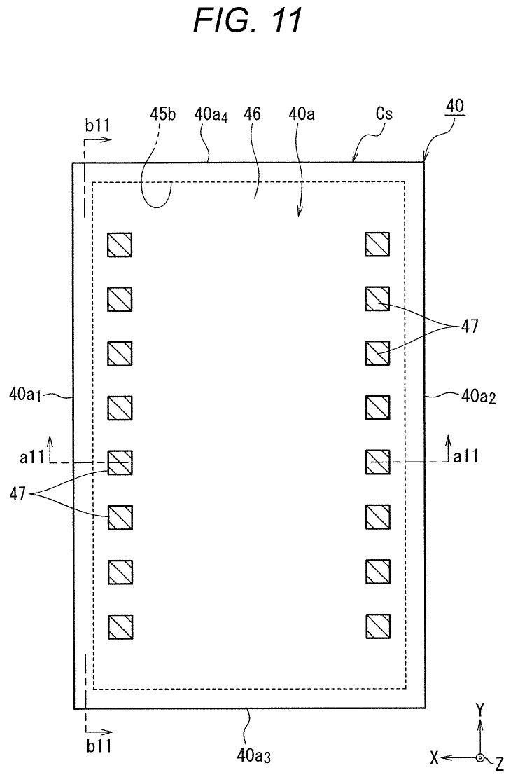

As illustrated in FIG. 11, the second semiconductor chip 40 has a quadrangular planar shape in plan view, and is formed in a rectangular shape, for example, in the first embodiment. As illustrated in FIG. 11, the bonding surface 40a of the second semiconductor chip 40 also has a rectangular shape as an example of the quadrangular shape.

### <Bonding Surface and Warp Suppression Film of Second Semiconductor Chip>

Next, the bonding surface 40a and the warp suppression film 45b of the second semiconductor chip 40 will be described with reference to FIGS. 11 to 13.

FIGS. 11, 12A, 12B, and 13 illustrate a state before the second semiconductor chip 40 is directly bonded to a wafer stacked body to be described below. Furthermore, since the first semiconductor chip 20 is formed by dividing the chip formation region 65 of the wafer stacked body 60 to be described below into small pieces, the description may be given where the “wafer stacked body” is replaced with a “second semiconductor chip” for convenience.

As illustrated in FIGS. 11 to 13, the bonding surface 40a of the second semiconductor chip 40 is provided on the multilayer wiring layer 45 on a side of the insulating layer 46. As illustrated in FIG. 11, the bonding surface 40a has two sides 40a1 and 40a2 located on opposite sides to each other in the X direction and two sides 40a3 and 40a4 located on opposite sides to each other in the Y direction. The two sides 40a1 and 40a2 extend in the Y direction. The two sides 40a3 and 40a4 extend in the X direction.

Here, the two sides 40a1 and 40a2 may be referred to as long sides. Furthermore, the two sides 40a3 and 40a4 may be referred to as short sides.

As illustrated in FIGS. 11 to 13, the second semiconductor chip 40 has a peripheral edge portion Cs including the four sides 40a1, 40a2, 40a3, and 40a4 of the bonding surface 40a. Then, the peripheral edge portion Cs has a curved surface shape that curves over the bonding surface 40a and a side surface of the second semiconductor chip 40. The curved peripheral edge portion Cs is formed by performing ring CMP for the bonding surface 40a of the second semiconductor chip 40 in a process of manufacturing the second semiconductor chip 40 to be described below.

As illustrated in FIG. 11, the warp suppression film 45b of the multilayer wiring layer 45 extends along at least one side of the bonding surface 40a of the second semiconductor chip 40. In the first embodiment, as illustrated in FIG. 11, the warp suppression film 45b is provided in the bonding surface 40a of the second semiconductor chip 40 on sides of the four sides (40a1, 40a2, 40a3, and 40a4), and has an annular planar pattern continuously extending along the four sides (40a1, 40a2, 40a3, and 40a4). The warp suppression film 45b overlaps with the sides (40a1, 40a2, 40a3, and 40a4) of the bonding surface 40a of the second semiconductor chip 40 in plan view, and is exposed from the side surface of the second semiconductor chip 40.

The warp suppression film 45b is disposed in an outer peripheral edge portion of the second semiconductor chip 40 (on a side of the peripheral edge portion Cs), thereby controlling local film stress of the second semiconductor chip 40 and suppressing a warp of the second semiconductor chip 40.

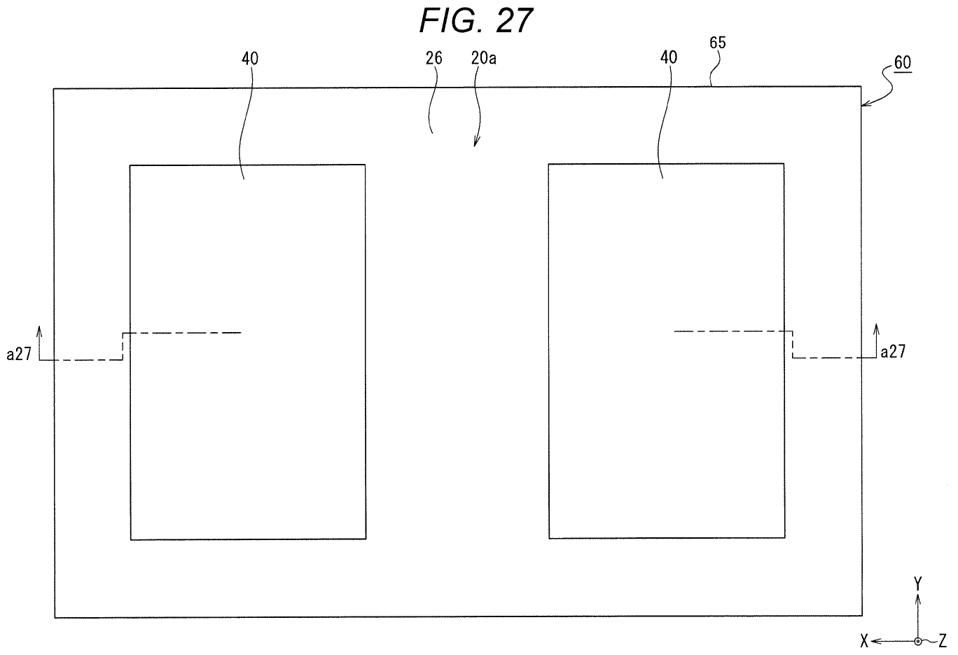

Specifically, as will be described in detail below, a process of manufacturing the solid-state imaging device 1A according to the first embodiment include a thinning process of reducing the thickness of the second semiconductor chip 40 in the Z direction after directly bonding the bonding surface 40a of the second semiconductor chip 40 to the bonding surface 20a (the bonding surface 20a of the first semiconductor chip) in the chip formation region 65 of the wafer stacked body 60 as illustrated in FIGS. 27 to 29. In this thinning process, the thickness of the semiconductor layer 42 of the second semiconductor chip 40 in the Z direction is reduced, so that rigidity of the second semiconductor chip 40 is decreased. Due to the decrease in the rigidity of the second semiconductor chip 40, a warp in which an outer peripheral edge portion of the second semiconductor chip 40 (the peripheral edge portion Cs side of the second semiconductor chip 40) is separated from the bonding surface 20a in the chip formation region 65 of the wafer stacked body 60 (the bonding surface 20a of the first semiconductor chip), that is, a warp having the bonding surface 40a of the second semiconductor chip 40 as a convex surface, may occur in the second semiconductor chip 40. The warp suppression film 45b suppresses such a warp of the second semiconductor chip 40.

For the warp suppression film 45b, a material having a linear expansion coefficient different from the surrounding multistage stacked portion 45a and insulating layer 46 is used. Furthermore, the rigidity is increased by using a dense film having a low shrinkage rate for the warp suppression film 45b. As a result, it is possible to suppress the warp of the peripheral portion of the semiconductor chip 40 by the difference in the linear expansion coefficient.

As illustrated in FIG. 12B, the warp suppression film 45b is disposed between the multistage stacked portion 45a and the insulating layer 46. A thickness t₁ of the warp suppression film 45b is larger than a thickness t₂ of wiring 45a1 of the multilayer wiring layer 45 (t₁>t₂) in order to enable control of the local film stress of the second semiconductor chip 40. Then, the thickness t₁ of the warp suppression film 45b is preferably larger than a thickness t₃ of the bonding metal pad 47 of the multilayer wiring layer 45.

The warp suppression film 45b is preferably configured by a material different from the insulating layer of the multistage stacked portion 45a of the multilayer wiring layer 45 or the uppermost insulating layer 46 of the multilayer wiring layer 45. For example, as the warp suppression film 45b, an insulating film such as a SiO film, a SiCO film, a SiO film, a SiCN film, or a silicon nitride (SiN) film, a metal film such as an aluminum (Al) film, a copper (Cu) film, a tungsten (W) film, a titanium (Ti) film, a tantalum (Ta) film, a zirconium (Zr) film, a hafnium (Hf) film, a lanthanum (La) film, or an alloy film thereof, an oxide film or a nitride film thereof, or a resin film thereof can be used. In a case where the insulating layer 46 is a silicon oxide layer, a silicon nitride film, an aluminum nitride film, or a hafnium nitride film is preferable because a processing selection ratio with the silicon oxide layer can be more favorably obtained. In the first embodiment, the warp suppression film 45b is configured by, for example, a silicon nitride film.

### <Bonding of First Semiconductor Chip and Second Semiconductor Chip>

As illustrated in FIG. 8, the bonding metal pad 27 of the first semiconductor chip 20 and the bonding metal pad 47 of the second semiconductor chip 40 are electrically and mechanically connected by metal-to-metal bonding in a state where the respective bonding surfaces face each other. Then, the metal-to-metal bonding between the bonding metal pad 27 and the bonding metal pad 47 makes the wiring of the multilayer wiring layer 25 of the first semiconductor chip 20 and the wiring of the multilayer wiring layer 45 of the second semiconductor chip 40 electrically conducted.

As illustrated in FIG. 8, the bonding metal pad 27 of the first semiconductor chip 20 and the bonding metal pad 47 of the second semiconductor chip 40 are bonded by direct bonding at their bonding surfaces in the state where the respective bonding surfaces face each other.

Furthermore, as illustrated in FIGS. 8 and 9, the insulating layer 26 of the first semiconductor chip 20 and the insulating layer 46 of the second semiconductor chip 40 are bonded by direct bonding in the state where the respective insulating layers face each other.

That is, the bonding surface 20a including the insulating layer 26 and the bonding metal pad 27 of the first semiconductor chip 20 and the bonding surface 40a including the insulating layer 46 and the bonding metal pad 47 of the second semiconductor chip 40 are bonded by direct bonding. As the direct bonding, for example, surface activation bonding can be used.

### «Method of Manufacturing Second Semiconductor Chip»

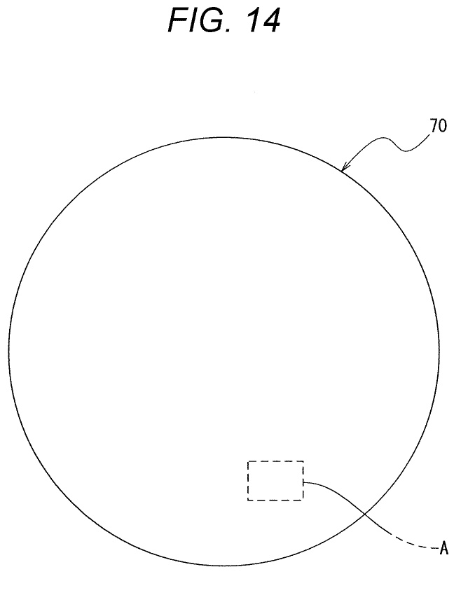

Next, a method of manufacturing the second semiconductor chip 40 included in the solid-state imaging device 1A will be described with reference to FIGS. 14 to 21.

FIG. 14 is a schematic plan view of a semiconductor wafer 70 for describing the method of manufacturing the second semiconductor chip 40 included in the solid-state imaging device 1A according to the first embodiment of the present technology,

FIG. 15 is a view illustrating a configuration of a chip formation region 75 by enlarging a region A in FIG. 14,

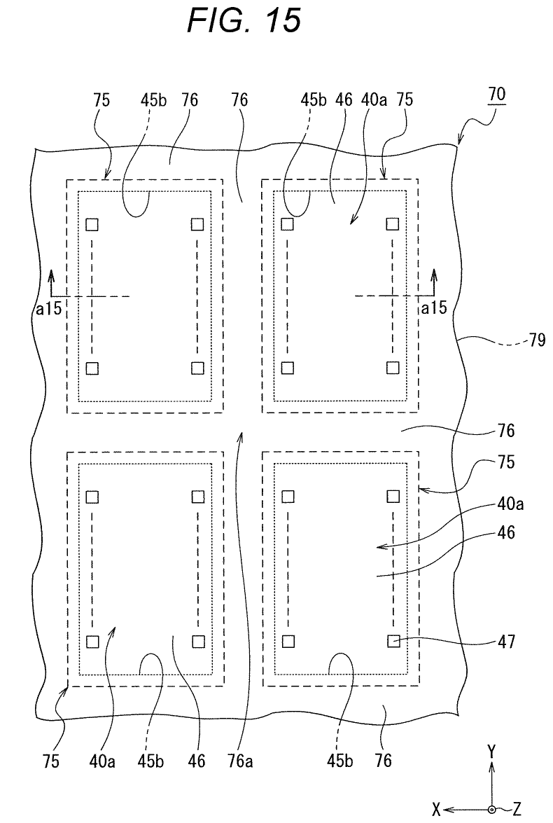

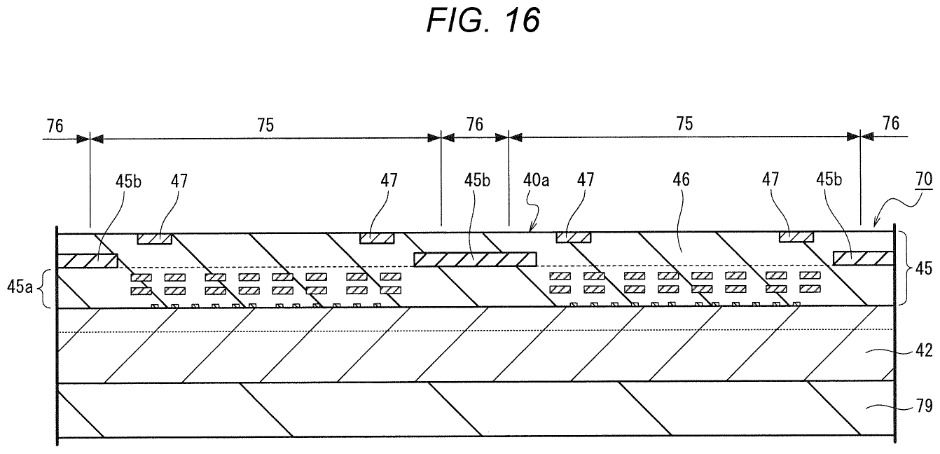

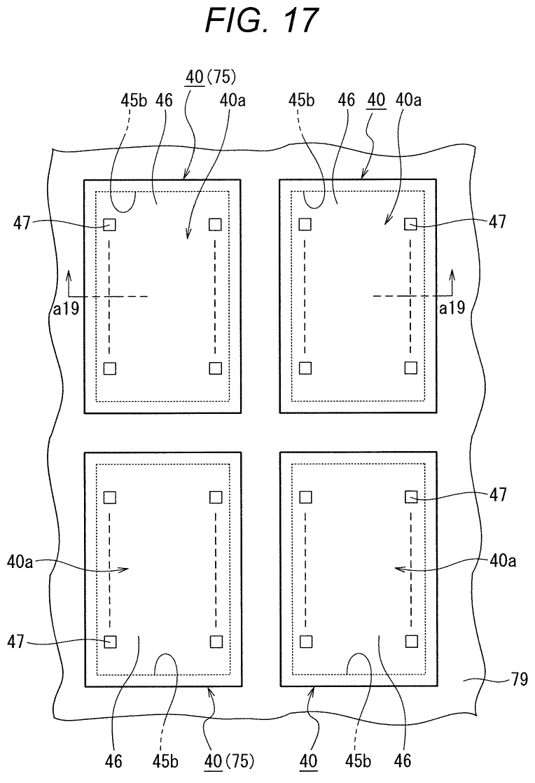

FIG. 16 is a longitudinal cross-sectional view schematically illustrating a longitudinal cross-sectional structure taken along cutting line a15-a15 in FIG. 15, FIG. 17 is a plan view schematically illustrating a state where a dicing process is performed for the semiconductor wafer 70 in the method of manufacturing the second semiconductor chip 40,

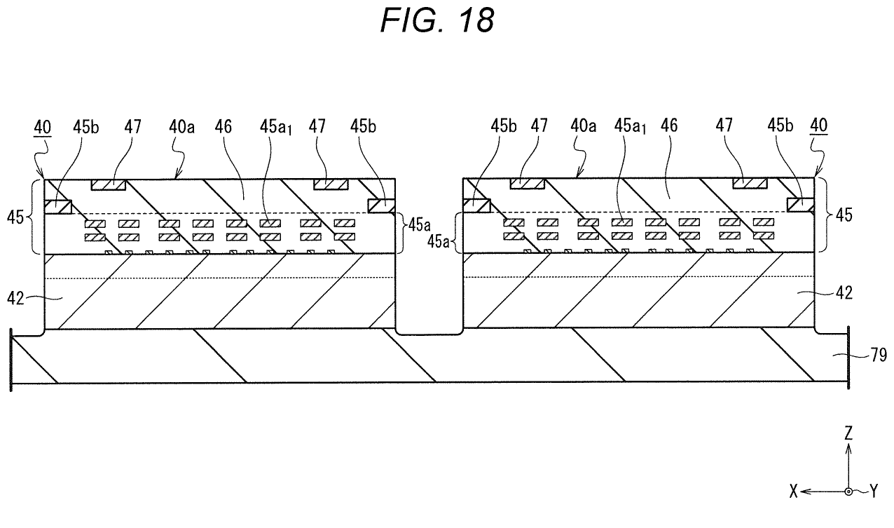

FIG. 18 is a longitudinal cross-sectional view schematically illustrating a longitudinal cross-sectional structure taken along cutting line a17-a17 in FIG. 17, and

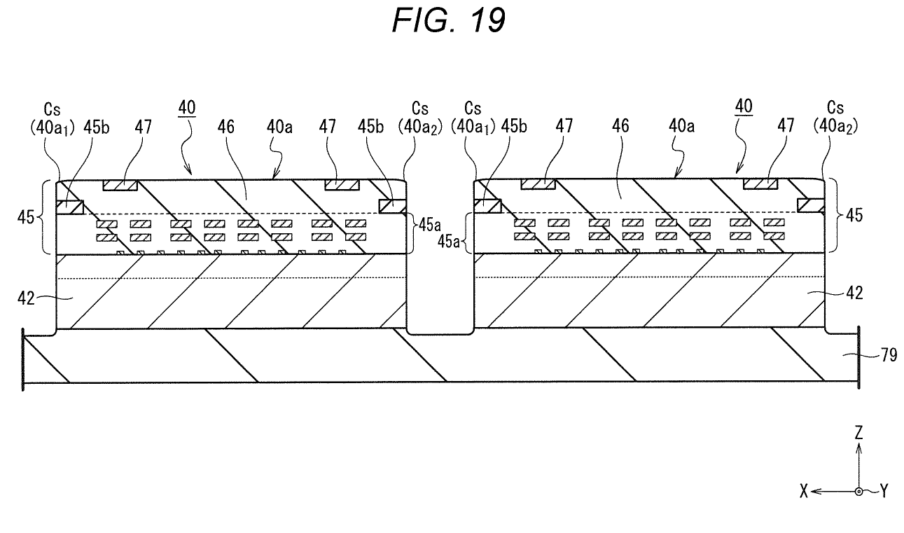

FIG. 19 is a longitudinal cross-sectional view schematically illustrating a state in which a ring CMP process is performed in the method for manufacturing the second semiconductor chip 40.

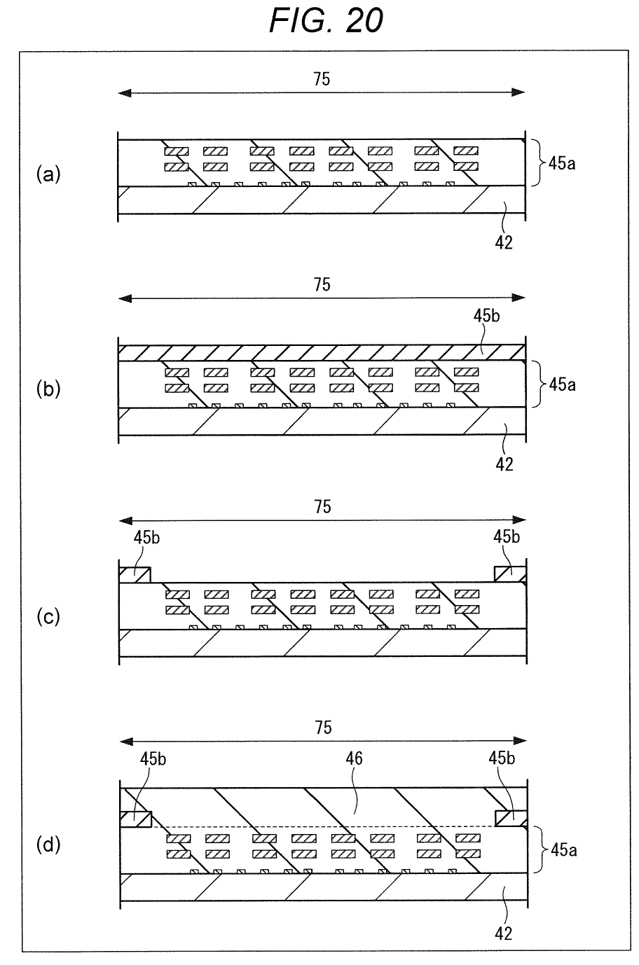

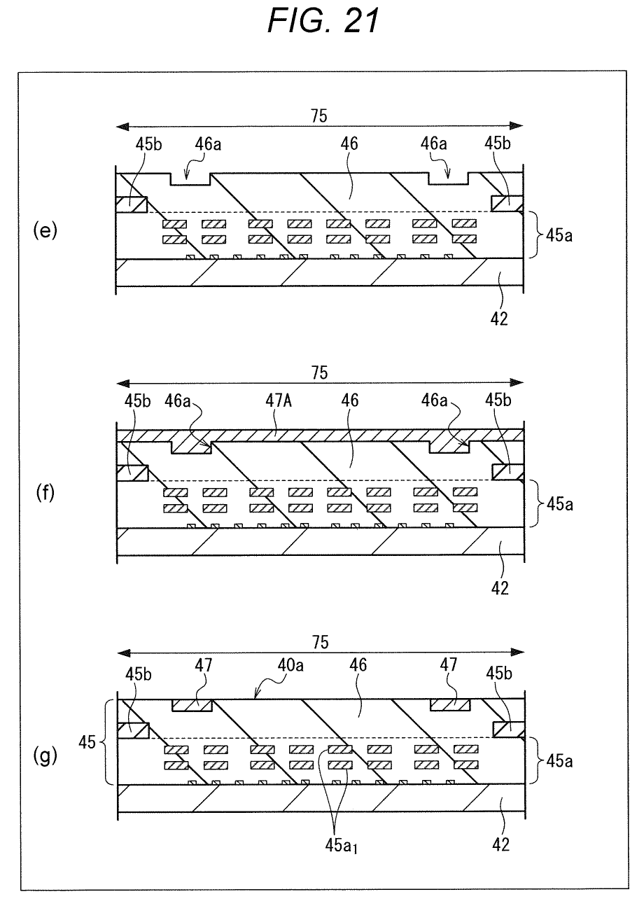

Furthermore, FIGS. 20 and 21 are process cross-sectional views schematically illustrating formation of the multilayer wiring layer 45 including the warp suppression film 45b and the bonding surface 40a in the method of manufacturing the second semiconductor chip 40.

The second semiconductor chip 40 included in the solid-state imaging device 1A is formed in the chip formation region 75 of the semiconductor wafer 70 illustrated in FIG. 15. The chip formation region 75 is partitioned by scribe lines 76 extending along the respective directions of the X direction and the Y direction, and a plurality of chip formation regions is arranged in a matrix. FIG. 15 illustrates four chip formation regions 75 arranged around an intersection portion 76a where the scribe line 76 extending in the X direction and the scribe line 76 extending in the Y direction intersect.

Then, the chip formation region 75 is individually divided into small pieces (individually divided) along the scribe lines 76, thereby forming the second semiconductor chip 40. The chip formation region 75 has a quadrangular planar shape in plan view, and has a rectangular shape in the first embodiment. Note that the scribe lines 76 are not physically formed.

In the semiconductor wafer 70 illustrated in FIG. 14, a pre-process of forming the transistor, the multilayer wiring layer 45, and the like in the semiconductor layer 42 (see FIG. 16) has already been performed, and the semiconductor layer 42, the multilayer wiring layer 45, the bonding surface 40a, and the like illustrated in FIG. 16 are formed in the chip formation region 75 illustrated in FIG. 15. The bonding surface 40a includes the insulating layer 46 and the bonding metal pad 47 of the multilayer wiring layer 45. Hereinafter, a process after the pre-process is performed will be described.

The semiconductor wafer 70 for which the pre-process has been performed is diced along the scribe lines 76, and the plurality of chip formation regions 65 of the semiconductor wafer 70 is individually divided into small pieces to form the second semiconductor chip 40, as illustrated in FIGS. 17 and 18. The dicing of the semiconductor wafer 70 is performed in a state where the semiconductor wafer 70 is bonded and fixed to a dicing sheet (dicing tape) 79. The second semiconductor chip 40 includes the bonding surface 40a and the warp suppression film 45b, and the bonding surface 40a includes the insulating layer 46 and the bonding metal pad 47.

Next, the ring CMP is performed for the bonding surface 40a of each of the plurality of second semiconductor chips 40 in the state where the plurality of second semiconductor chips 40 is bonded and fixed to the dicing sheet 79.

In this process, the peripheral edge portion Cs of the second semiconductor chip 40 on the bonding surface side is excessively polished, and as illustrated in FIG. 19, the peripheral edge portion Cs including the four sides (40a₁, 40a₂, 40a₃, and 40a₄) of the bonding surface 40a of the second semiconductor chip 40 has a curved surface shape that curves over the bonding surface 40a and the side surface of the second semiconductor chip 40. FIG. 19 illustrates the peripheral edge portions Cs at the two sides 40a₁ and 40a₂ of the bonding surface 40a in the cross section along the X direction of the second semiconductor chip 40.

Next, after surface modification treatment of activating the bonding surface 40a of the second semiconductor chip 40 is performed, the second semiconductor chip 40 is conveyed to a chip bonding process during the process of manufacturing the solid-state imaging device 1A to be described below.

### <Formation of Multilayer Wiring Layer>

Next, formation of the multilayer wiring layer 45 including the warp suppression film 45b and the bonding surface 40a will be described with reference to FIGS. 20 and 21. The multilayer wiring layer 45 is formed in a wafer state before the plurality of chip formation regions 65 of the semiconductor wafer 70 is individually divided into small pieces to form the second semiconductor chip 40.

First, as illustrated in FIG. 20(a), the multistage stacked portion 45a in which an insulating layer and a wiring layer are alternately stacked in a plurality of stages is formed on the semiconductor layer 42 on the element formation surface side.

Next, as illustrated in FIG. 20(b), the warp suppression film 45b is formed on an entire surface of the multistage stacked portion 45a on the opposite side to the semiconductor layer 42 side. As the warp suppression film 45b, for example, an insulating film such as a silicon nitride (SiN) film, a metal film such as an aluminum (Al) film, a copper (Cu) film, or an alloy film thereof, or a resin film can be used. In the first embodiment, a silicon nitride film is formed as the warp suppression film 45b by, for example, a CVD method.

Next, the warp suppression film 45b is patterned into a predetermined shape, and as illustrated in FIG. 20(c), the warp suppression film 45b having a predetermined shape is formed on the multistage stacked portion 45a. The patterning of the warp suppression film 45b is performed using a known photolithography technique and an anisotropic dry etching technique.

Although not illustrated in detail, the warp suppression film 45b is formed in a shape extending along at least one of the four sides of the chip formation region 75 in plan view. In the first embodiment, the warp suppression film 45b is formed in an annular pattern continuously extending along the four sides of the chip formation region 75 in plan view, for example, although not limited thereto.

Next, as illustrated in FIG. 20(d), the insulating layer 46 that covers the warp suppression film 45b is formed on the entire surface of the multistage stacked portion 45a on the opposite side to the semiconductor layer 42 side. The insulating layer 46 can be formed by, for example, forming a silicon oxide film by a CVD method.

Next, as illustrated in FIG. 21(e), a recess 46a is formed in the surface layer portion of the insulating layer 46 on the opposite side to the multistage stacked portion 45a side. The recess 46a is formed using a known photolithography technique and an anisotropic dry etching technique.

Next, as illustrated in FIG. 21(f), a metal film 47A is formed so as to embed the recess 46a on the entire surface of the insulating layer 46 on the opposite side to the multistage stacked portion 45a side. As the metal film 47A, for example, a metal film of aluminum (Al), copper (Cu), or the like, or an alloy film of an alloy mainly containing Al or Cu, or the like, can be used. These metal films and alloy films can be formed by, for example, a sputtering method.

Next, the metal film 47A on the insulating layer 46 is selectively removed such that the metal film 47A remains inside the recess 46a of the insulating layer 46, and as illustrated in FIG. 21(g), the bonding metal pad 47 is formed in the recess 46a of the insulating layer 46. The selective removal of the metal film 47A is performed by, for example, a CMP method.

By this process, the bonding surface 40a including the insulating layer 46 and the bonding metal pads 47 interspersed with the insulating layer 46 is formed in the chip formation region 75.

Furthermore, by this process, the multilayer wiring layer 45 including the multistage stacked portion 45a, and including the warp suppression film 45b and the bonding surface 40a is formed.

### «Method for Manufacturing Solid-State Imaging Device»

Next, a method of manufacturing the solid-state imaging device 1A will be described with reference to FIGS. 22 to 34.

FIG. 22 is a view illustrating a planar configuration of the wafer stacked body. FIG. 23 is a longitudinal cross-sectional view schematically illustrating a longitudinal cross-sectional structure of the wafer stacked body 60. FIG. 24 is a view schematically illustrating a configuration of the chip formation region 65 by enlarging a region B in FIG. 23.

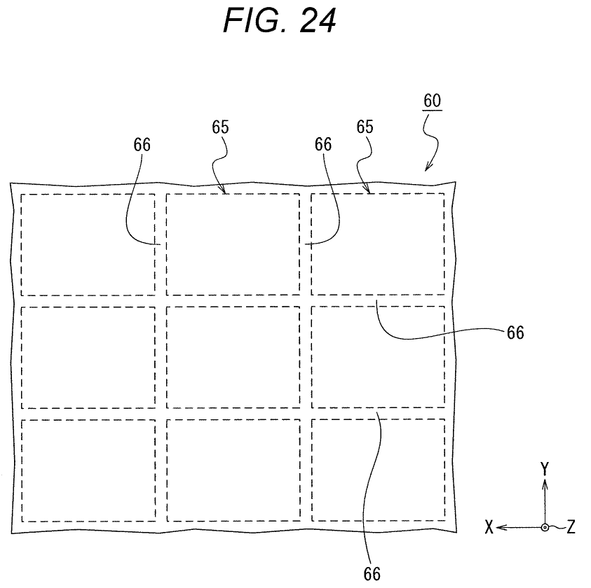

Furthermore, FIGS. 25, 27, 31, and 34 are plan views schematically illustrating processes of the method of manufacturing the solid-state imaging device 1A,

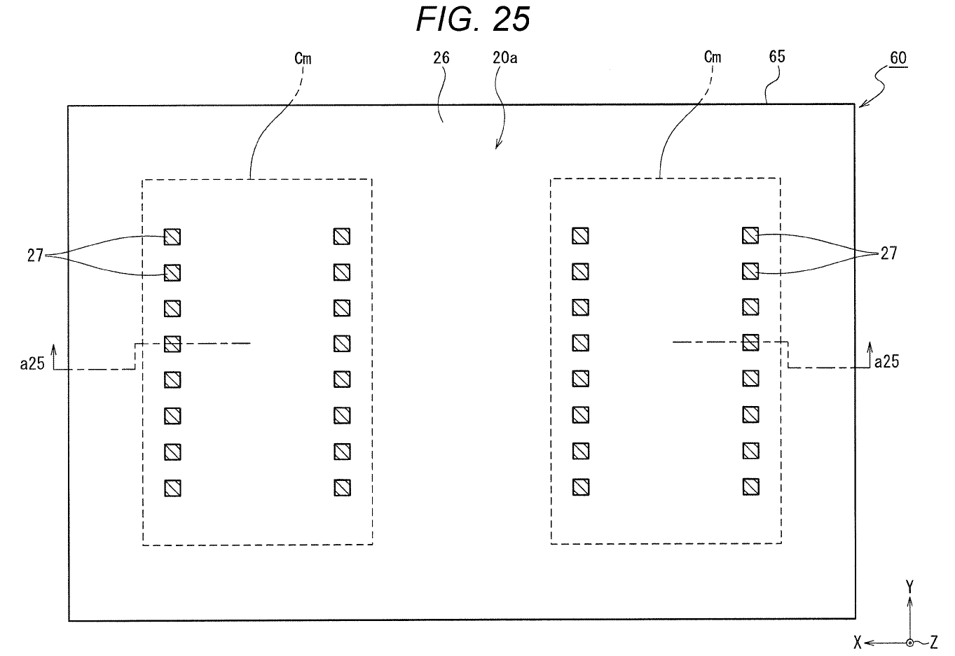

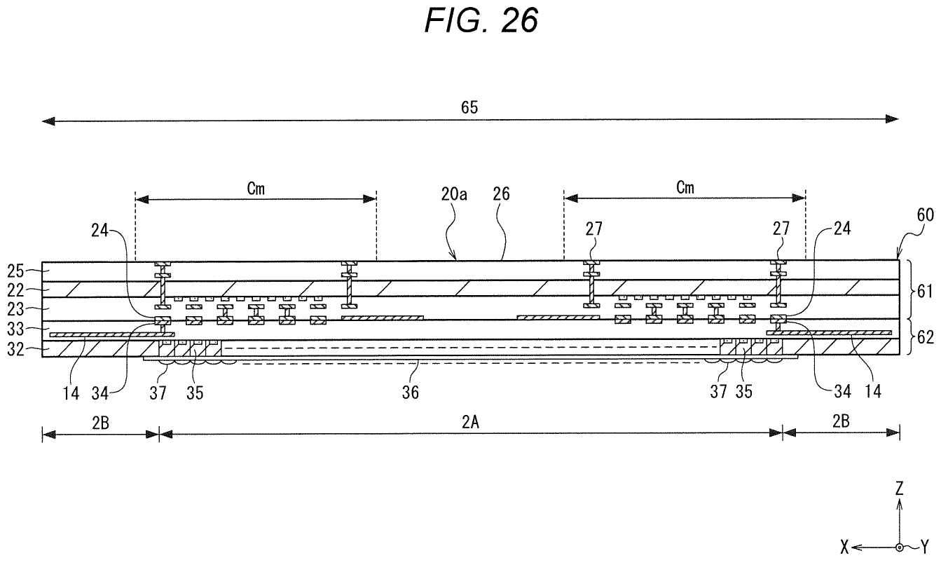

FIG. 26 is a longitudinal cross-sectional view schematically illustrating a longitudinal cross-sectional structure taken along cutting line a25-a25 in FIG. 25,

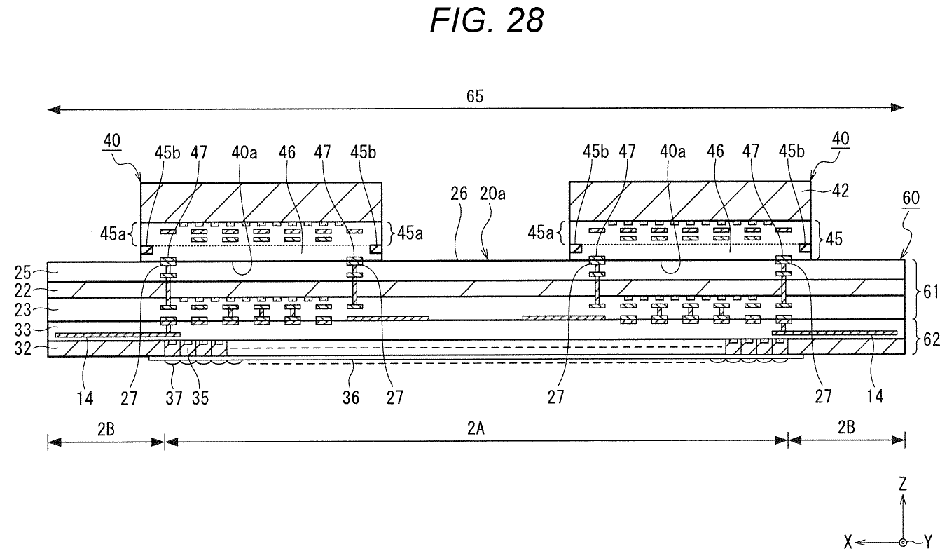

FIG. 28 is a longitudinal cross-sectional view schematically illustrating a longitudinal cross-sectional structure taken along cutting line a27-a27 in FIG. 27,

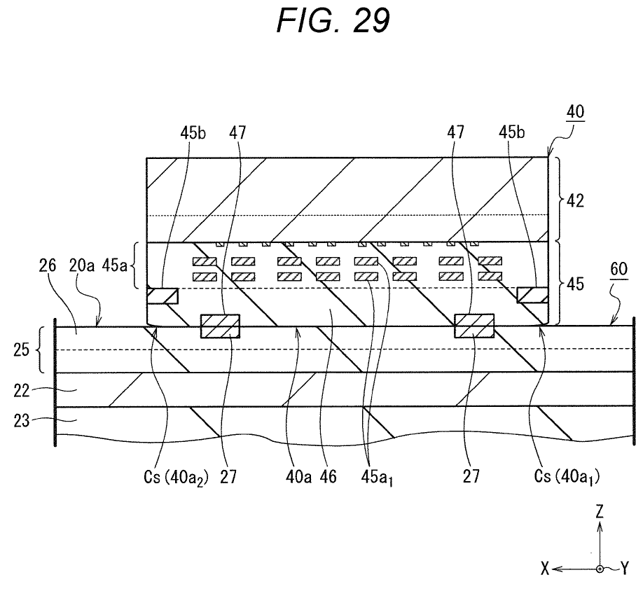

FIG. 29 is a partially enlarged longitudinal cross-sectional view of FIG. 28,

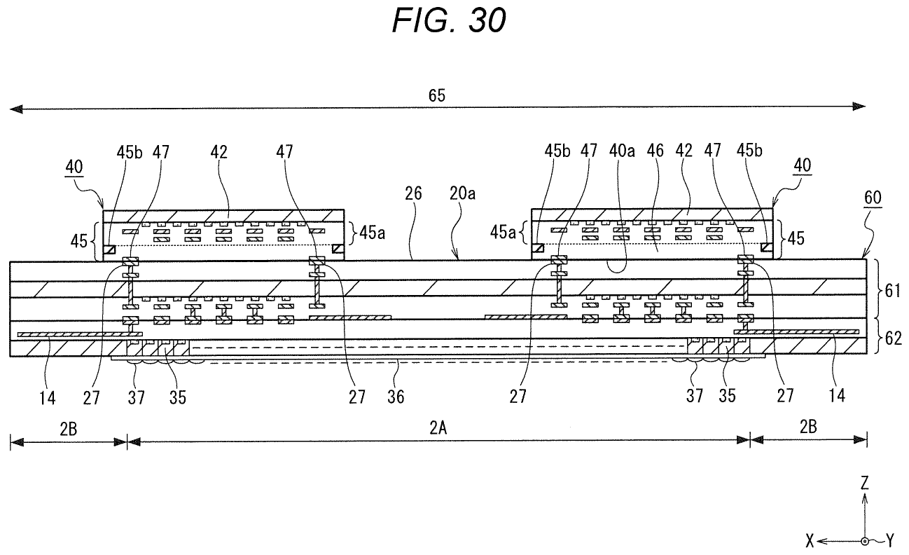

FIG. 30 is a longitudinal cross-sectional view schematically illustrating a process subsequent to FIG. 27,

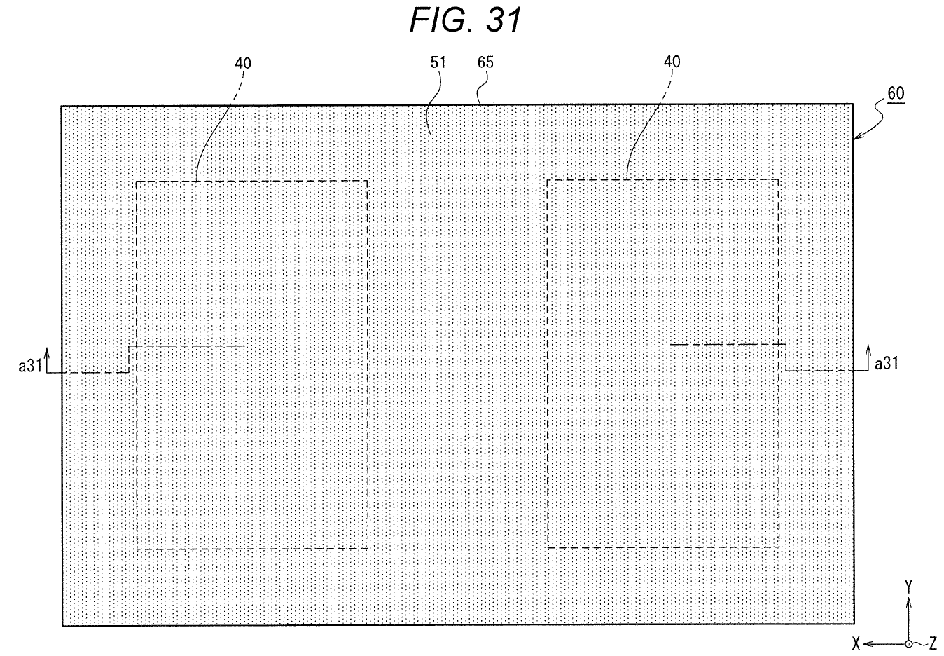

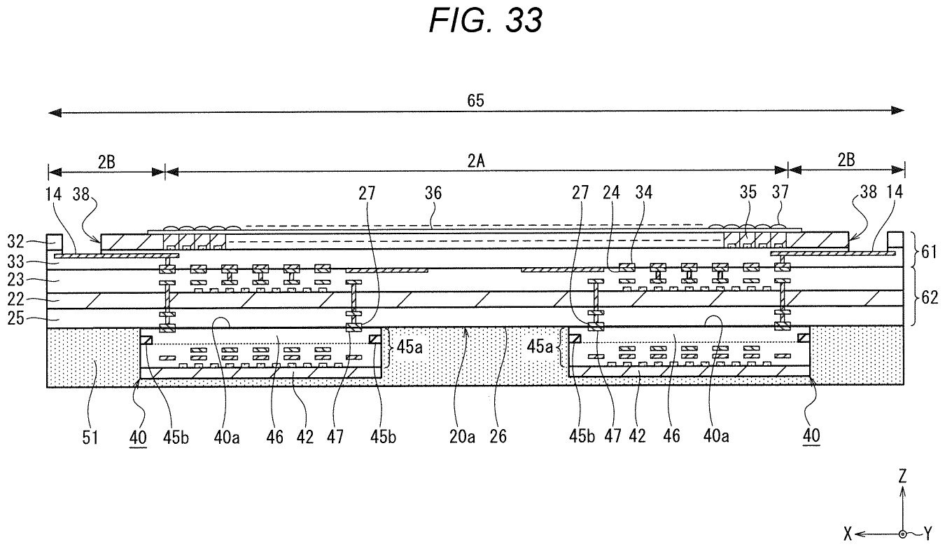

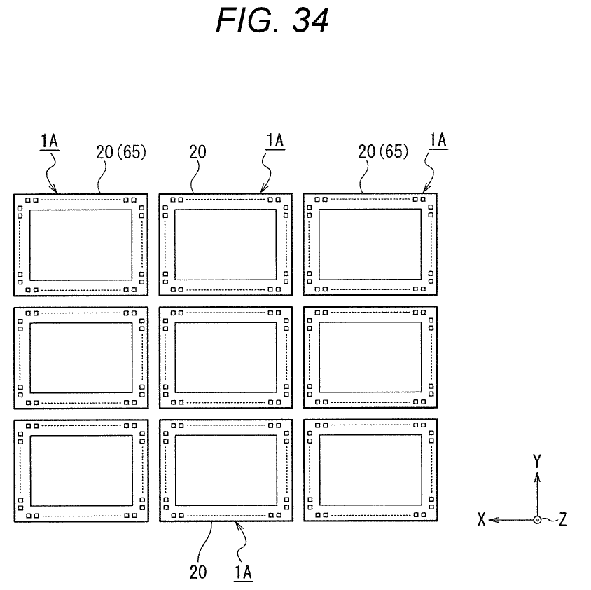

FIG. 33 is a longitudinal cross-sectional view schematically illustrating a process subsequent to FIG. 31, and FIG. 34 is a plan view schematically illustrating a process subsequent to FIG. 33.

Here, the first semiconductor chip 20 included in the solid-state imaging device 1A is manufactured in the chip formation region 65 of the wafer stacked body 60 illustrated in FIG. 24. The chip formation region 65 is partitioned by scribe lines (dicing lines) 66 extending along the respective directions of the X direction and the Y direction, and a plurality of chip formation regions is arranged in a matrix. FIG. 24 illustrates an example of nine chip formation regions 65 arranged in a three-by-three matrix in the X direction and the Y direction. Then, the plurality of chip formation regions 65 is individually divided into small pieces along the scribe lines 66, thereby forming the first semiconductor chip 20. The chip formation region 65 is divided into small pieces after the manufacturing processes described below is performed.

Note that the scribe lines 66 are not physically formed.

As illustrated in FIGS. 22 and 23, the wafer stacked body 60 includes two semiconductor wafers 61 and 62 stacked on each other.

The semiconductor wafer 61 includes the semiconductor layer 22, the multilayer wiring layer 23 stacked on the semiconductor layer 22 on the element formation surface side, and the multilayer wiring layer 25 stacked on the semiconductor layer 22 on the opposite side to a side of the multilayer wiring layer 23.

The semiconductor wafer 62 includes the semiconductor layer 32 and the multilayer wiring layer 33 stacked on the semiconductor layer 32 on the element formation surface side. Then, the semiconductor wafers 61 and 62 are bonded in a state where the multilayer wiring layer 23 side of the semiconductor wafer 61 and the multilayer wiring layer 33 side of the semiconductor wafer 62 face each other.

FIGS. 25 to 34 illustrate one chip formation region 65 of the wafer stacked body 60 as an example. Furthermore, FIGS. 25 and 26 illustrate a state in which a wafer stacking process is performed to form the wafer stacked body 60 in the process of manufacturing the solid-state imaging device 1A.

As illustrated in FIG. 26, the chip formation region 65 includes the multilayer wiring layer 25, the semiconductor layer 22, the multilayer wiring layer 23, the multilayer wiring layer 33, and the semiconductor layer 32. Then, the bonding metal pad 24 of the multilayer wiring layer 23 and the bonding metal pad 34 of the multilayer wiring layer 33 are bonded by direct bonding, and electrical conduction is established between the multilayer wiring layer 23 and the multilayer wiring layer 33. Then, the uppermost insulating layer 26 of the multilayer wiring layer 23 and the uppermost insulating layer of the multilayer wiring layer 23 are directly bonded. Then, the chip formation region 65 has the bonding surface 20a on the multilayer wiring layer 25 on the opposite side to the semiconductor layer 22 side. Then, the bonding surface 20a includes the uppermost insulating layer 26 of the multilayer wiring layer 25 and the bonding metal pad 27 provided in the insulating layer 26 in the state where the surface (bonding surface) is exposed from the insulating layer 26. The bonding metal pad 27 is disposed in the chip mounting region Cm. Then, in the chip formation region 65, the pixel array unit 2A illustrated in FIG. 3, the logic circuit 13 illustrated in FIGS. 1 and 2, the bonding pad (input/output terminal) 14, the pixel circuit 15, and the like are already formed. Hereinafter, a process after the wafer stacked body 60 is formed (a process after the wafer stacking process) will be described.

Note that, in the first embodiment, a case where the photoelectric conversion region 35, the optical filter layer 36, and the microlens 37 are also already formed will be described, but the photoelectric conversion region 35, the optical filter layer 36, and the microlens 37 may be formed after a sealing body forming process to be described below.

After the wafer stacked body 60 illustrated in FIGS. 25 and 26 is formed, the second semiconductor chip 40 is mounted in the chip formation region 65 of the wafer stacked body 60 as illustrated in FIGS. 27 and 28. The second semiconductor chip 40 is mounted by directly bonding the bonding surface 40a of the second semiconductor chip 40 and the bonding surface 20a of the wafer stacked body 60 (the bonding surface 20a of the first semiconductor chip 20).

Specifically, first, surface improvement treatment of activating the bonding surface 20a of the wafer stacked body 60 is performed. In this surface improvement treatment, for example, the bonding surface 20a of the wafer stacked body 60 is irradiated with plasma to remove oxides and adsorbents, and dangling bonds of atoms are generated. Also in the above-described surface modification treatment of activating the bonding surface 40a of the second semiconductor chip 40, dangling bonds of atoms are generated by plasma irradiation, for example.

In this process, the surface of each of the insulating layer 26 and the bonding metal pads 27 included in the bonding surface 20a of the wafer stacked body 60 undergoes the surface improvement treatment. Also in the second semiconductor chip 40, the surface of each of the insulating layer 46 and the bonding metal pads 47 included in the bonding surface 40a undergoes the surface improvement treatment.

Next, as illustrated in FIG. 29, the second semiconductor chip 40 is mounted on the chip formation region 65 (chip mounting region Cm) of the wafer stacked body 60 in the state where the bonding surface 20a and the bonding metal pad 27 of the wafer stacked body 60 for which the surface improvement treatment has been performed and the bonding surface 40a and the bonding metal pad 47 of the second semiconductor chip 40 for which the surface improvement treatment has also been performed face each other.

Next, the bonding surface 40a of the second semiconductor chip 40 is crimped (pressure-bonded) to the bonding surface 20a of the wafer stacked body 60 in the state illustrated in FIG. 29 such that a bonding wave is generated from a center portion toward the peripheral portion in the two-dimensional plane of the second semiconductor chip 40.

By this process, the dangling bonds of the bonding surface 20a of the wafer stacked body 60 and the dangling bonds of the bonding surface 40a of the second semiconductor chip 40 are coupled, and the bonding surface 20a of the wafer stacked body 60 and the bonding surface 40a of the second semiconductor chip 40 are coupled by surface activation bonding. More specifically, the insulating layer 26 included in the bonding surface 20a of the wafer stacked body 60 and the insulating layer 46 included in the bonding surface 40a of the second semiconductor chip 40 are bonded by surface activation bonding, and the bonding metal pad 27 included in the bonding surface 20a of the wafer stacked body 60 and the bonding metal pad 47 included in the bonding surface 40a of the second semiconductor chip 40 are bonded by surface activation bonding.

Note that, in this process, as will be described with reference to FIG. 29, since the peripheral edge portion Cs of the second semiconductor chip 40 on the bonding surface 40a side has a curved surface shape, the peripheral edge portion Cs of the second semiconductor chip 40 on the bonding surface 40a side may be separated from the bonding surface 20a of the wafer stacked body 60 (first semiconductor chip 20).

Next, as illustrated in FIG. 30, the thickness of the semiconductor layer 42 of the second semiconductor chip 40 in the Z direction is reduced to thin the second semiconductor chip 40. The thinning of the second semiconductor chip 40 is treatment for thinning the solid-state imaging device 1A. The thickness of the semiconductor layer 42 in the Z direction can be reduced by grinding the surface layer portion of the semiconductor layer 42 on the opposite side to the multilayer wiring layer 45 side by, for example, a CMP method.

Here, the rigidity of the second semiconductor chip 40 is decreased by reducing the thickness of the semiconductor layer 42. Due to the decrease in the rigidity, in a conventional semiconductor chip, as will be described with reference to FIG. 30, a warp in which an outer peripheral edge portion of the second semiconductor chip 40 (the peripheral edge portion Cs side of the second semiconductor chip 40) is separated from the bonding surface 20a in the chip formation region 65 of the wafer stacked body 60 (the bonding surface 20a of the first semiconductor chip 20), that is, a warp having the bonding surface 40a of the second semiconductor chip 40 as a convex surface, may occur in the second semiconductor chip 40.

In contrast, as illustrated in FIG. 30, the second semiconductor chip 40 of the first embodiment includes the warp suppression film 45b that suppresses the warp of the second semiconductor chip 40, so that it is possible to suppress the warp of the second semiconductor chip 40 accompanying the decrease in the rigidity of the second semiconductor chip 40.

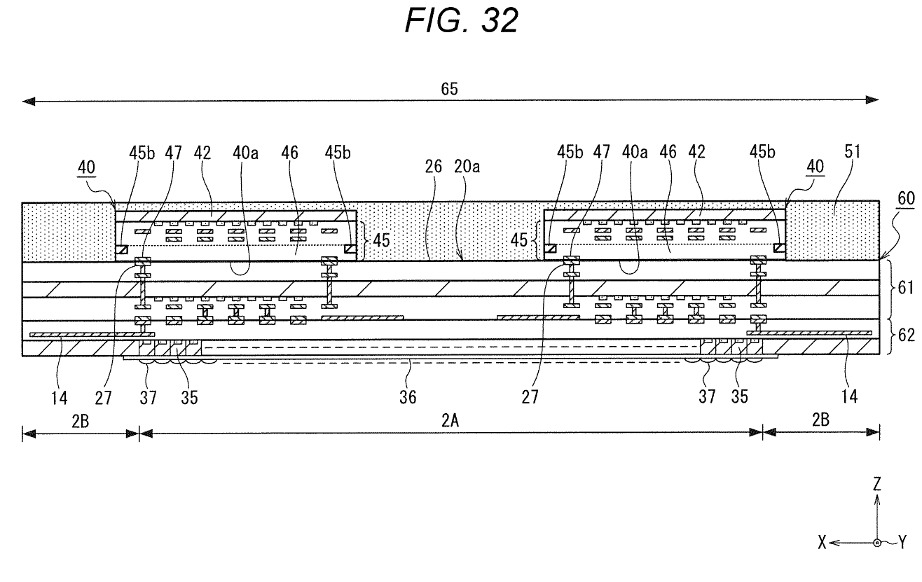

Next, as illustrated in FIGS. 31 and 32, the sealing body 51 is formed on the bonding surface 20a side of the wafer stacked body 60, the sealing body 51 covering each of the two second semiconductor chips 40 and having a planarized surface layer portion in the chip formation region 65 on the opposite side to the bonding surface 20a side. The sealing body 51 can be formed by, for example, forming a sealing material so as to cover the entire second semiconductor chip 40 in the chip formation region 65, and then planarizing the surface of the sealing material by, for example, a chemical mechanical polishing (CMP) method. As the sealing material, for example, an epoxy-based thermosetting insulating resin or a polyimide-based thermoplastic insulating resin can be used. Furthermore, as the sealing material, a silicon oxide-based material such as phosho silicate glass (PSG) having high fluidity can also be used.

In this process, each of the two second semiconductor chips 40 is sealed with the sealing body 51.

Note that the sealing body 51 may be formed by selectively forming the sealing material outside the second semiconductor chip 40 by a spin coating method or the like in the chip formation region 65 to expose an upper surface side of the semiconductor layer 42 of the second semiconductor chip 40.

Next, as illustrated in FIG. 33, the bonding opening 38 that penetrates the semiconductor layer 32 and exposes the surface of the bonding pad 14 is formed.

Then, thereafter, the plurality of chip formation regions 65 of the wafer stacked body 60 is individually divided into small pieces along the scribe lines 66, so that as illustrated in FIG. 34, the first semiconductor chip 20 including the first substrate unit 21 and the second substrate unit 31 is formed, and the chip stacked body in which the bonding surface 40a of the second semiconductor chip 40 is bonded to the bonding surface 20a of the first semiconductor chip 20 by direct bonding is formed. Then, the solid-state imaging device 1A including the first semiconductor chip 20, the second semiconductor chip 40, and the sealing body 51 is almost completed.

### Principal Effects of the First Embodiment

The second semiconductor chip 40 of the solid-state imaging device 1A according to the first embodiment of the present technology includes the multilayer wiring layer 45 including the second bonding surface, and the semiconductor layer 42 provided on the multilayer wiring layer 45 on the opposite side to the second bonding surface 40a side. Then, the multilayer wiring layer 45 includes the warp suppression film 45b that annularly extends along the four sides (40a₁, 40a₂, 40a₃, and 40a₄) of the second bonding surface 40a and suppresses the warp of the second semiconductor chip 40.

Therefore, even if the thickness of the semiconductor layer 42 of the second semiconductor chip 40 is reduced after the bonding surface 20a of the wafer stacked body 60 (the bonding surface 20a of the first semiconductor chip 20) and the bonding surface 40a of the second semiconductor chip 40 are bonded by direct bonding in the process of manufacturing the solid-state imaging device 1A, it is possible to suppress the warp of the second semiconductor chip 40 due to the decrease in the rigidity of the second semiconductor chip 40, and it is possible to suppress cracking, chipping, and the like of the second semiconductor chip 40, which cause the decrease in the manufacturing yield of the solid-state imaging device 1A. Therefore, the solid-state imaging device 1A according to the first embodiment can improve the manufacturing yield.

Furthermore, since the warp suppression film 45b extends along the sides (40a₁, 40a₂, 40a₃, and 40a₄) of the bonding surface 40a of the second semiconductor chip 40, it is possible to control the local film stress of the second semiconductor chip 40 corresponding to a stress strain that causes the warp of the second semiconductor chip 40 by changing a length in a longitudinal direction, a width in a lateral direction, or the thickness. Therefore, the thickness t₁ of the warp suppression film 45b is larger than the thickness t₂ of wiring 45a₁ of the multilayer wiring layer 45 (t₁>t₂) in order to enable control of the local film stress of the second semiconductor chip 40. Then, the thickness t1 of the warp suppression film 45b is preferably larger than a thickness t₃ of the bonding metal pad 47 of the multilayer wiring layer 45.

### Modifications of the First Embodiment

Next, modifications of the first embodiment will be described.

### Modification 1-1

In the above-described first embodiment, the case where the warp suppression film 45b overlaps with the sides (40a₁, 40a₂, 40a₃, and 40a₄) of the bonding surface 40a of the second semiconductor chip 40 in plan view has been described, but the warp suppression film 45b is not limited to the above-described first embodiment.

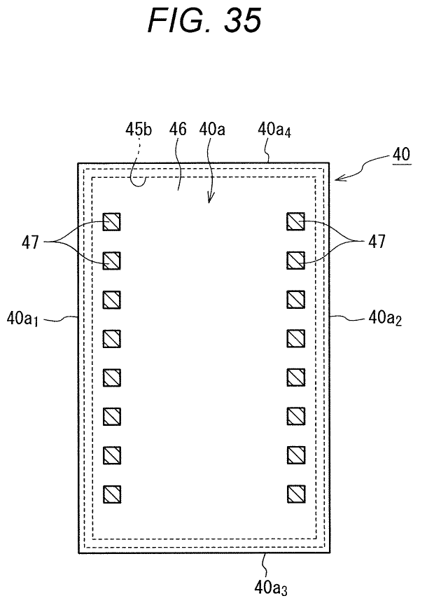

For example, as Modification 1-1, as illustrated in FIG. 35, the warp suppression film 45b may be disposed inside the sides (40a₁, 40a₂, 40a₃, and 40a₄) of the bonding surface 40a of the second semiconductor chip 40 in plan view. In this case, the warp suppression film 45b is separated inward from the side surface of the second semiconductor chip 40 (the side surface of the multilayer wiring layer 42).

### Modification 1-2

Furthermore, in the above-described first embodiment, the warp suppression film 45b annularly extending along the four sides (40a₁, 40a₂, 40a₃, and 40a₄) of the bonding surface 40a of the second semiconductor chip 40 has been described, but the warp suppression film 45b is not limited to the annular pattern of the above-described first embodiment.

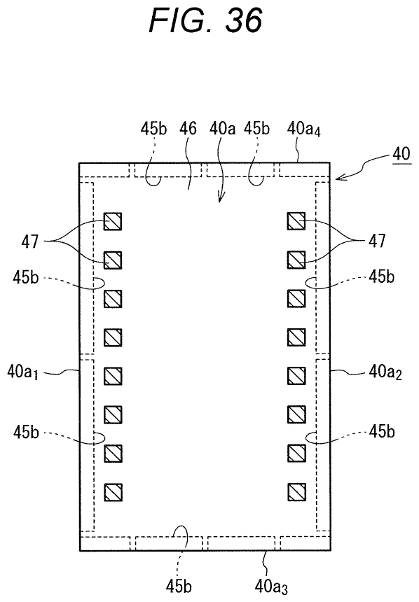

For example, as Modification 1-2, as illustrated in FIG. 36, the warp suppression films 45b may be configured to be interspersed along the four sides (40a₁, 40a₂, 40a₃, and 40a₄) of the bonding surface 40a of the second semiconductor chip 40.

### Modification 1-3

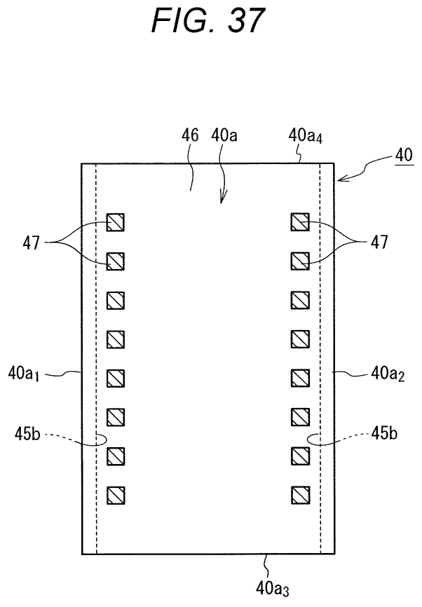

Furthermore, as Modification 1-3, as illustrated in FIG. 37, the warp suppression films 45b may be individually and respectively disposed on the sides of the two long sides (40a₁ and 40a₂) located on the opposite sides to each other in the X direction among the four sides (40a₁, 40a₂, 40a₃, and 40a₄) of the bonding surface 40a of the second semiconductor chip 40. In this case, the warp suppression film 45b extends along each of the two long sides 40a₁ and 40a₂.

### Modification 1-4

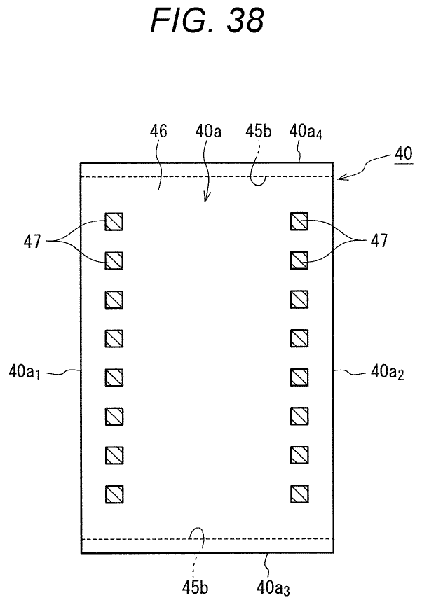

Furthermore, as Modification 1-4, as illustrated in FIG. 38, the warp suppression films 45b may be individually and respectively disposed on the sides of the two short sides (40a₃ and 40a₄) located on the opposite sides to each other in the Y direction among the four sides (40a₁, 40a₂, 40a₃, and 40a₄) of the bonding surface 40a of the second semiconductor chip 40. In this case, the warp suppression film 45b extends along each of the two long sides 40a₁ and 40a₂.

In short, the warp suppression film 45b only needs to extend along at least one of the four sides of the bonding surface of second semiconductor chip 40. In other words, the warp suppression film 45b only needs to be present on at least a part of the bonding surface of the second semiconductor chip on the peripheral edge portion Cs side in plan view.

Also in the first to fourth modifications, effects similar to those of the above-described first embodiment can be obtained.

### Modification 1-5

FIG. 39 is a plan view schematically illustrating a configuration of the second semiconductor chip 40 according to Modification 1-5 of the first embodiment of the present technology.

Modification 1-5 is an example of a case where the warp of the second semiconductor chip 40 on a side of a corner portion Cr is selectively suppressed.

Referring to FIG. 39, since the planar shape of the second semiconductor chip 40 is a quadrangular shape, stress caused by a difference in linear expansion coefficient between the semiconductor layer 21 and the multilayer wiring layer 45 or the like is likely to concentrate on the corner portion Cr where the two sides of the bonding plane 40a intersect in plan view, and floating (warp) is most likely to occur at the corner portion Cr. Therefore, the warp suppression film 45 may be selectively provided in a vicinity of the corner portion Cr where two sides (specifically, the side 40a₁ or 40a₂ extending in the Y direction and the side 40a₃ or 40a₄ extending in the X direction) having different extending directions intersect at the bonding surface 40a of the second semiconductor chip 40, and may selectively suppress the warp of the bonding surface 40a on the corner portion Cr side.

For example, as illustrated in FIG. 39, the warp suppression film 45a may have a shape selectively extending over two sides including at least the corner portion Cr of the bonding surface 40a of the second semiconductor chip 40 in plan view. Specifically, on the bonding surface 40a, the warp suppression film 45b extending over the two sides 40a₁ and 40a₄ including the corner portion Cr₁, the warp suppression film 45b extending over the two sides 40a₁ and 40a₃ including the corner portion Cr₂, the warp suppression film 45b extending over the two sides 40a₂ and 40a₄ including the corner portion Cr₃, or the warp suppression film 45b extending over the two sides 40a₂ and 40a₃ including the corner portion Cr₄ may be selectively provided.

In this case, as illustrated in FIG. 39, the warp suppression film 45b may be selectively provided for each of the four corner portions Cr (Cr₁, Cr₂, Cr₃, and Cr₄) of the bonding surface 40a. Furthermore, although not illustrated, since the degree of warp varies depending on the chip configuration even among the four corner portions Cr (Cr₁, Cr₂, Cr₃, and Cr₄), the warp suppression film may be selectively provided for at least one of the four corner portions Cr (Cr₁, Cr₂, Cr₃, and Cr₄). In this case, the warp suppression film 45b has an L-shaped planar shape.

Note that the corner portion Cr of the bonding surface 40a is included in the peripheral edge portion Cs of the bonding surface 40a.

### Modification 1-6

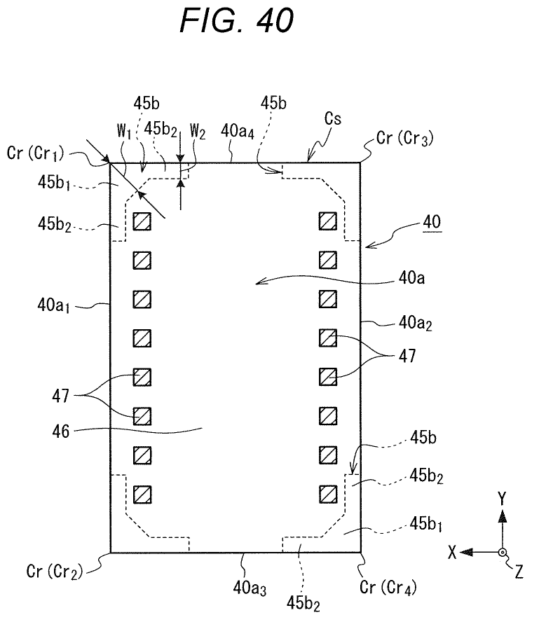

FIG. 40 is a plan view schematically illustrating a configuration of the second semiconductor chip 40 according to Modification 1-6 of the first embodiment of the present technology.

Modification 1-6 is an example of a case where a countermeasure against the warp of the second semiconductor chip 40 on the corner portion Cr side is further strengthened.

As illustrated in FIG. 40, the warp suppression film 45b may be configured such that a first width W₁ connecting an outside (corner portion side) and an inside in a first portion 45b₁ adjacent to the corner portion Cr (Cr₁, Cr₂, Cr₃, or Cr₄) of the bonding surface 40a in plan view is wider than a second width W₂ connecting an outside (side side) and an inside in a second portion 45b₂ adjacent to the side (40a₁, 40a₂, 40a₃, or 40a₄) of the bonding surface 40a in plan view.

Specifically, for example, the corner portion Cr₁ illustrated in FIG. 40 will be described as an example. In the warp suppression film 45b selectively extending along the two sides 40a₁ and 40a₄ including the corner portion Cr₁ of the bonding surface 40a in plan view, the first width W₁ connecting an outer-side end portion located on the corner portion Cr₁ side and an inner-side end portion located on an opposite side (bonding metal pad 47 side) to the outer-side end portion (corner portion Cr₁ side) in the first portion 45b₁ adjacent to the corner portion Cr₁ of the bonding surface 40a in plan view is wider than the second width W₂ connecting an outer-side end portion located on a side of the side 40a₁ or 40a₄ and an inner-side end portion located on an opposite side to the outer-side end portion (the side of the side 40a₁ or 40a₄) in the second portion 45b₂ adjacent to the side 40a₁ or 40a₄ of the bonding surface 40a in plan view.

In the case of the warp suppression film 45b of Modification 1-6, the area at the corner portion Cr of the bonding surface 40 can be selectively increased. Therefore, it is possible to further strengthen the countermeasure against the warp of the bonding surface 40a on the corner portion Cr side as compared with the warp suppression film 45b of Modification 1-5 described above.

Note that the first width W₁ of the first portion 45b₁ can be made wider than the second width W₂ of the second portion 45b₂ by inclining the inner-side end portion of the first portion 45b₁ with respect to the side (40a₁, 40a₂, 40a₃, or 40a₄) of the bonding surface 40a in plan view.

### Modification 1-7

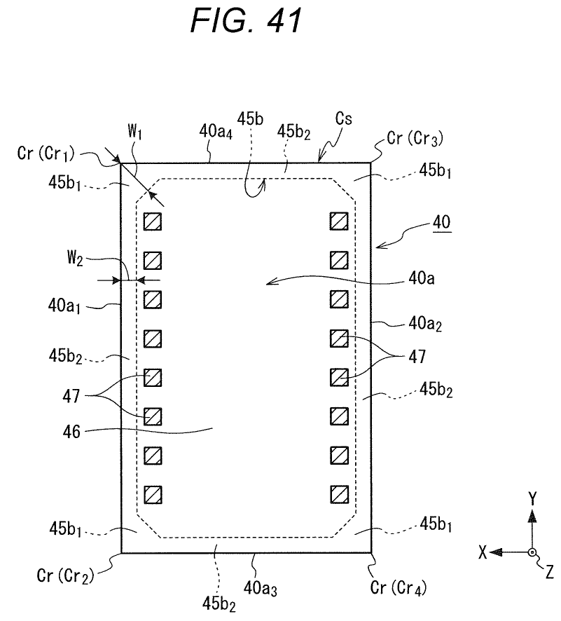

FIG. 41 is a plan view schematically illustrating a configuration of the second semiconductor chip 40 according to Modification 1-7 of the first embodiment of the present technology.

As illustrated in FIG. 41, in Modification 1-7, the corner widening technique of Modification 1-6 illustrated in FIG. 40 is applied to the warp suppression film 45b of the above-described first embodiment.

That is, as illustrated in FIG. 41, the warp suppression film 45b of Modification 1-7 is provided in the bonding surface 40a of the second semiconductor chip 40 on sides of the four sides (40a₁, 40a₂, 40a₃, and 40a₄), and has an annular planar pattern continuously extending along the four sides (40a₁, 40a₂, 40a₃, and 40a₄). Then, in the warp suppression film 45b having the annular planar pattern, the first width W₁ connecting the outer-side end portion located on the corner portion Cr₁ side and the inner-side end portion located on the opposite side (bonding metal pad 47 side) to the outer-side end portion (corner portion Cr₁ side) in the first portion 45b₁ adjacent to the corner portion Cr₁ of the bonding surface 40a in plan view is wider than the second width W₂ connecting the outer-side end portion located on the side of the side 40a₁ or 40a₄ and the inner-side end portion located on the opposite side (bonding metal pad 47 side) to the outer-side end portion (the side of the side 40a₁ or 40a₄) in the second portion 45b₂ adjacent to the side 40a₁ or 40a₄ of the bonding surface 40a in plan view.

Also in the case of the warp suppression film 45b of Modification 1-7, the area at the corner portion Cr of the bonding surface 40a can be selectively increased. Therefore, it is possible to further strengthen the countermeasure against the warp of the bonding surface 40a on the corner portion Cr side as compared with the warp suppression film 45b of the above-described first embodiment.

### Modification 1-8

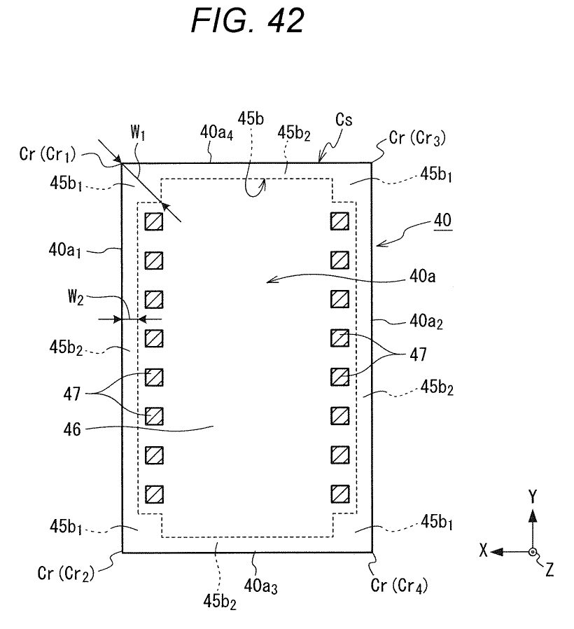

FIG. 42 is a plan view schematically illustrating a configuration of the second semiconductor chip 40 according to Modification 1-8 of the first embodiment of the present technology.

In Modification 1-8, the planar shape of the first portion 45b₁ of the warp suppression film 45b is made quadrangular, and the first width W₁ of the first portion 45b₁ is made wider than the second width W₂ of the second portion 45b₂. That is, in Modification 1-8, each of the outer-side end portion and the inner-side end portion of the first portion 45b₁ has a corner portion.

Also in the warp suppression film 45b of Modification 1-8, the area at the corner portion Cr of the bonding surface 40 can be selectively increased. Therefore, it is possible to further strengthen the countermeasure against the warp of the bonding surface 40a on the corner portion Cr side as compared with the warp suppression film 45b of the above-described first embodiment.

### Modification 1-9

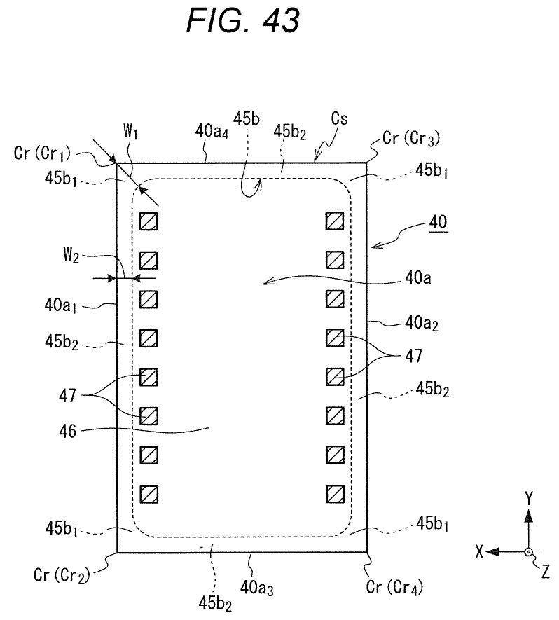

FIG. 43 is a plan view schematically illustrating a configuration of the second semiconductor chip 40 according to Modification 1-9 of the first embodiment of the present technology.

In Modification 1-9, the planar shape of the inner-side end portion is made arc-shaped in the first portion 45b₁ of the warp suppression film 45b, and the first width W₁ of the first portion 45b₁ is made wider than the second width W₂ of the second portion 45b₂.

Also in the warp suppression film 45b of Modification 1-9, the area at the corner portion Cr of the bonding surface 40 can be selectively increased. Therefore, it is possible to further strengthen the countermeasure against the warp of the bonding surface 40a on the corner portion Cr side as compared with the warp suppression film 45b of the above-described first embodiment.

### Modification 1-10

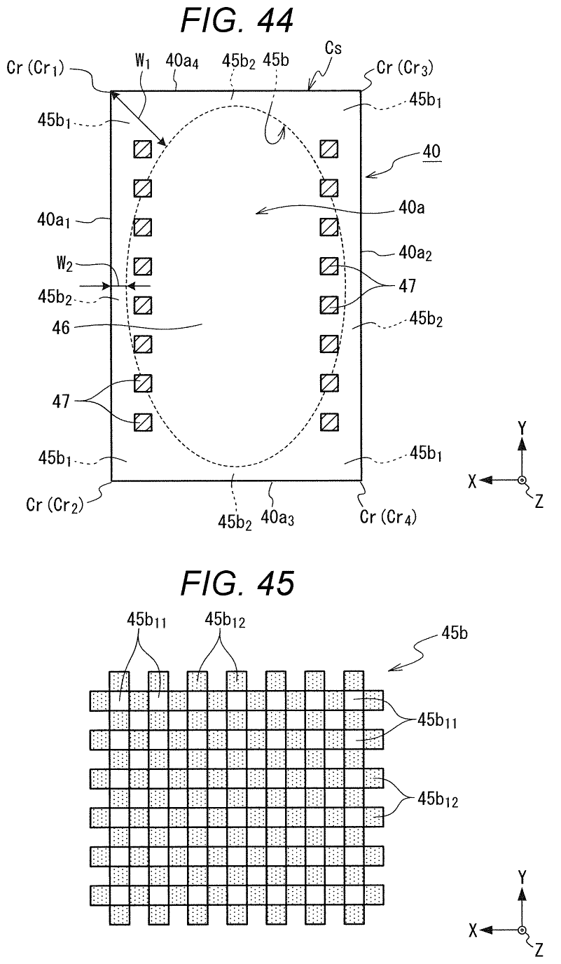

FIG. 44 is a plan view schematically illustrating a configuration of a second semiconductor chip according to Modification 1-10 of the first embodiment of the present technology.

In Modification 1-10, the planar shape of the inner-side end portion of the warp suppression film 45b is made elliptical, and the first width W₁ of the first portion 45b₁ is made wider than the second width W₂ of the second portion 45b₂.

Also in the warp suppression film 45b of Modification 1-9, the area at the corner portion Cr of the bonding surface 40 can be selectively increased. Therefore, it is possible to further strengthen the countermeasure against the warp of the bonding surface 40a on the corner portion Cr side as compared with the warp suppression film 45b of the above-described first embodiment.

### Modifications 1-11 to 1-14

FIGS. 45 to 48 are views schematically illustrating mesh-like patterns as film quality of the warp suppression film 45b according to Modifications 1-11 to 1-14 of the first embodiment of the present technology.

The warp suppression film 45b may be configured by a normal solid film or may be configured in mesh-like planar patterns illustrated in FIGS. 45 to 48, as its own film quality (film state).

The mesh-like planar pattern of Modification 1-11 illustrated in FIG. 45 has a checkered pattern in which an opening 45b₁₁ and a film portion 45b₁₂ are alternately and repeatedly arranged in each of the X direction and the Y direction.

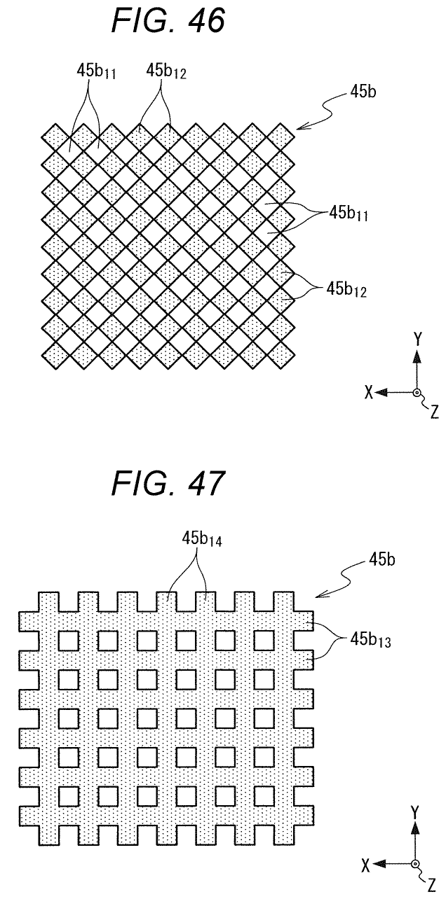

Furthermore, the mesh-like planar pattern of Modification 1-12 illustrated in FIG. 46 has a checkered pattern in which an opening 51b₁₁ and a film portion 45b₁₂ are alternately and repeatedly arranged in an oblique direction with respect to the X direction and the Y direction.

Furthermore, the mesh-like planar pattern of Modification 1-13 illustrated in FIG. 47 is a lattice-like planar pattern in which a plurality of first film portions 51b₁₃ extending in the X direction and arranged at predetermined intervals in the Y direction and a plurality of second film portions 51b₁₄ extending in the Y direction and arranged at predetermined intervals in the X direction intersect in the same plane.

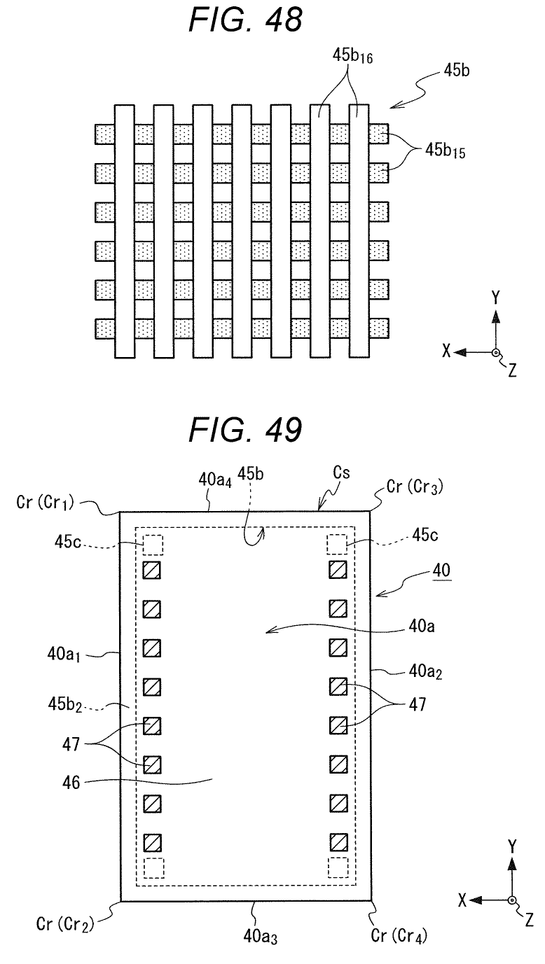

Furthermore, the mesh-like planar pattern of Modification 1-14 illustrated in FIG. 48 is a mesh-like planar pattern in which a first film portion 45b₁₅ and a second film portion 45b₁₆ in different layers intersect in a lattice-like manner in plan view.

Also in Modifications 1-11 to 1-14, effects similar to those of the above-described first embodiment can be obtained.

Furthermore, the mesh-like patterns of Modifications 1-11 to 1-14 can also be applied to the warp suppression film 45b of Modifications 1-2 to 1-10 described above.

### Modification 1-15

FIG. 49 is a plan view schematically illustrating a configuration of the second semiconductor chip 40 according to Modification 1-15 of the first embodiment of the present technology.

In Modification 1-15, a warp suppression film 45c is selectively provided in the vicinity of the corner portion Cr of the bonding surface 42a in plan view, separately from the above-described warp suppression film 45b of the first embodiment. The warp suppression film 45c is separated from the warp suppression film 45b in plan view.

The warp suppression film 45c is not limited thereto, but has, for example, a quadrangular planar shape and is disposed inside the warp suppression film 45b. The warp suppression film 45c is formed in the same layer as the warp suppression film 45c, for example, in the inner layer of the multilayer wiring layer 45.

As the warp suppression film 45c, an insulating film such as a silicon nitride (SiN) film, a metal film such as an aluminum (Al) film, a copper (Cu) film, or an alloy film thereof, or a resin film can be used, similarly to the warp suppression film 45b. Also in Modification 1-15, the warp suppression film 45b is configured by, for example, a silicon nitride film.

The warp suppression film 45c is preferably configured to have a planar size larger than the planar size of the bonding metal pad 47. Furthermore, the warp suppression film 45c is preferably disposed outside the bonding metal pad 47, that is, on the side of the side (40a1, 40a2, 40a3, or 40a4) of the bonding surface 40a with respect to the bonding metal pad 47 and inside the warp suppression film 45c.

In Modification 1-15, the warp suppression film 45c different from the tangential warp suppression film 45b is provided in the vicinity of the corner portion Cr of the bonding surface 40a in plan view, so that it is possible to further strengthen the countermeasure against warp of the bonding surface 40a on the corner portion Cr side as compared with the above-described first embodiment.

### Modification 1-16

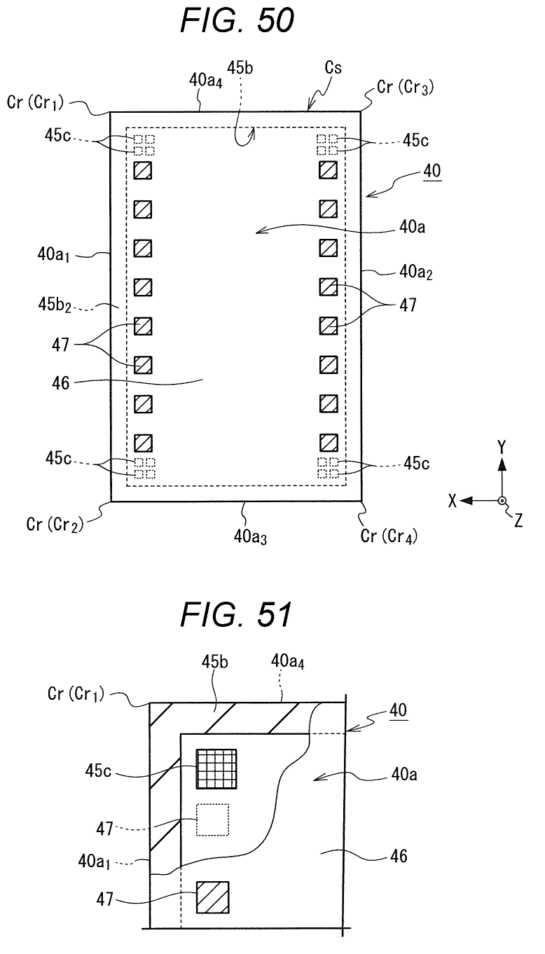

FIG. 50 is a plan view schematically illustrating a configuration of the second semiconductor chip 40 according to Modification 1-16 of the first embodiment of the present technology.

As illustrated in FIG. 50, in Modification 1-16, a plurality of warp suppression films 45c is selectively provided in the vicinity of the corner portion Cr of the bonding surface 42a in plan view, separately from the above-described warp suppression film 45b of the first embodiment. Also in Modification 1-16, it is possible to further strengthen the countermeasure against the warp of the bonding surface 40a on the corner portion Cr side as compared with the above-described first embodiment, similarly to Modification 1-15.

### Modification 1-17

FIG. 51 is a plan view of a main part schematically illustrating a configuration of the second semiconductor chip 40 according to Modification 1-17 of the first embodiment of the present technology.

As illustrated in FIG. 51, in Modification 1-17, as a film quality state of the warp suppression film 45b, the warp suppression film 45b is configured by a normal solid film, and the warp suppression film 45c is configured in a mesh-like planar pattern. Also in Modification 1-17, it is possible to further strengthen the countermeasure against the warp of the bonding surface 40a on the corner portion Cr side as compared with the above-described first embodiment, similarly to Modification 1-15.

Note that, contrary to Modification 1-17, the warp suppression film 45b may be configured in a mesh-like planar pattern, and the warp suppression film 45c may be configured by a normal solid film. Furthermore, both the warp suppression films 45b and 45c may be configured by a normal solid film, or both the warp suppression films 45b and 45c may be configured in a mesh-like pattern.

### Modification 1-18

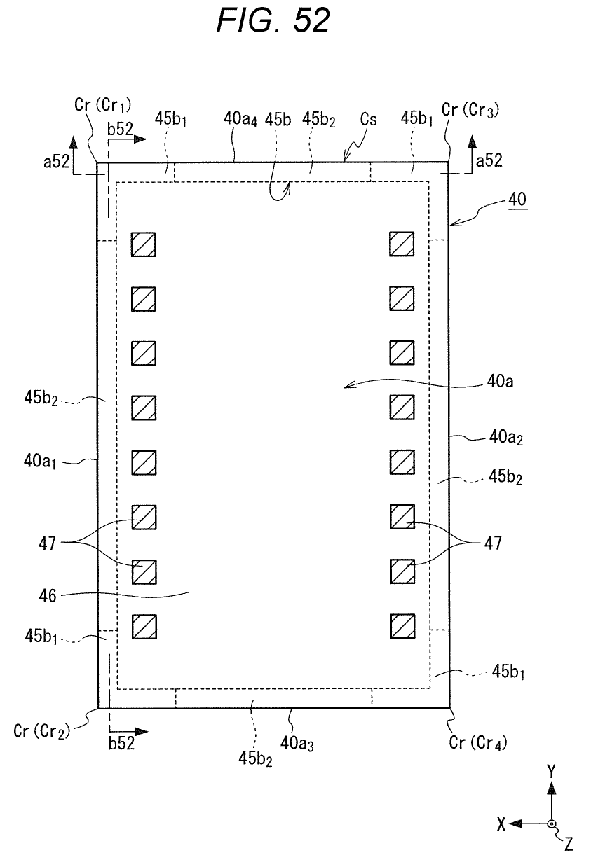

FIG. 52 is a plan view schematically illustrating a configuration of the second semiconductor chip 40 according to Modification 1-18 of the first embodiment of the present technology.

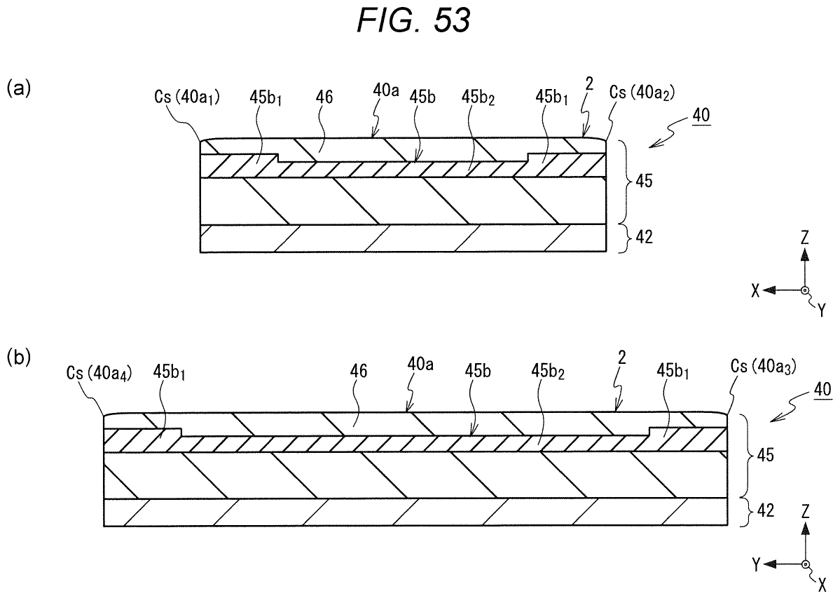

FIG. 53 is cross-sectional views schematically illustrating a configuration of the second semiconductor chip 40 according to Modification 1-18 of the first embodiment of the present technology (FIG. 53(a) is a longitudinal cross-sectional view schematically illustrating a longitudinal cross-sectional structure taken along cutting line a52-a52 in FIG. 52, and FIG. 53(b) is a longitudinal cross-sectional view schematically illustrating a longitudinal cross-sectional structure taken along cutting line b52-b52 in FIG. 52).

As illustrated in FIGS. 52 and 53((a) and (b)), in Modification 1-18, the film thickness of the warp suppression film 45b is different between the first portion 45b₁ and the second portion 45b₂. That is, in the warp suppression film 45b of Modification 1-18, the film thickness of the first portion 45b₁ adjacent to a corner portion Cr₁ of the bonding surface 40a in plan view is larger than the film thickness of the second portion 45b₂ adjacent to the side of the bonding surface 40a in plan view.

Also in Modification 1-18, it is possible to further strengthen the countermeasure against the warp of the bonding surface 40a on the corner portion Cr side as compared with the above-described first embodiment.

### Modification 1-19

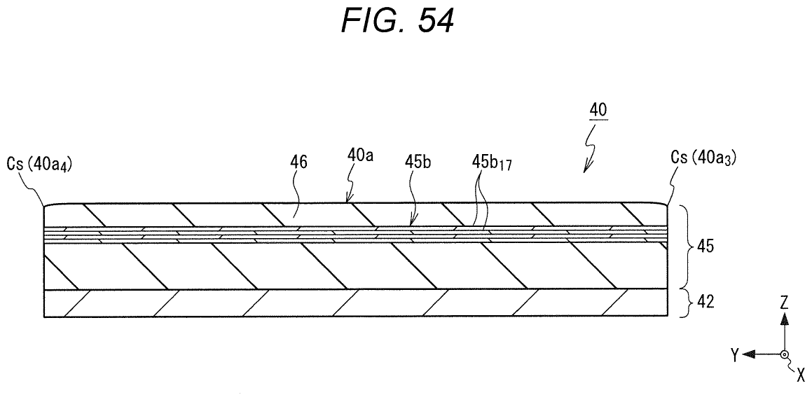

FIG. 54 is a longitudinal cross-sectional view schematically illustrating a longitudinal cross-sectional structure at the same position as cutting line b52-b52 illustrated in FIG. 52 in the second semiconductor chip 40 according to Modification 1-19 of the first embodiment of the present technology.

As illustrated in FIG. 54, in Modification 1-19, the warp suppression film 45b is configured by a stacked film in which a plurality of films is stacked in multiple stages. As the films, films of the same substance may be stacked in multiple stages, or films of different substances may be stacked in multiple stages.

Also in Modification 1-18, effects similar to those of the above-described first embodiment can be obtained.

Note that although not illustrated, Modification 1-19 can be combined with each of Modification 1-1 to 1-18 described above.

### Second Embodiment

In a second embodiment, an example in which a warp suppression film is provided in a bonding surface 40a of a second semiconductor chip 40 and in each of inner layers of a multilayer wiring layer 45 will be described.

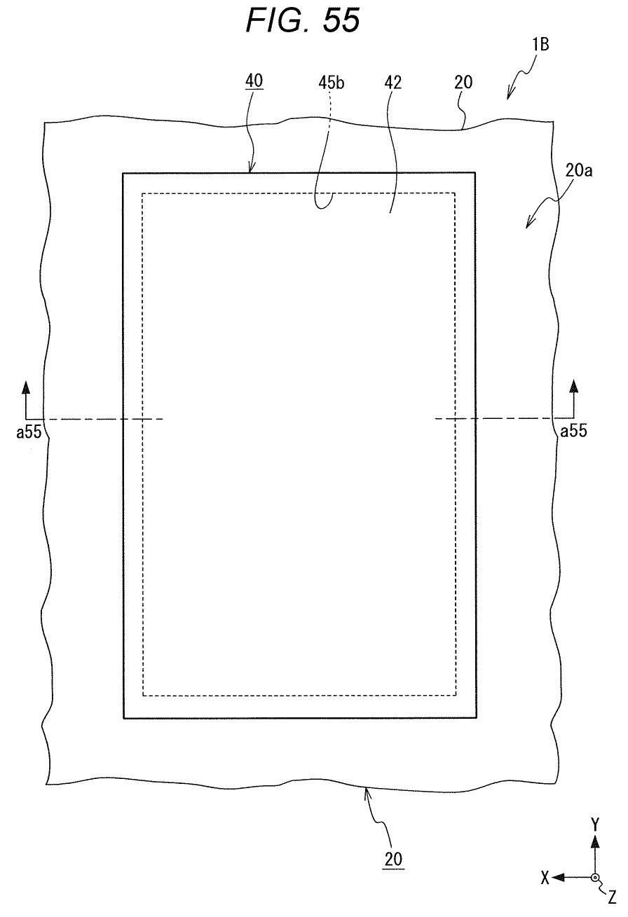

FIG. 55 is a plan view of a main part schematically illustrating a configuration example of a solid-state imaging device 1B according to the second embodiment of the present technology.

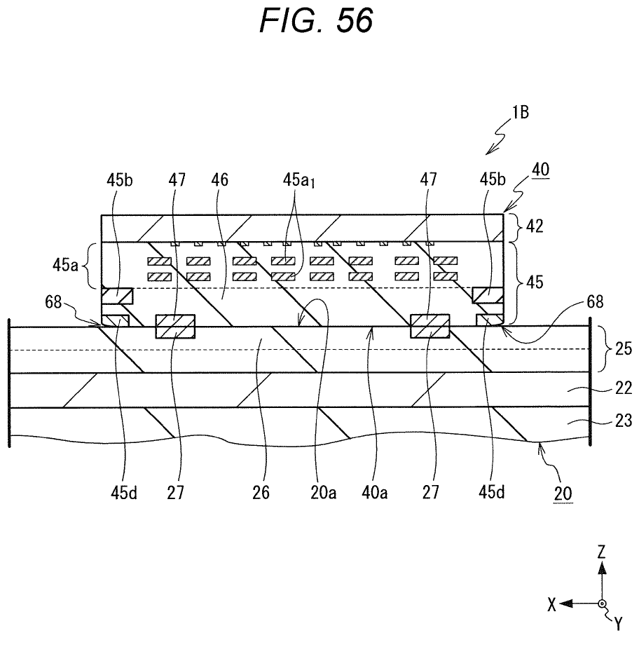

FIG. 56 is a longitudinal cross-sectional view schematically illustrating a longitudinal cross-sectional structure taken along cutting line a55-a55 in FIG. 55.

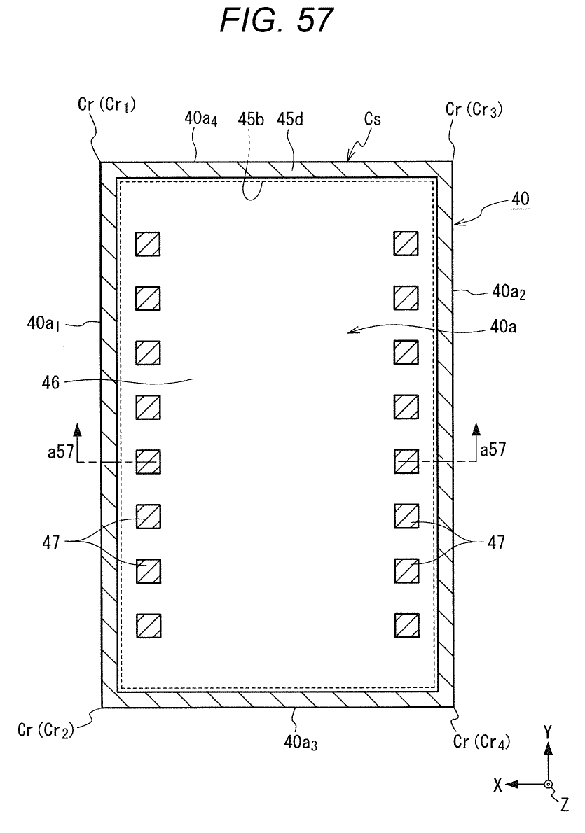

FIG. 57 is a plan view schematically illustrating a bonding surface side of the second semiconductor chip 40.

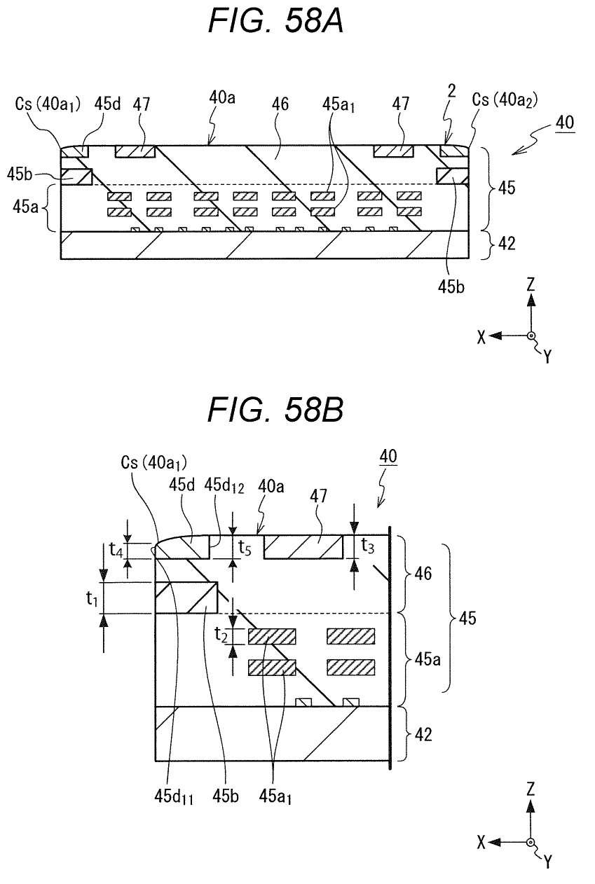

FIG. 58A is a longitudinal cross-sectional view schematically illustrating a longitudinal cross-sectional structure taken along cutting line a57-a57 in FIG. 57.

FIG. 58B is a partially enlarged longitudinal cross-sectional view of FIG. 58A.

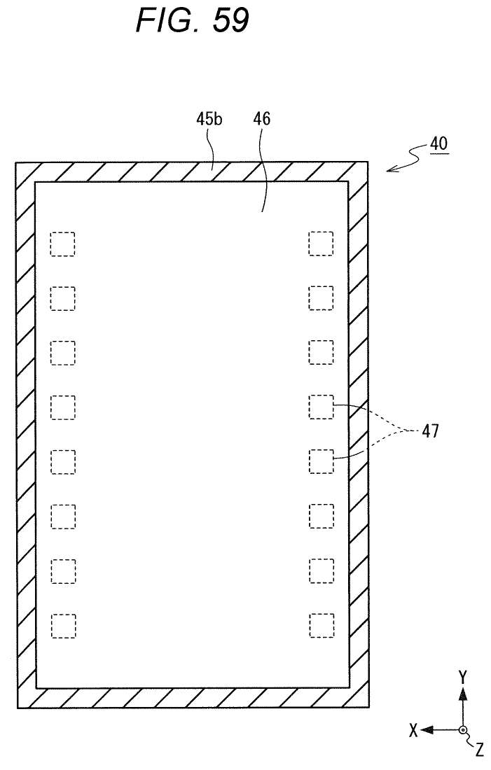

FIG. 59 is a plan view schematically illustrating a planar shape of a warp suppression film 45b provided in an inner layer of the multilayer wiring layer 45 of the second semiconductor chip 40.

Note that FIG. 55 corresponds to FIG. 7 of the above-described first embodiment.

As illustrated in FIGS. 55 and 56, the solid-state imaging device 1B according to the second embodiment of the present technology basically has a configuration similar to the solid-state imaging device 1A according to the above-described first embodiment, and a configuration of the second semiconductor chip 40 is different.

That is, as illustrated in FIGS. 56 and 57, the second semiconductor chip 40 according to the second embodiment further includes a warp suppression film 45d as a warp suppression portion in the bonding surface 40a. The other configuration is roughly similar to the configuration of the above-described first embodiment.

As illustrated in FIGS. 56, 57, and 58A, the warp suppression film 45d is provided in the multilayer wiring layer 45. That is, the multilayer wiring layer 45 of the second embodiment includes a multistage stacked portion 45a, the warp suppression film 45b, an insulating layer 46, and a bonding metal pad 47, and further includes the warp suppression film 45d.

The insulating layer 46 is an uppermost insulating layer of the multilayer wiring layer 45, and a surface of the insulating layer 46 is the bonding surface 40a of the second semiconductor chip 40, as described above. That is, the bonding surface 40a of the second semiconductor chip 40 according to the second embodiment includes the uppermost insulating layer 46 of the multilayer wiring layer 45, the bonding metal pads 47 interspersed with the insulating layer 46, and the warp suppression film 45d. That is, the semiconductor chip 40 of the second embodiment includes the warp suppression film 45b provided in the inner layer of the multilayer wiring layer 45 and the warp suppression film 45d provided in the bonding surface 40a of the multilayer wiring layer 45.

Similarly to the bonding metal pad 47, the warp suppression film 45d is provided in the insulating layer 46 of the multilayer wiring layer 45 in a state where a bonding surface side is exposed. Then, the bonding surface 40a is substantially flat where a step between the warp suppression film 45d and the bonding metal pad 47, and the insulating layer 46 is as small as possible.

The warp suppression film 45d is not limited thereto, but is formed in the same process as the bonding metal pad 47, for example, and is configured by the same metal material as the bonding metal pad 47.

As illustrated in FIG. 57, the warp suppression film 45d is provided in at least a part of the bonding surface 40a of the second semiconductor chip 40 on a side of a peripheral edge portion Cs. In the second embodiment, as illustrated in FIG. 57, the warp suppression film 45d is provided in the second semiconductor chip 40 on sides of four sides (40a₁, 40a₂, 40a₃, and 40a₄) of the bonding surface 40a, and has an annular planar pattern continuously extending along the four sides (40a₁, 40a₂, 40a₃, and 40a₄), similarly to the warp suppression film 45b of the above-described first embodiment. Then, the warp suppression film 45d overlaps with the sides (40a₁, 40a₂, 40a₃, and 40a₄) of the bonding surface 40a of the second semiconductor chip 40 in plan view, and is exposed from a side surface of the second semiconductor chip 40, that is, from a side surface of the multilayer wiring layer 45. That is, the warp suppression film 45d is provided over the bonding surface 40a and the side surface of the multilayer wiring layer 45.

Similarly to the warp suppression film 45b, the warp suppression film 45d is disposed in an outer peripheral edge portion of the second semiconductor chip 40 (on the side of the peripheral edge portion Cs), thereby controlling local film stress of the second semiconductor chip 40 and suppressing a warp of the second semiconductor chip 40. For the warp suppression film 45d, a material having a linear expansion coefficient different from the surrounding multistage stacked portion 45a and insulating layer 46 is used. Furthermore, rigidity is increased by using a dense film having a low shrinkage rate for the warp suppression film 45d. As a result, it is possible to suppress the warp of the peripheral portion of the semiconductor chip 40 by the difference in the linear expansion coefficient.

As illustrated in FIG. 58B, in the warp suppression film 40d, a thickness t₄ of an outer-side end portion 40d₁₁ located on the side of the side (the side of the side 40a₁ in FIG. 58B) of the bonding surface 40a is thinner than a thickness t₅ of an inner-side end portion 40d₁ located on an opposite side of the outer-side end portion 40d₁₁. (t₄<t₅). In the second embodiment, a bonding surface (an upper surface in FIG. 58B) of the warp suppression film 45d has a curved surface shape, but may have a planar shape or a stepped shape. The configuration related to the thickness of the warp suppression film 40d (t₄<t₅) is for suppressing generation of voids generated in the bonding surface 40a of the second semiconductor chip 40 on the peripheral edge portion Cs side due to a progressive change in a bonding wave when the bonding surface 40a of the second semiconductor chip 40 is crimped (pressure-bonded) to a bonding surface 20a of a wafer stacked body 60 so that the bonding wave is generated from a center portion toward the peripheral portion of the second semiconductor chip 40 in a two-dimensional plane as illustrated in FIG. 29.

Furthermore, as illustrated in FIG. 58B, to enable control of local film stress of the second semiconductor chip 40, the thickness t₅ of at least the inner-side end portion 40d₁₂ of the outer-side end portion 40d₁₁ and the inner-side end portion 40d₁₂ is preferably larger than a thickness t₂ of wiring 45a₁ of the multilayer wiring layer 45 (t₄>t₂) in the warp suppression film 45d. Then, the thickness t₅ of the inner-side end portion 40d₁₂ of the warp suppression film 45d is more preferably thicker than a thickness t₃ of the bonding metal pad 47 of the multilayer wiring layer 45.

As illustrated in FIG. 59, the warp suppression film 45a of the second embodiment is also provided in the bonding surface 40a of the second semiconductor chip 40 on the sides of the four sides (40a₁, 40a₂, 40a₃, and 40a₄) and has an annular planar pattern continuously extending along the four sides (40a₁, 40a₂, 40a₃, and 40a₄), similarly to the above-described first embodiment. Therefore, the warp suppression films 45d and 45b of the second embodiment extend along the peripheral edge portion Cs of the semiconductor chip 40 in a state of overlapping with each other in plan view.

### Effects of Second Embodiment

The second semiconductor chip 40 according to the second embodiment includes the two warp suppression films 45d and 45b. Therefore, even if the thickness of a semiconductor layer 42 of the second semiconductor chip 40 is reduced after the bonding surface 20a of the wafer stacked body 60 (the bonding surface 20a of the first semiconductor chip 20) and the bonding surface 40a of the second semiconductor chip 40 are bonded by direct bonding in a process of manufacturing the solid-state imaging device 1B, it is possible to further suppress a warp of the second semiconductor chip 40 due to a decrease in the rigidity of the second semiconductor chip 40, and it is possible to suppress cracking, chipping, and the like of the second semiconductor chip 40, which cause a decrease in a manufacturing yield of the solid-state imaging device 1B. Therefore, the solid-state imaging device 1B according to the first embodiment can further improve the manufacturing yield.

Furthermore, in the warp suppression film 45d according to the second embodiment, the thickness t₄ of the outer-side end portion 40d₁₁ located in the bonding surface 40a on the side of the side (the side of the side 40a₁ in FIG. 58B) is thinner than the thickness t₅ of the inner-side end portion 40d₁₂ located on the opposite side to the outer-side end portion 40d₁₁. (t₄<t₅).

Therefore, in the process of manufacturing the solid-state imaging device 1B, when the bonding surface 20a of the wafer stacked body 60 and the bonding surface 40a of the second semiconductor chip 40 are bonded by surface activation bonding, even if the bonding wave arriving at the side (40a₁, 40a₂, 40a₃, or 40a₄) of the bonding surface 40a precedes the corner portion Cr (Cr₁, Cr₂, Cr₃, or Cr₄) of the bonding surface 40a, which is an arrival position of the bonding wave spreading in a circular shape, a vacant space 68 formed by the warp suppression film 45d is formed in the bonding surface 40a on the corner portion Cr side, so that a gas such as an inert gas or air in atmosphere can be released. Therefore, according to the solid-state imaging device 1B of the second embodiment, generation of voids can be suppressed.

Furthermore, since generation of voids can be suppressed, it is possible to further improve the manufacturing yield and reliability of the solid-state imaging device 1B.

Note that, in the above-described second embodiment, the case where the warp suppression film 45d is configured by the same material as the metal bonding pad 47 has been described, but the warp suppression film may be configured by another material. Note that the warp suppression film 45d is preferably configured by a material different from the insulating layer of the multistage stacked portion 45a of the multilayer wiring layer 45 or the uppermost insulating layer 46 of the multilayer wiring layer 45, similarly to the warp suppression film 45b. For example, as the warp suppression film 45d, an insulating film such as a silicon nitride (SiN) film, a metal film such as an aluminum (Al) film, a copper (Cu) film, or an alloy film thereof, or a resin film can be used. In the first embodiment, the warp suppression film 45d is configured by, for example, a silicon nitride film.

### Modifications of Second Embodiment

### Modification 2-1

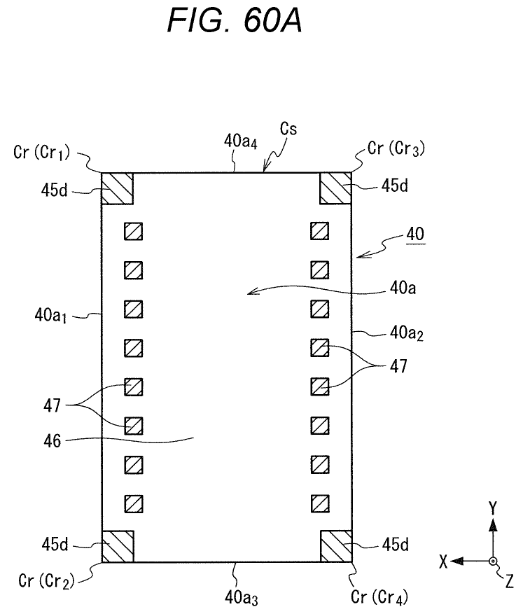

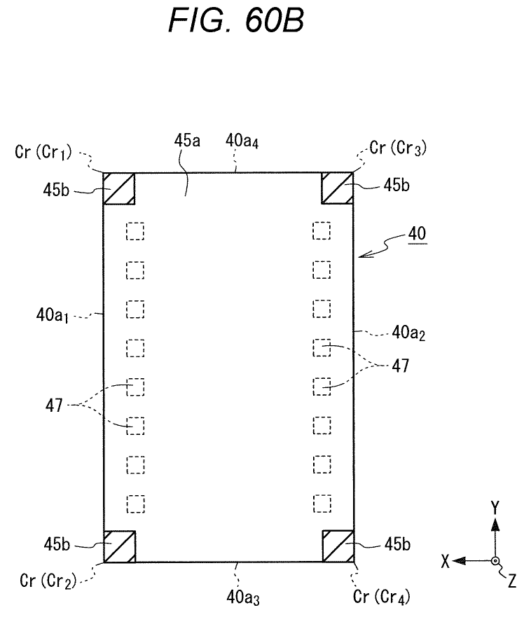

FIG. 60A is a plan view schematically illustrating a planar pattern of the warp suppression film 45d included in the bonding surface 45a of the second semiconductor chip 40 according to Modification 2-1 of the second embodiment of the present technology.

FIG. 60B is a plan view schematically illustrating a planar pattern of a warp suppression film included in the inner layer of the multilayer wiring layer 45 of the second semiconductor chip 40 according to Modification 2-1 of the second embodiment of the present technology.

As illustrated in FIGS. 60A and 60B, in the modification 2-1, in the semiconductor chip 40, each of the warp suppression films 45d and 45b is selectively provided in the vicinity of the corner portion Cr of the bonding surface 42a in plan view.

In Modification 2-1, it is possible to further selectively strengthen the countermeasure against the warp of the bonding surface 40a of the semiconductor chip 40 on the corner portion Cr side as compared with the above-described second embodiment.

### Modification 2-2

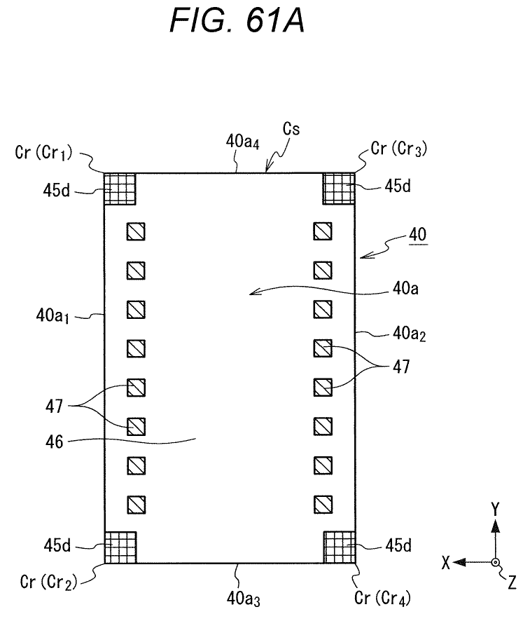

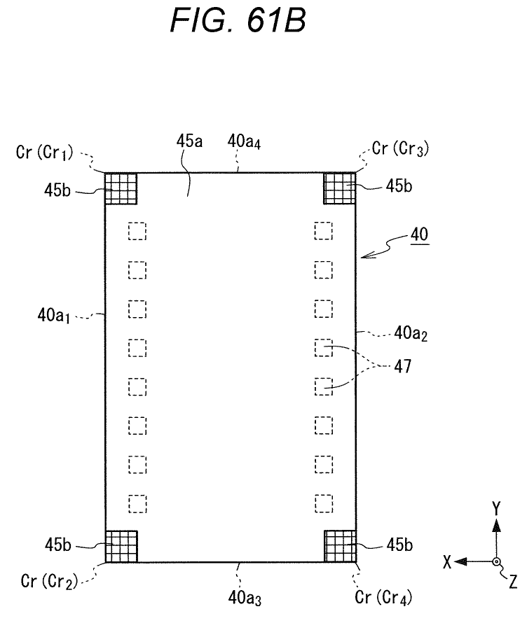

FIG. 61A is a plan view schematically illustrating a planar pattern of the warp suppression film included in the bonding surface of the second semiconductor chip according to Modification 2-2 of the second embodiment of the present technology.

FIG. 61B is a plan view schematically illustrating a planar pattern of the warp suppression film included in the inner layer of the multilayer wiring layer of the second semiconductor chip according to Modification 2-2 of the second embodiment of the present technology.

As illustrated in FIGS. 61A and 61B, in Modification 2-2, each of the warp suppression films 45d and 45c is configured in a mesh-like planar pattern illustrated in Modification 1-11 described above.

Also in Modification 2-2, it is possible to further selectively strengthen the countermeasure against the warp of the bonding surface 40a of the semiconductor chip 40 on the corner portion Cr side as compared with the above-described second embodiment.

### Other Modifications

In the above-described second embodiment, the case where the warp suppression films 45d and 45c are configured in the annular plane pattern has been described, but the modifications of the above-described first embodiment can also be applied to the warp suppression films 45d and 45c.

### Third Embodiment

In a third embodiment, an example in which a warp suppression film is provided over a bonding surface 40a and a side surface of a semiconductor chip 40 will be described.

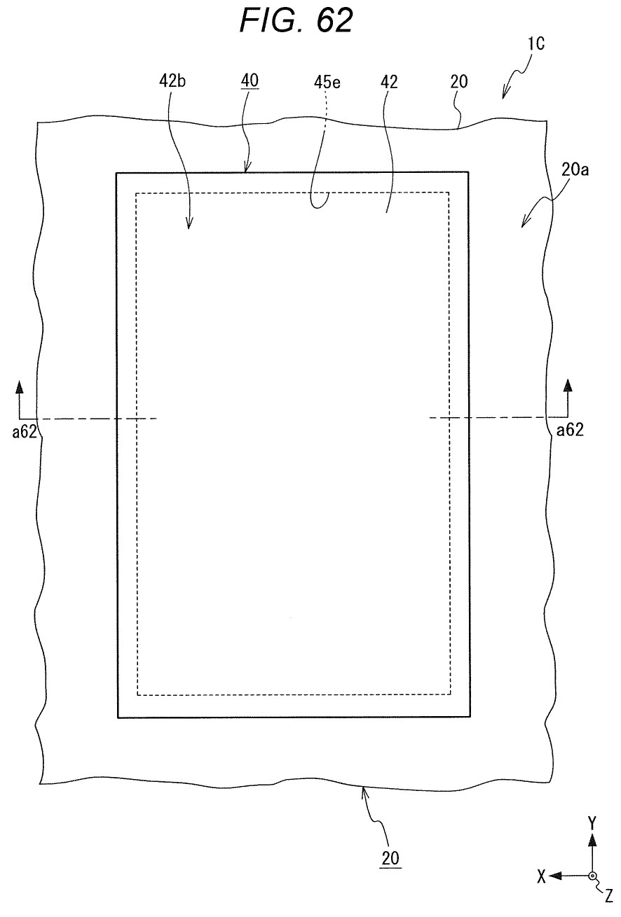

FIG. 62 is a plan view of a main part schematically illustrating a configuration example of a solid-state imaging device 1C according to the third embodiment of the present technology.

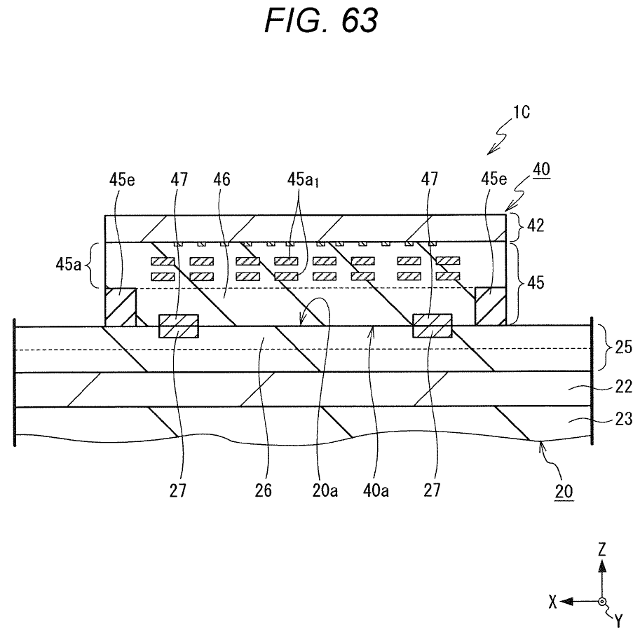

FIG. 63 is a longitudinal cross-sectional view schematically illustrating a longitudinal cross-sectional structure taken along cutting line a62-a62 in FIG. 62.

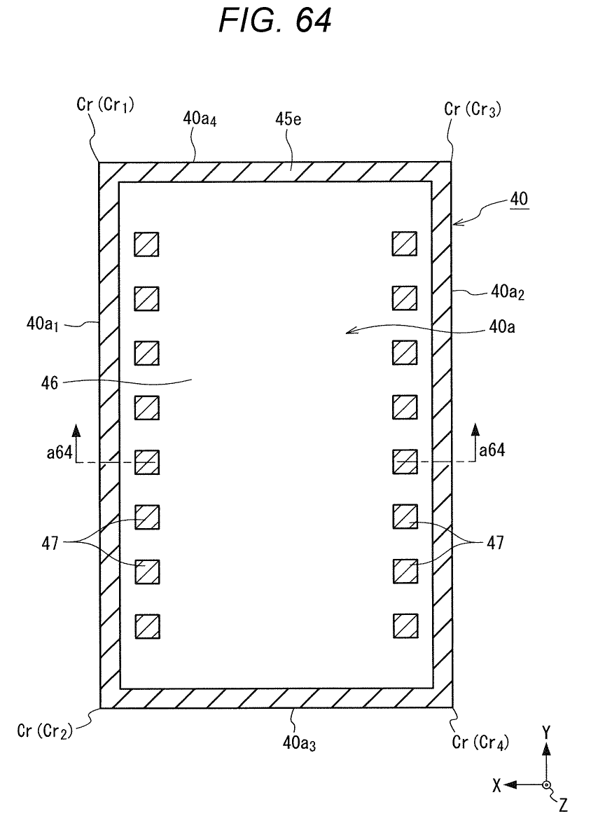

FIG. 64 is a plan view schematically illustrating a bonding surface side of the second semiconductor chip.

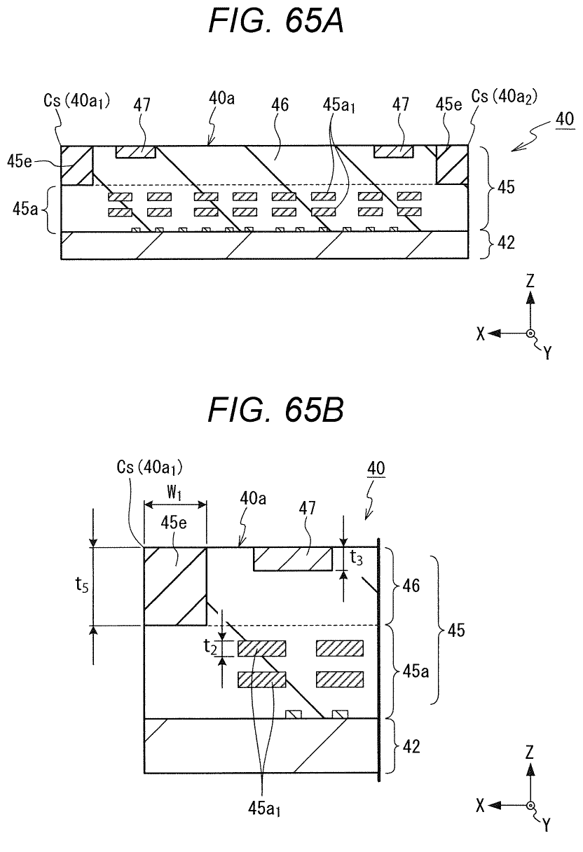

FIG. 65A is a longitudinal cross-sectional view schematically illustrating a longitudinal cross-sectional structure taken along cutting line a64-a64 in FIG. 64.

FIG. 65B is a partially enlarged longitudinal cross-sectional view of FIG. 65A.

Note that FIG. 62 corresponds to FIG. 7 of the above-described first embodiment.

As illustrated in FIGS. 62 to 65B, the solid-state imaging device 1C according to the third embodiment of the present technology basically has a configuration similar to the solid-state imaging device 1A according to the above-described first embodiment, and a configuration of the second semiconductor chip 40 is different.

That is, as illustrated in FIGS. 62 to 65B, the second semiconductor chip 40 according to the third embodiment includes a warp suppression film 45e provided over a second bonding surface 45b and a side surface of a multilayer wiring layer 45 instead of the warp suppression film 45b as the warp suppression portion illustrated in FIG. 8 of the above-described first embodiment. The other configuration is roughly similar to the configuration of the above-described first embodiment.

As illustrated in FIGS. 62 to 65B, the warp suppression film 45e is provided over the bonding surface 40a and the side surface of the multilayer wiring layer 45, that is, the bonding surface 40a and the side surface of the second semiconductor chip 40. Then, the multilayer wiring layer 45 of the third embodiment includes the multilayer wiring layer 45a, the warp suppression film 45e, an insulating layer 46, and a bonding metal pad 47.

Similarly to the bonding metal pad 47, the warp suppression film 45e is provided in the multilayer wiring layer 45 in a state where a bonding surface side is exposed. Then, the bonding surface 40a is substantially flat where a step between the warp suppression film 45e and the bonding metal pad 47, and the insulating layer 46 is as small as possible.

As illustrated in FIGS. 62 to 65B, the warp suppression film 45e is selectively provided in the bonding surface 40a of the second semiconductor chip 40 on a side of a peripheral edge portion Cs in plan view. Although not illustrated, in the third embodiment, as illustrated in FIGS. 62 to 65B, the warp suppression film 45e is provided in the bonding surface 40a of the second semiconductor chip 40 on sides of four sides (40a₁, 40a₂, 40a₃, and 40a₄), and has an annular planar pattern continuously extending along the four sides (40a₁, 40a₂, 40a₃, and 40a₄), similarly to the warp suppression film 45b of the above-described first embodiment, for example. Then, the warp suppression film 45e overlaps with the sides (40a₁, 40a₂, 40a₃, and 40a₄) of the bonding surface 40a of the second semiconductor chip 40 in plan view, and is exposed from the side surface of the second semiconductor chip 40.

Similarly to the above-described warp suppression film 45b, the warp suppression film 45e is disposed in an outer peripheral edge portion of the second semiconductor chip 40 (on a side of a peripheral edge portion Cs), thereby controlling local film stress of the second semiconductor chip 40 and suppressing a warp of the second semiconductor chip 40. For the warp suppression film 45e, a material having a linear expansion coefficient different from the surrounding multistage stacked portion 45a and insulating layer 46 is used. Furthermore, rigidity is increased by using a dense film having a low shrinkage rate for the warp suppression film 45d. As a result, it is possible to suppress the warp of the semiconductor chip 40 on a peripheral portion side (the side of the peripheral edge portion Cs) by the difference in the linear expansion coefficient.

The warp suppression film 45e is bonded to a bonding surface 20a of a first semiconductor chip 20 (the bonding surface 20a of a chip formation region 65 of a wafer stacked body 60) by direct bonding. Here, in a case where the bonding surface 20a of the second semiconductor chip 20 is configured by a silicon oxide film, bonding strength between the bonding surface 20a of the base member 20 and the warp suppression film 45e can be increased by configuring the warp suppression film 45e by silicon nitride. Meanwhile, a silicon nitride film is useful as the warp suppression film 45e that suppresses the warp of the second semiconductor chip 40. Therefore, by providing the warp suppression film 45e made of a silicon nitride film on the peripheral edge portion Cs side of the bonding surface 40a of the second semiconductor chip 40 and directly bonding the warp suppression film 45e to the bonding surface 20a of the first semiconductor chip 20, it is possible to increase the bonding strength between the first semiconductor chip 20 and the peripheral edge portion Cs side of the second semiconductor chip 40 while suppressing the warp of the second semiconductor chip 40. Thereby, it is possible to suppress defects such as peeling of the second semiconductor chip 40 from the first semiconductor chip 20, and thus it is possible to improve a manufacturing yield of the solid-state imaging device 1C.

As illustrated in FIG. 65B, the warp suppression film 45e has a thickness t5 larger than a width W3 (t5>W3). With such a configuration, internal stress of the second semiconductor chip 40 can be further increased, so that a warp suppressing effect can be further enhanced as compared with the first embodiment.

Note that, in the above-described third embodiment, the case of using the warp suppression film 45e made of a silicon nitride film has been described. However, the film is not limited to a silicon nitride film as long as the film can suppress the warp of the second semiconductor chip 40 and increase the bonding strength between the bonding surface 20a of the first semiconductor chip 20 and the bonding surface 40a of the second semiconductor chip 40.

### Modifications of Third Embodiment

### Modification 3-1

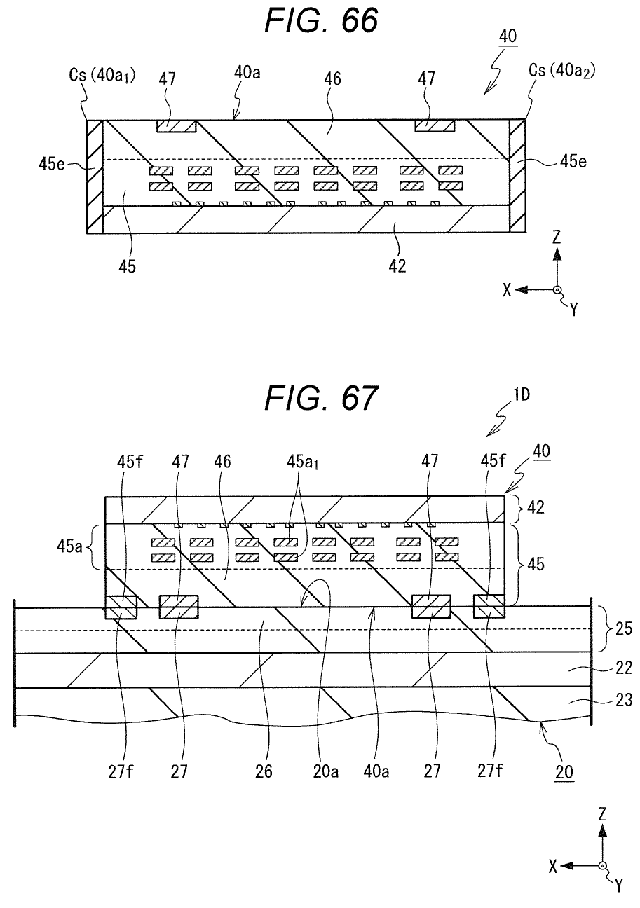

FIG. 66 is a longitudinal cross-sectional view schematically illustrating a longitudinal cross-sectional structure of the second semiconductor chip according to Modification 3-1 of the third embodiment of the present technology.

As illustrated in FIG. 66, in Modification 3-1, the warp suppression film 45e extends over the bonding surface 40a of the semiconductor chip 40 and a back surface on an opposite side the bonding surface 40a, and covers the side surface of each of the multilayer wiring layer 45 and the semiconductor layer 42.

In the case of Modification 3-1, it is possible to further strengthen a countermeasure against the warp of the second semiconductor chip 40 as compared with the above-described first embodiment.

### Other Modifications

In the above-described third embodiment, the case where the warp suppression film 45e is configured in the annular plane pattern has been described, but the modifications of the above-described first embodiment can also be applied to the warp suppression film 45e.

### Fourth Embodiment

In a fourth embodiment, an example in which a warp suppression film 45f is formed in a same process as a bonding metal pad 47 will be described.

FIG. 67 is a longitudinal cross-sectional view schematically illustrating a configuration example of a solid-state imaging device 1D according to the fourth embodiment of the present technology.

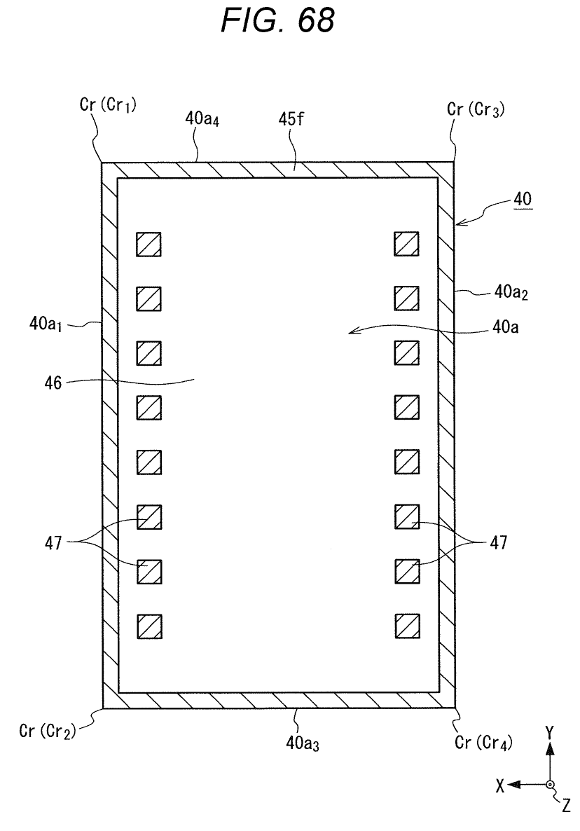

FIG. 68 is a plan view schematically illustrating a bonding surface 40a side of a second semiconductor chip 40.

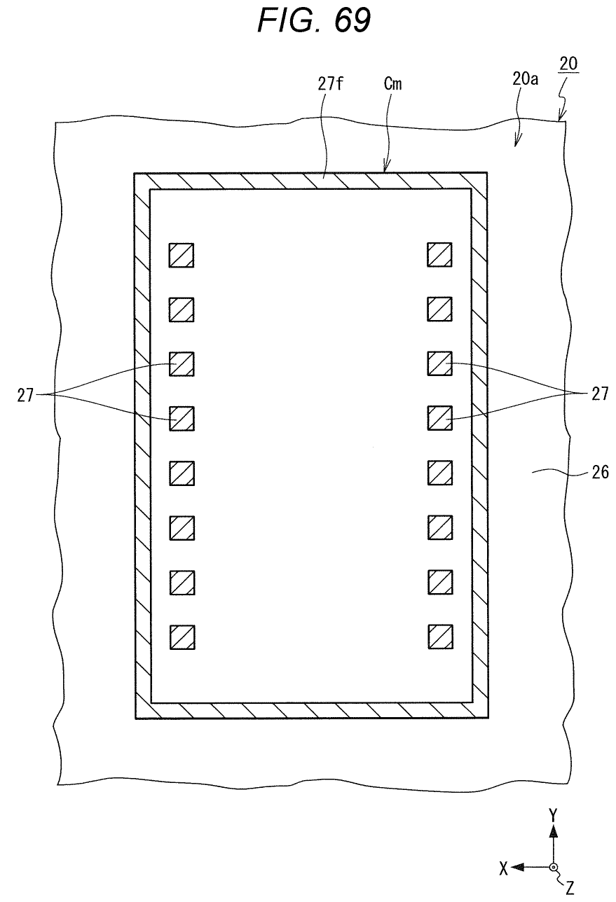

FIG. 69 is a plan view schematically illustrating a bonding surface 20a side of a first semiconductor chip 20.

As illustrated in FIGS. 67 to 69, the solid-state imaging device 1D according to the fourth embodiment of the present technology basically has a configuration similar to the solid-state imaging device 1A according to the above-described first embodiment, and a configuration of the second semiconductor chip 40 is different.

That is, as illustrated in FIGS. 67 and 68, the second semiconductor chip 40 according to the fourth embodiment includes the warp suppression film 45f provided over a second bonding surface 45b and a side surface of a multilayer wiring layer 45 instead of the warp suppression film 45b as a warp suppression portion illustrated in FIG. 8 of the above-described first embodiment. The other configuration is roughly similar to the configuration of the above-described first embodiment.

As illustrated in FIGS. 67 and 68, similarly to the bonding metal pad 47, the warp suppression film 45f is provided in the multilayer wiring layer 45 in a state where a bonding surface side is exposed. Then, the bonding surface 40a is substantially flat where a step between the warp suppression film 45f and the bonding metal pad 47, and an insulating layer 46 is as small as possible.

The warp suppression film 45f according to the fourth embodiment is not limited thereto, but is formed in the same process as the bonding metal pad 47, for example, and is configured by the same metal material as the bonding metal pad 47. Then, although not limited thereto, the warp suppression film 45f is provided in the bonding surface 40a of the second semiconductor chip 40 on sides of four sides (40a₁, 40a₂, 40a₃, and 40a₄), and has an annular planar pattern continuously extending along the four sides (40a₁, 40a₂, 40a₃, and 40a₄), similarly to the warp suppression film 45e of the above-described third embodiment. Then, the warp suppression film 45e overlaps with the sides (40a₁, 40a₂, 40a₃, and 40a₄) of the bonding surface 40a of the second semiconductor chip 40 in plan view, and is exposed from the side surface of the second semiconductor chip 40.

As illustrated in FIG. 69, the first semiconductor chip 20 of the fourth embodiment includes a dummy pad 27f in the bonding surface 20a in correspondence with the warp suppression film 45f of the second semiconductor chip 40. The dummy pad 27f is provided on the bonding surface 20 of the first semiconductor chip 20 so as to overlap the warp suppressing film in plan view, and is configured in an annular planar pattern similar to the warp suppression film. The dummy pad 27f is formed in the same process as a bonding metal pad 27, for example, for example, and is configured by the same metal material as the bonding metal pad 27. Unlike the metal bonding pad 27, the dummy pad 27f does not perform electrical connection, and for example, no potential is supplied.

As illustrated in FIG. 67, the dummy pad 27f of the first semiconductor chip 20 and the warp suppression film 45f of the second semiconductor chip 40 are bonded by direct bonding, similarly to the bonding between the bonding surface 20a of the first semiconductor chip 20 and the bonding surface 40a of the second semiconductor chip 40.

Also in the solid-state imaging device 1D according to the fourth embodiment, similarly to the above-described third embodiment, it is possible to increase bonding strength between the first semiconductor chip 20 and a peripheral edge portion Cs side of the second semiconductor chip 40 while suppressing a warp of the second semiconductor chip 40, and it is possible to suppress a defect such as peeling of the second semiconductor chip 40 from the first semiconductor chip 20. Therefore, the solid-state imaging device 1D according to the fourth embodiment can improve a manufacturing yield.

### Modifications of Fourth Embodiment

In the above-described fourth embodiment, the case where the warp suppression film 45f is configured in the annular plane pattern has been described, but the modifications of the above-described first embodiment can also be applied to the warp suppression film 45f.

### Fifth Embodiment

In the above-described first to fourth embodiments, the cases where the warp suppression films 45b, 45c, 45d, 45e, and 45f are provided in the multilayer wiring layer 45 of the second semiconductor chip 40 as the warp suppression portion that suppresses the warp of the second semiconductor chip 40 has been described. In this fifth embodiment, a case where a warp suppression portion is provided in a semiconductor layer 42 of a second semiconductor chip 40 will be described. Then, in the fifth embodiment, a modified layer 81 with disturbed crystallinity will be described as the warp suppression portion provided in the semiconductor layer 42 of the second semiconductor chip 40.

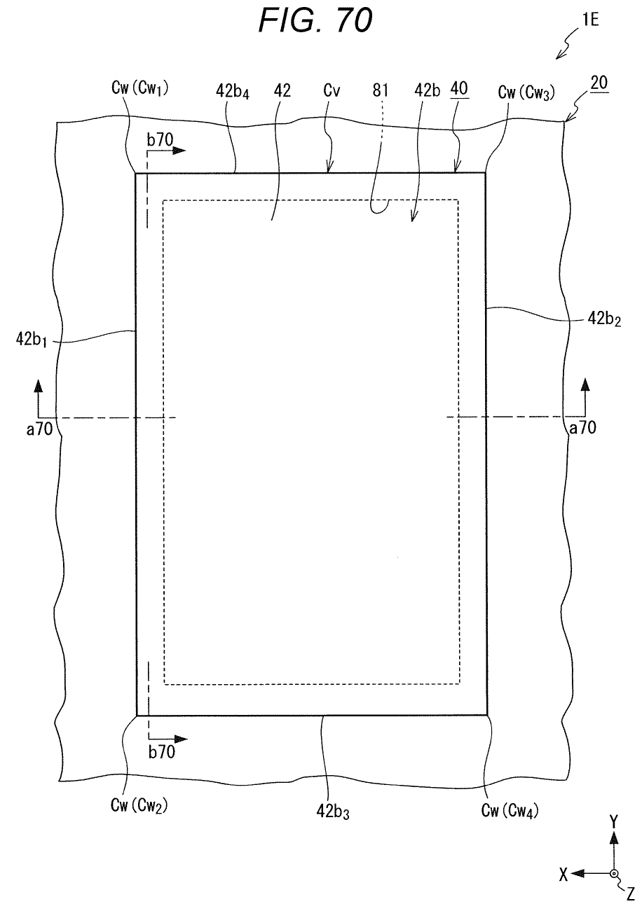

FIG. 70 is a plan view of a main part schematically illustrating a configuration example of a solid-state imaging device according to the fifth embodiment of the present technology.

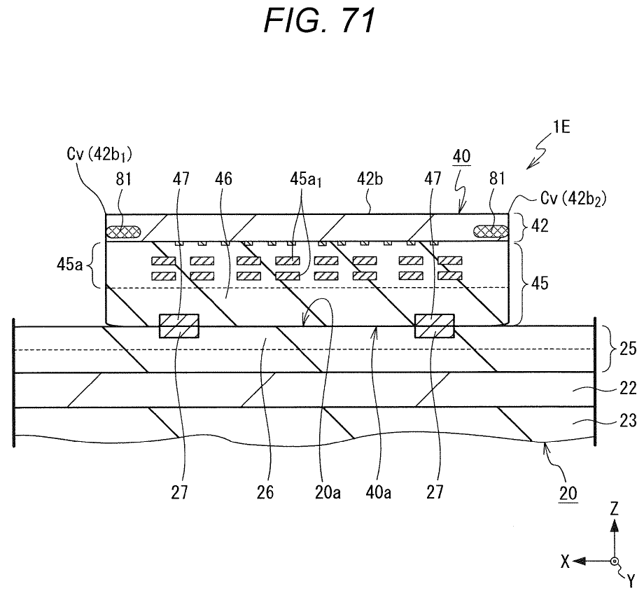

FIG. 71 is a longitudinal cross-sectional view schematically illustrating a longitudinal cross-sectional structure taken along cutting line a70-a70 in FIG. 70.

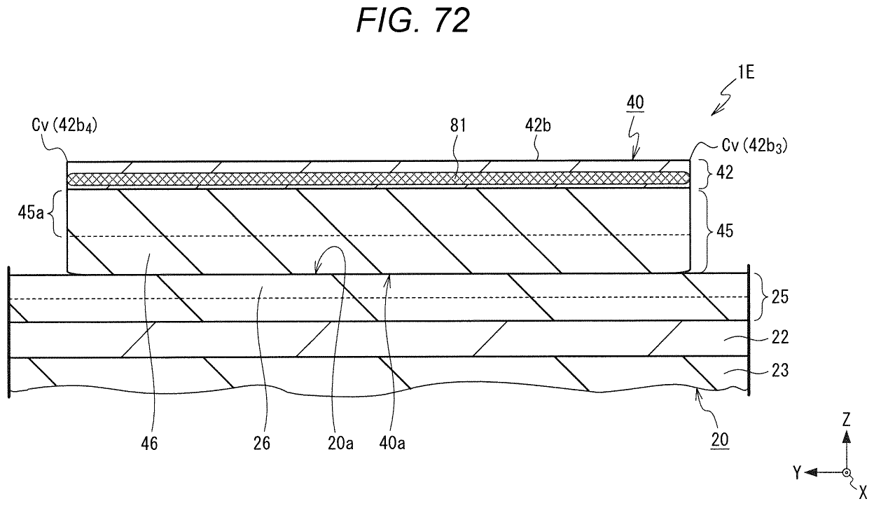

FIG. 72 is a longitudinal cross-sectional view schematically illustrating a longitudinal cross-sectional structure taken along cutting line b70-b70 in FIG. 70.

As illustrated in FIGS. 70 to 72, a solid-state imaging device 1E according to the fifth embodiment of the present technology basically has a configuration similar to the solid-state imaging device 1A according to the above-described first embodiment, and a configuration of the second semiconductor chip 40 is different.

That is, as illustrated in FIGS. 70 to 72, the second semiconductor chip 40 according to the fifth embodiment includes the modified layer 81 provided in the semiconductor layer 42 instead of a warp suppression film 45b as the warp suppression portion illustrated in FIG. 8 of the ab-described first embodiment. The other configuration is roughly similar to the configuration of the above-described first embodiment.

As described above, the second semiconductor chip 40 illustrated in FIGS. 70 to 72 includes the semiconductor layer 42 having a first surface (element formation surface or main surface) and a second surface (back surface 42b) located on opposite sides to each other in a thickness direction (Z), and a multilayer wiring layer 45 provided on the first surface side of the semiconductor layer 42. That is, the second semiconductor chip 40 of the fifth embodiment includes the multilayer wiring layer 45 including the second bonding surface 40a, the semiconductor layer 42 having the quadrangular back surface 42b on the opposite side to a side of the multilayer wiring layer 45, and the modified layer 81 as the warp suppression portion that is provided in the second semiconductor layer 42 and suppresses the warp of the second semiconductor chip 40.

Here, in the fifth embodiment, the back surface 42b of the semiconductor layer 42 may be referred to as a back surface located on an opposite side to a bonding surface 40a of the second semiconductor chip 40.

As illustrated in FIGS. 70 to 72, in the semiconductor chip 40 according to the fifth embodiment, the back surface 42b of the semiconductor layer 42 has a quadrangular shape similarly to the bonding surface 40a. Then, the back surface 42b of the semiconductor layer 42 has two sides 42b₁ and 42ba₂ located on opposite sides to each other in an X direction and two sides 42ba₃ and 42b₄ located on opposite sides to each other in a Y direction. The two sides 42b₁ and 42b₂ extend in the Y direction. The two sides 42b₃ and 42b₄ extend in the X direction.

Here, the two sides 42b₁ and 42b₂ may be referred to as long sides. Furthermore, the two sides 42ba₃ and 42ba₄ may be referred to as short sides.

As illustrated in FIGS. 70 to 72, the second semiconductor chip 40 has a peripheral edge portion Cv including the four sides 42b₁, 42b₂, 42b₃, and 42b₄ of the back surface 42b.

As illustrated in FIGS. 70 to 72, the modified layer 81 is selectively provided in the back surface 42b of the semiconductor layer 42 on a side of the peripheral edge portion Cv in plan view. In the first embodiment, as illustrated in FIG. 70, the modified layer 81 is provided in the back surface 42b of the semiconductor layer 42 on sides of four sides (42b₁, 42b₂, 42b₃, and 42b₄), and has an annular planar pattern continuously extending along the four sides (42b₁, 42b₂, 42b₃, and 42b₄). Then, the modified layer 81 overlaps with the sides (42b₁, 42b₂, 42b₃, and 42b₄) of the back surface 42b of the semiconductor layer 42 in plan view, and is exposed from a side surface of the semiconductor layer 42.

Similarly to the above-described warp suppression film 45b, the modified layer 81 is disposed in an outer peripheral edge portion of the second semiconductor chip 40 (on a side of a peripheral edge portion Cs), that is, in an outer peripheral edge portion of the semiconductor layer 42 (on the side of the peripheral edge portion Cv), thereby controlling local film stress of the second semiconductor chip 40 and suppressing a warp of the second semiconductor chip 40.

Unlike single crystal of the semiconductor layer 42, the modified layer 81 is in a state where crystallinity is disturbed. The modified layer 81 can be formed, for example, by condensing a laser beam having a wavelength having transparency into the semiconductor layer 42. When condensing energy is high, a material is locally vaporized inside the semiconductor layer 42 to form holes, so that the modified layer 81 with disturbed crystallinity can be formed. Note that the modified layer 81 includes, for example, a polycrystalline or amorphous region.

The modified layer 81 formed in this manner is in a lower density state than the surrounding single crystal in the semiconductor layer, thereby causing compressive stress.

The modified layer 81 can be configured by a strip-shaped hole having a predetermined width, and can be configured in a pattern in which a plurality of holes exists in a dot manner. Furthermore, the modified layer 81 can also be configured in a pattern in which a plurality of linear holes is present. The compressive stress is inherent in any modified layer 81.

The second semiconductor chip 40 according to the fifth embodiment includes the modified layer 81 provided in the semiconductor layer 42 as the warp suppression portion that suppresses a warp of the second semiconductor chip 40. Therefore, even if a thickness of the semiconductor layer 42 of the second semiconductor chip 40 is reduced after a bonding surface 20a of a wafer stacked body 60 (the bonding surface 20a of a first semiconductor chip 20) and the bonding surface 40a of the second semiconductor chip 40 are bonded by direct bonding in a process of manufacturing the solid-state imaging device 1E, it is possible to suppress the warp of the second semiconductor chip 40 due to a decrease in rigidity of the second semiconductor chip 40, and it is possible to suppress cracking, chipping, and the like of the second semiconductor chip 40, which cause a decrease in a manufacturing yield of the solid-state imaging device 1F. Therefore, the solid-state imaging device 1E according to the fifth embodiment can further improve the manufacturing yield.

Note that the modified layer 81 is preferably formed at a depth position that remains even after the thickness of the semiconductor layer 42 of the second semiconductor chip is reduced.

### Modification of Fifth Embodiment

### Modification 5-1

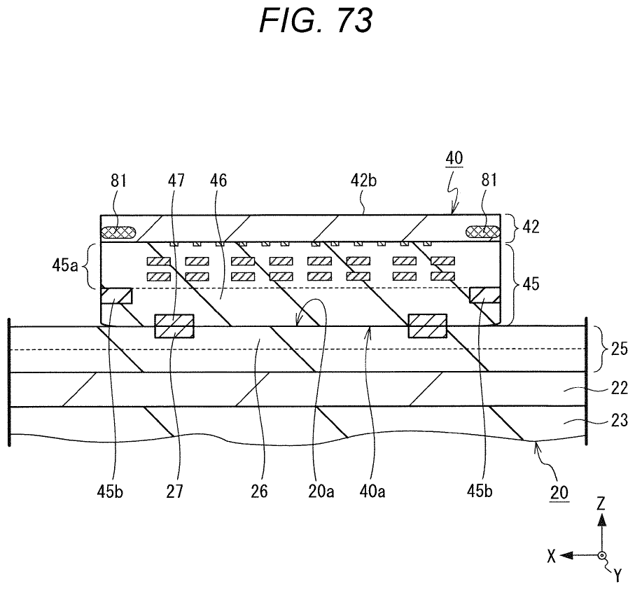

FIG. 73 is a longitudinal cross-sectional view schematically illustrating a longitudinal cross-sectional structure of a solid-state imaging device according to Modification 5-1 of the fifth embodiment of the present technology.

As illustrated in FIG. 73, Modification 5-1 is obtained by combining the above-described fifth embodiment with the warp suppression film 45b of the above-described first embodiment. According to Modification 5-1, the warp of the second semiconductor chip 40 can be more effectively suppressed than the above-described fifth embodiment.

### Other Modifications

In the above-described fifth embodiment, the case where the modified layer 81 is configured in the annular plane pattern has been described, but the modifications of the above-described first embodiment can also be applied to the modified layer 81.

### Sixth Embodiment

In the above-described fifth embodiment, the modified layer 81 has been described as the warp suppression portion provided in the semiconductor layer 42 of the second semiconductor chip 40. In a sixth embodiment, a thick portion (second portion) 82a included in a semiconductor layer 42 will be described as a warp suppression portion provided in the semiconductor layer 42 of a second semiconductor chip 40.

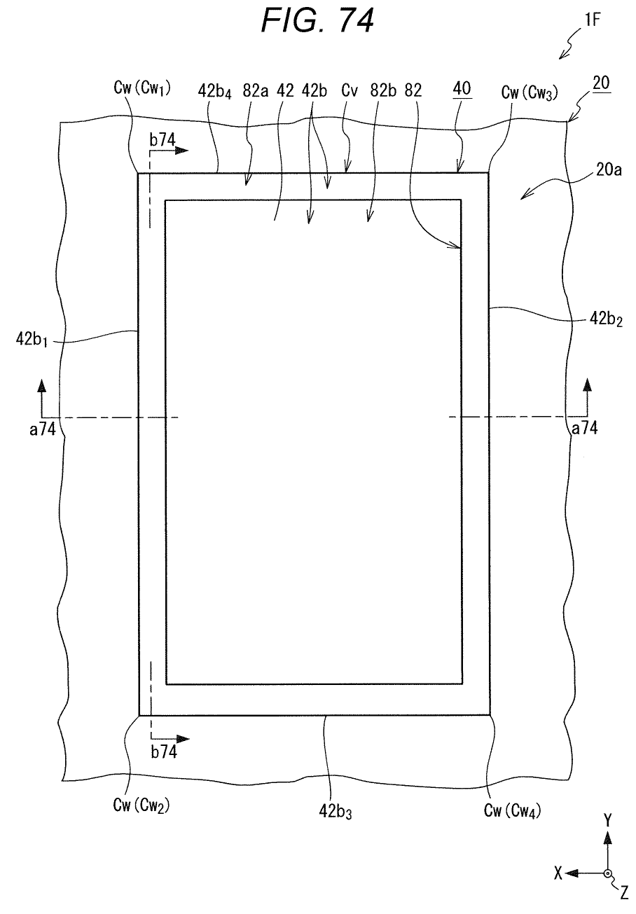

FIG. 74 is a plan view of a main part schematically illustrating a configuration example of a solid-state imaging device according to the sixth embodiment of the present technology.

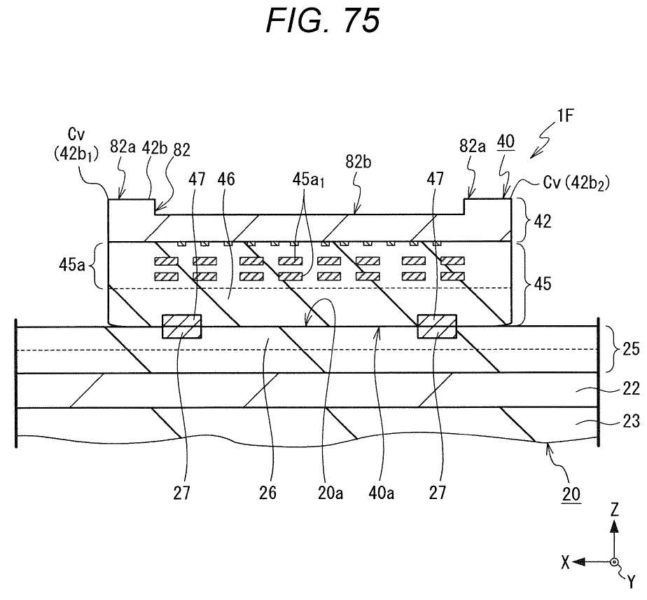

FIG. 75 is a longitudinal cross-sectional view schematically illustrating a longitudinal cross-sectional structure taken along cutting line a75-a75 in FIG. 75.

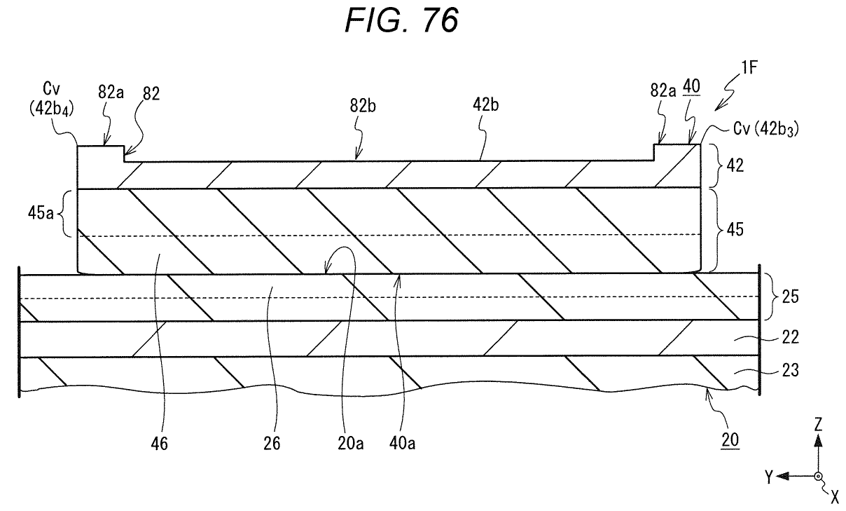

FIG. 76 is a longitudinal cross-sectional view schematically illustrating a longitudinal cross-sectional structure taken along cutting line b75-b75 in FIG. 75.

As illustrated in FIGS. 74 to 76, a solid-state imaging device 1F according to the sixth embodiment of the present technology basically has a configuration similar to the solid-state imaging device 1E according to the above-described fifth embodiment, and a configuration of the second semiconductor chip 40 is different.

That is, as illustrated in FIGS. 74 to 76, the second semiconductor chip 40 according to the sixth embodiment includes the thick portion 82a included in a back surface 42b of the semiconductor layer 42 instead of the modified layer 81 as the warp suppression portion illustrated in FIGS. 70 to 72 of the above-described fifth embodiment. The other configuration is roughly similar to that of the above-described fifth embodiment.

As illustrated in FIGS. 74 to 76, the back surface 42b of the semiconductor chip 40 of the sixth embodiment includes a thin portion (first portion) having a first thickness and the thick portion (second portion) having a second thickness thicker than the first thickness. Then, the thick portion is provided in the back surface 42b of the semiconductor chip 40 on a side of a peripheral edge portion Cv. In the sixth embodiment, as illustrated in FIG. 74, the thick portion 82a is provided in, but not limited to, the back surface 42b of the semiconductor layer 42 on sides of four sides (42b₁, 42b₂, 42b₃, and 42b₄), and has an annular planar pattern continuously extending along the four sides (42b₁, 42b₂, 42b₃, and 42b₄), for example. Then, the thick portion 82a overlaps with the sides (42b₁, 42b₂, 42b₃, and 42b₄) of the back surface 42b of the semiconductor layer 42 in plan view, and is included in a side surface of the semiconductor layer 42.

As illustrated in FIGS. 74 to 76, a thin portion 82b is provided in a central region of the back surface 42 of the second semiconductor chip 40, and is recessed toward a multilayer wiring layer 45 side from the thick portion 82a. Furthermore, the thick portion 82a is provided in a peripheral region of the back surface 42 of the second semiconductor chip 40, and protrudes to an opposite side to the multilayer wiring layer 45 side from the thin portion 82b. That is, the back surface 42b of the second semiconductor chip 40 of the sixth embodiment includes a stepped portion 82 formed by the thin portion (first portion) 82b and the thick portion (second portion) 82a having relatively different thicknesses.

As described above, the back surface 42 of the second semiconductor chip 40 includes the stepped portion 82 formed by the thin portion (first portion) 82b and the thick portion (second portion) 82a having relatively different thicknesses, whereby bending rigidity of the second semiconductor chip 40 in a Z direction can be increased.

Therefore, even if a thickness of the semiconductor layer 42 of the second semiconductor chip 40 is reduced after a bonding surface 20a of a wafer stacked body 60 (the bonding surface 20a of a first semiconductor chip 20) and the bonding surface 40a of the second semiconductor chip 40 are bonded by direct bonding in a process of manufacturing the solid-state imaging device 1F, it is possible to suppress a warp of the second semiconductor chip 40 due to a decrease in rigidity of the second semiconductor chip 40, and it is possible to suppress cracking, chipping, and the like of the second semiconductor chip 40, which cause a decrease in a manufacturing yield of the solid-state imaging device 1F. Therefore, the solid-state imaging device 1F according to the sixth embodiment can improve the manufacturing yield.

### Modification of Sixth Embodiment

In the above-described sixth embodiment, the thick portion 82a in the annular plane pattern continuously extending along the four sides (42b₁, 42b₂, 42b₃, and 42b₄) of the back surface 42b of the second semiconductor chip 40 has been described as the thick portion 82a of the semiconductor layer 45. However, the thick portion 82a is not limited to the annular plane pattern of the above-described sixth embodiment.

### Modification 6-1

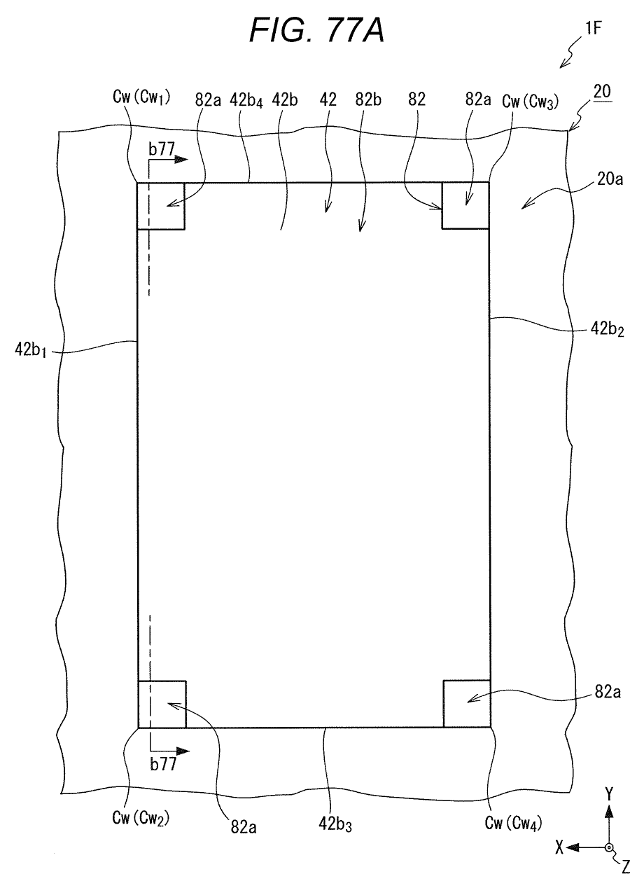

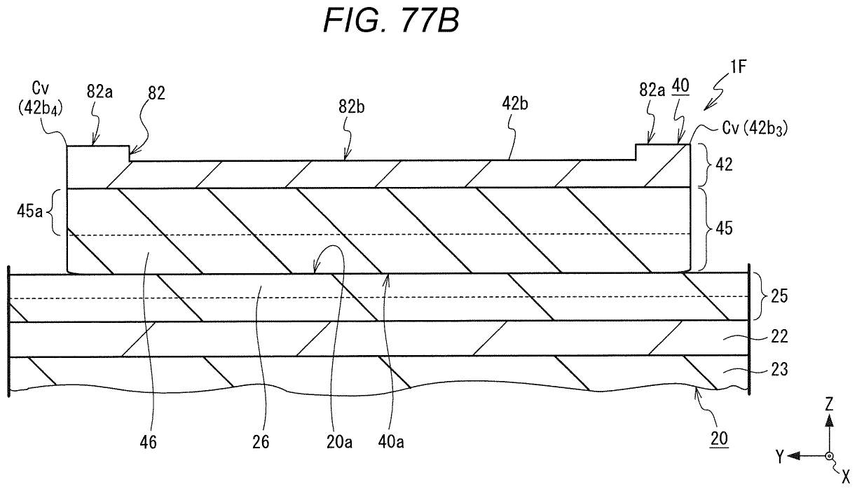

FIG. 77A is a plan view of a main part schematically illustrating a configuration example of the solid-state imaging device according to Modification 2-1 of the sixth embodiment of the present technology.

FIG. 77B is a longitudinal cross-sectional view schematically illustrating a longitudinal cross-sectional structure taken along cutting line b77-b77 in FIG. 77A.

As illustrated in FIGS. 77A and 77B, in Modification 6-1, the thick portions 82a are provided at four corner portions Cw (Cw₁, Cw₂, Cw₃, and Cw₄) in the back surface 42b of the second semiconductor chip 40. Then, the thick portions 82a of Modification 6-1 overlap with the corner portions Cw (Cw₁, Cw₂, Cw₃, and Cw₄) in plan view.

Also in Modification 6-1, the warp of the second semiconductor chip 40 can be suppressed similarly to the above-described sixth embodiment. Furthermore, in particular, in Modification 6-1, it is possible to suppress the warp of the semiconductor layer 42 of the second semiconductor chip 40 on a side of the corner portion Cw (a side of the corner portion Cr of the bonding surface 40a).

### Modification 6-2

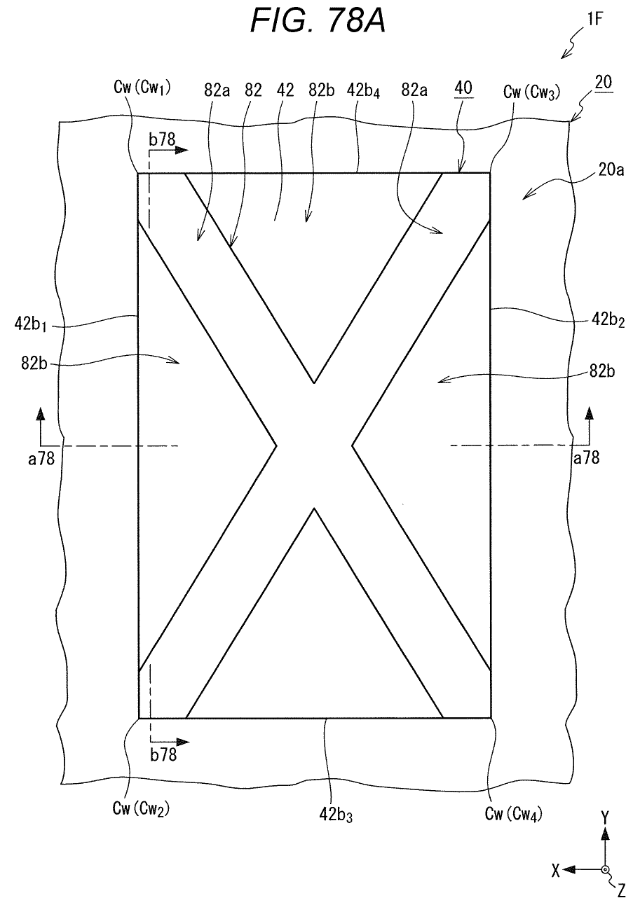

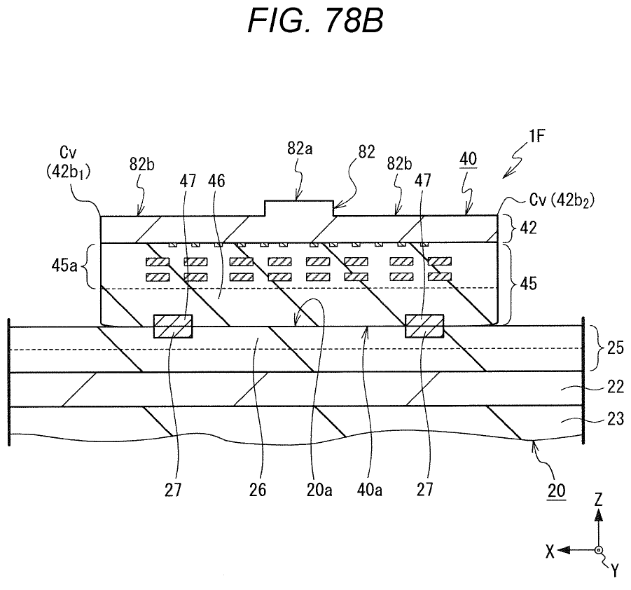

FIG. 78A is a plan view of a main part schematically illustrating a configuration example of the solid-state imaging device according to Modification 6-2 of the sixth embodiment of the present technology.

FIG. 78B is a longitudinal cross-sectional view schematically illustrating a longitudinal cross-sectional structure taken along cutting line a78-a78 in FIG. 78A.

FIG. 78C is a longitudinal cross-sectional view schematically illustrating a longitudinal cross-sectional structure taken along cutting line b78-b78 in FIG. 78A.

As illustrated in FIGS. 78A to 78C, in Modification 6-2, the thick portion 82a is configured in an X-shaped planar pattern extending from the sides of the four corner portions Cw (Cw₁, Cw₂, Cw₃, and Cw₄) toward the center portion on the back surface 42b of the semiconductor layer 42 of the second semiconductor chip 40. The X-shaped thick portion 82a extends inward from the sides of the corner portions Cw (Cw₁, Cw₂, Cw₃, and Cw₄) included in the peripheral edge portions Cv of the back surface 42b of the semiconductor layer 42.

Also in Modification 6-2, the warp of the second semiconductor chip 40 can be suppressed similarly to the above-described sixth embodiment. Furthermore, also in Modification 6-2, it is possible to suppress the warp of the semiconductor layer 42 of the second semiconductor chip 40 on the corner portion Cw side (the corner portion Cr side of the bonding surface 40a).

### Modification 6-3

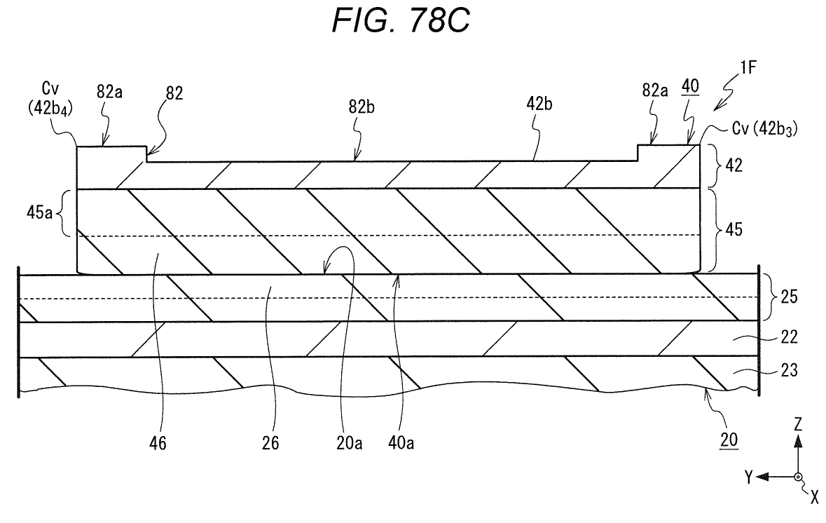

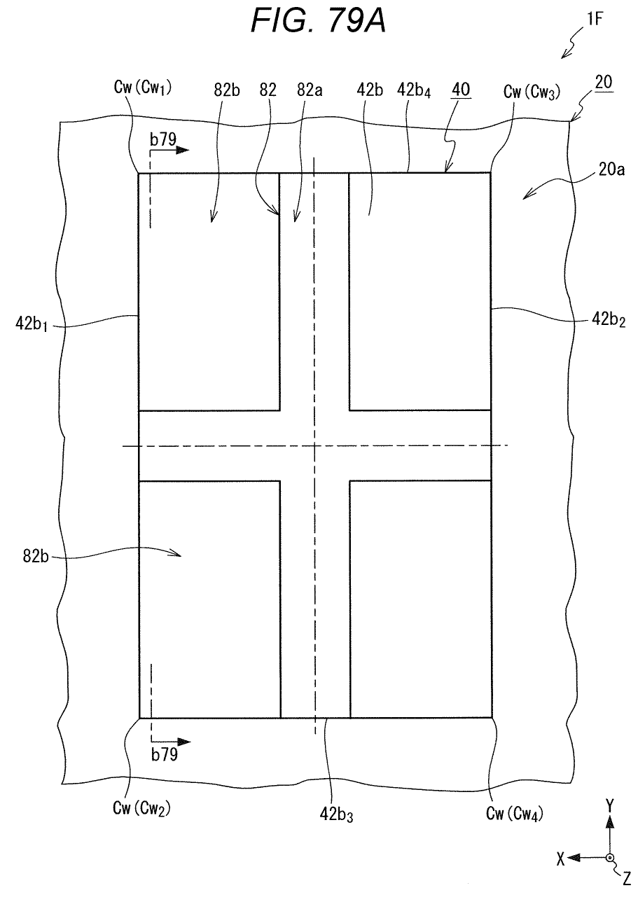

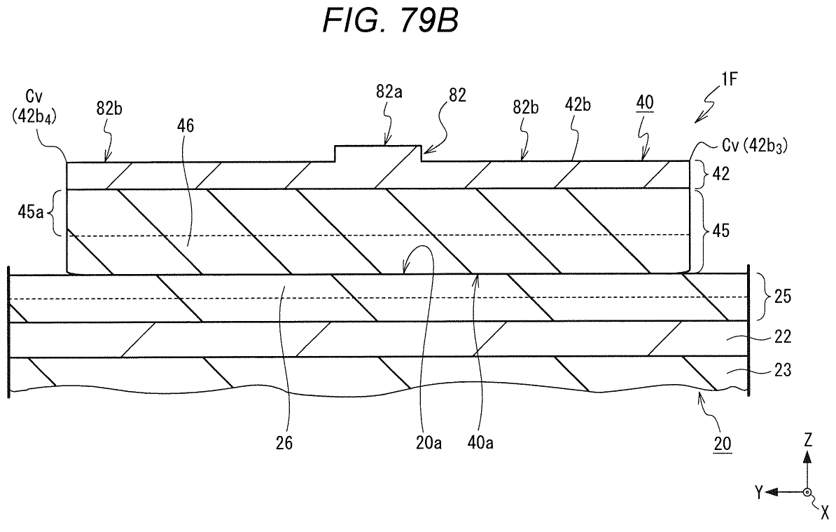

FIG. 79A is a plan view of a main part schematically illustrating a configuration example of the solid-state imaging device according to Modification 6-3 of the sixth embodiment of the present technology.

FIG. 79B is a longitudinal cross-sectional view schematically illustrating a longitudinal cross-sectional structure taken along cutting line b79-b79 in FIG. 79A.

As illustrated in FIGS. 79A and 79B, in Modification 6-3, the thick portion 82a is configured in a cross-shaped planar pattern in which a first portion extending in the X direction and a second portion extending in the Y direction intersect at the center portion on the back surface 42b of the semiconductor layer 42 of the second semiconductor chip 40. The cross-shaped thick portion 82a extends inward from the sides of the sides (42b₁, 42b₂, 42b₃, and 42b₄) included in the peripheral edge portion Cv of the back surface 42b of the semiconductor layer 42.

Also in Modification 6-3, the warp of the second semiconductor chip 40 can be suppressed similarly to the above-described sixth embodiment.

### Modification 6-4

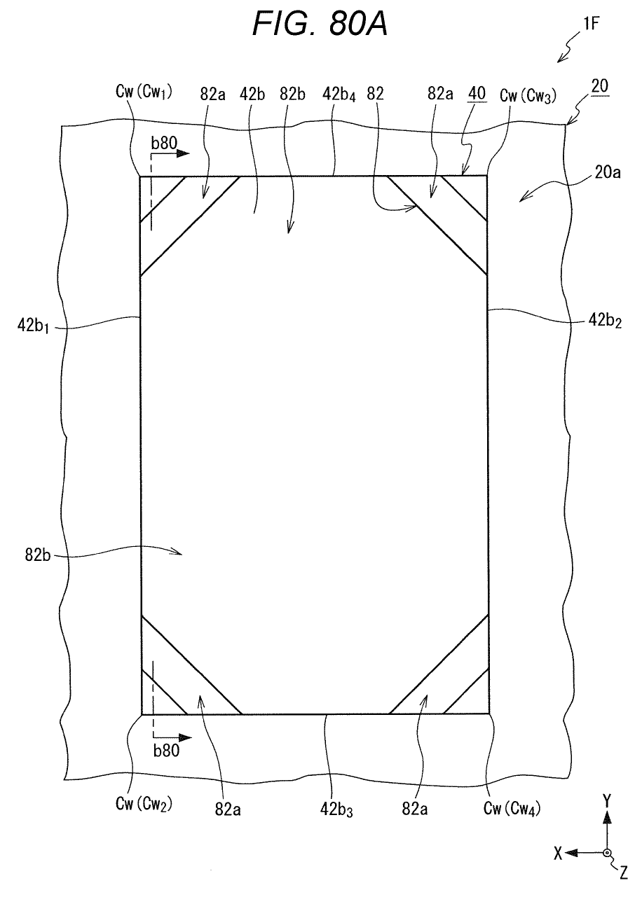

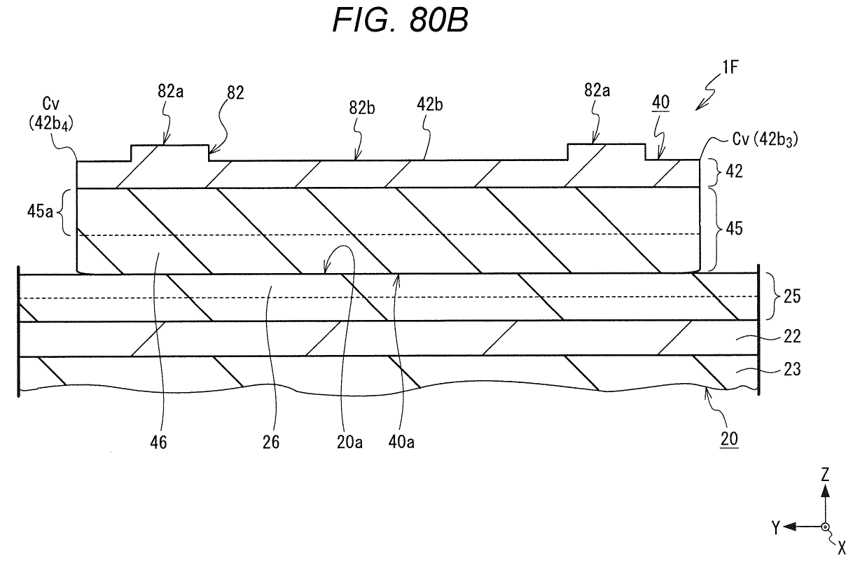

FIG. 80A is a plan view of a main part schematically illustrating a configuration example of the solid-state imaging device according to Modification 6-4 of the sixth embodiment of the present technology.

FIG. 80B is a longitudinal cross-sectional view schematically illustrating a longitudinal cross-sectional structure taken along cutting line b80-b80 in FIG. 80A.

As illustrated in FIGS. 80A and 80B, in Modification 6-4, the inclined-shaped thick portion 82a obliquely extending over two sides having different extending directions is provided in the vicinity of the corner portion Cw of the back surface 42b of the semiconductor layer 42 of the second semiconductor chip 40. The inclined-shaped thick portions 82a extend inward from the sides of the sides (42b₁, 42b₂, 42b₃, and 42b₄) included in the peripheral edge portion Cv of the back surface 42b of the semiconductor layer 42.

Also in Modification 6-4, the warp of the second semiconductor chip 40 can be suppressed similarly to the above-described sixth embodiment. Furthermore, also in Modification 6-4, it is possible to suppress the warp of the semiconductor layer 42 of the second semiconductor chip 40 on the corner portion Cw side (the corner portion Cr side of the bonding surface 40a).

### Modification 6-5

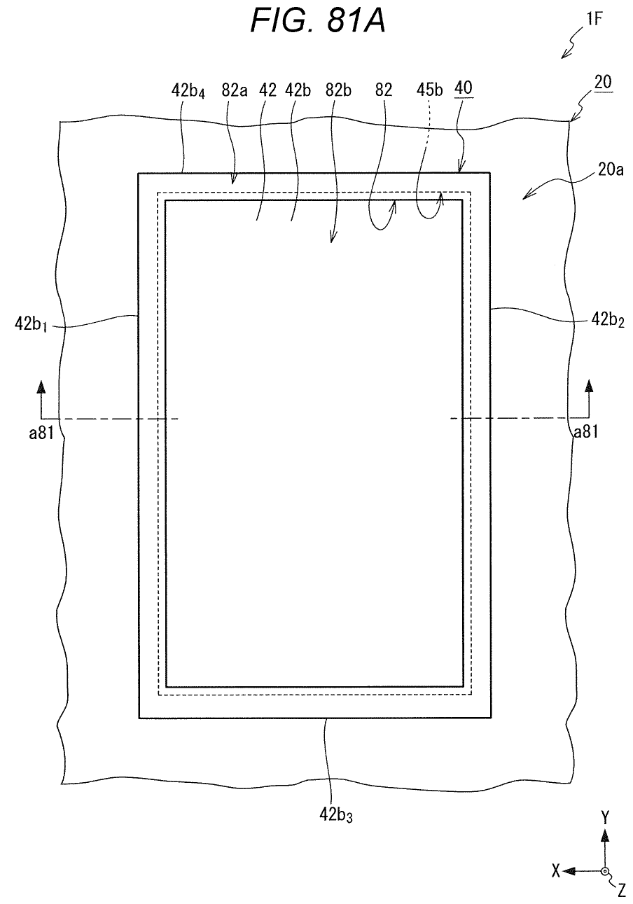

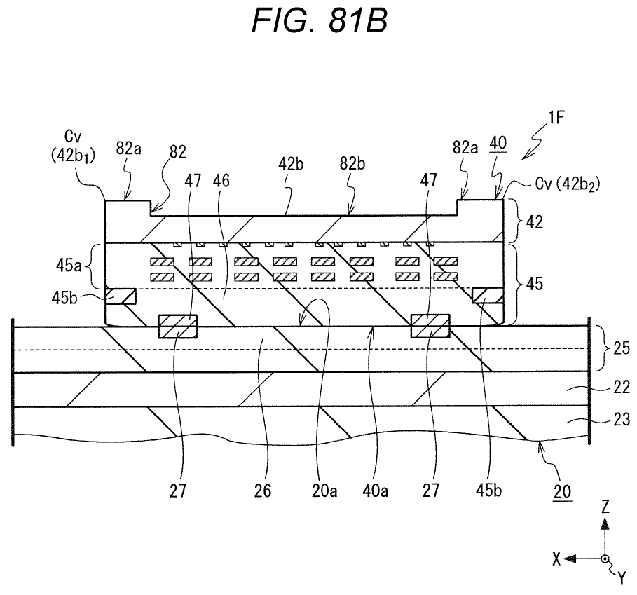

FIG. 81A is a plan view of a main part schematically illustrating a configuration example of the solid-state imaging device according to Modification 6-5 of the sixth embodiment of the present technology.

FIG. 81B is a longitudinal cross-sectional view schematically illustrating a longitudinal cross-sectional structure taken along cutting line a81-a81 in FIG. 81A.

As illustrated in FIGS. 81A and 81B, Modification 6-5 is obtained by combining the above-described sixth embodiment with the warp suppression film 45b of the above-described first embodiment. According to Modification 6-5, the warp of the second semiconductor chip 40 can be more effectively suppressed than the above-described sixth embodiment.

### Seventh Embodiment

In a seventh embodiment, a technique for suppressing generation of voids caused by bonding waves will be described.

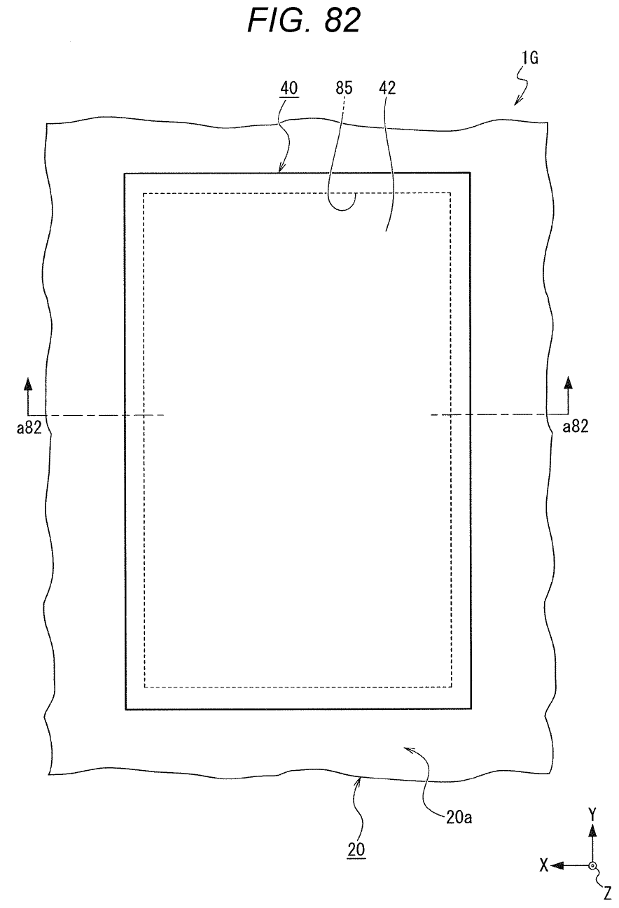

FIG. 82 is a plan view of a main part schematically illustrating a configuration example of a solid-state imaging device according to the seventh embodiment of the present technology.

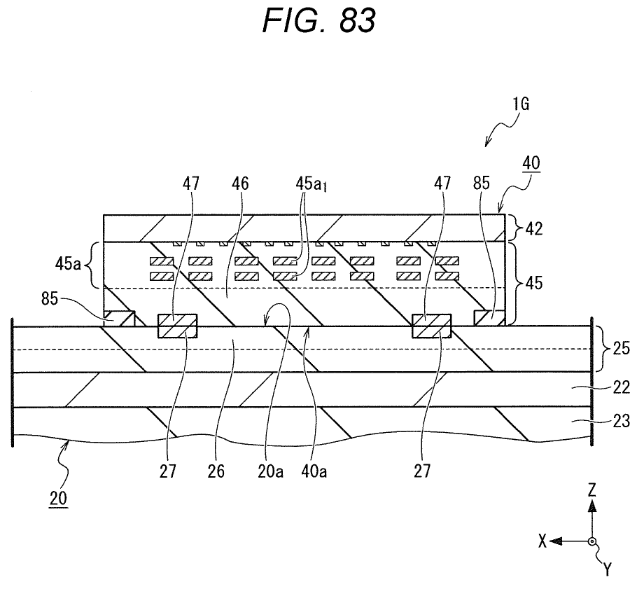

FIG. 83 is a longitudinal cross-sectional view schematically illustrating a longitudinal cross-sectional structure taken along line a82-a782 in FIG. 82.

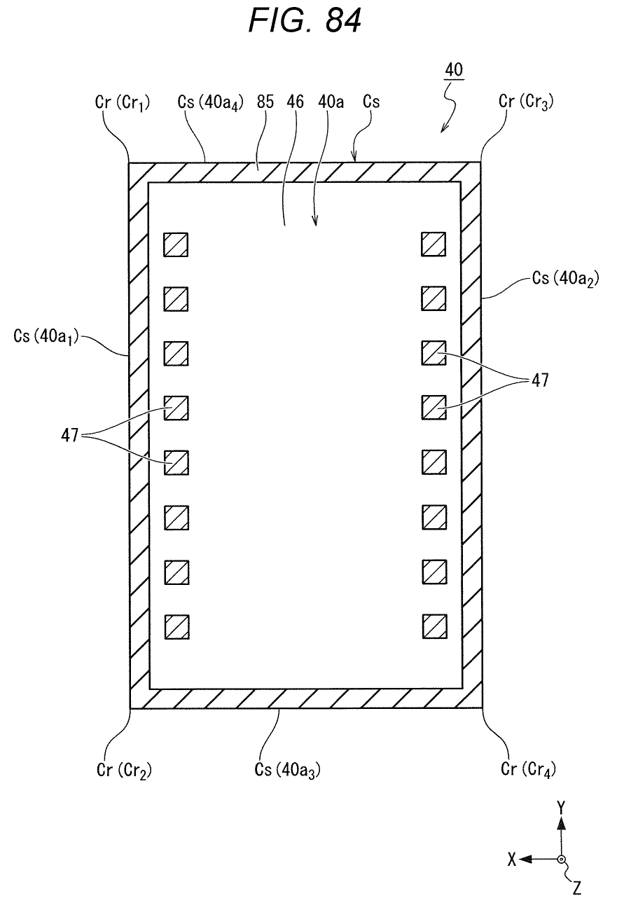

FIG. 84 is a plan view schematically illustrating a bonding surface side of a second semiconductor chip.

Note that FIG. 82 corresponds to FIG. 7 of the above-described first embodiment.

As illustrated in FIGS. 82 to 84, a solid-state imaging device 1G according to the seventh embodiment of the present technology basically has a configuration similar to the solid-state imaging device 1A according to the above-described first embodiment, and a configuration of a second semiconductor chip 40 is different.

That is, as illustrated in FIGS. 83 and 84, the semiconductor chip 40 of the seventh embodiment includes a weak bonding portion 85 instead of the warp suppression film 45b illustrated in FIG. 8 of the above-described first embodiment. The other configuration is roughly similar to the configuration of the above-described first embodiment.

As illustrated in FIGS. 83 to 84, the weak bonding portion 85 is included in a bonding surface 40a of a second semiconductor chip 40 together with an insulating layer 46 and a bonding metal pad 47 of a multilayer wiring layer 45. Then, the weak bonding portion 85 is configured by a material having a weaker bonding force with respect to a bonding surface 20a of a first semiconductor chip 20 than the insulating layer 46 of the multilayer wiring layer 45. That is, the second bonding surface 40a of the second semiconductor chip 40 of the seventh embodiment includes the insulating layer 46 included in the multilayer wiring layer 45 and the weak bonding portion 85 having a weaker bonding force with respect to the bonding surface 20a of the first semiconductor chip 20 than the insulating layer 46. The weak bonding portion 85 is configured by, for example, a porous film (porous film). Since the porous film includes a plurality of pores, the bonding force with a counterpart is weaker than that of a film formed by a film forming method such as a CVD method.

The bonding wave when the second semiconductor chip is directly bonded to the bonding surface of the first semiconductor chip affects the bonding force between the bonding surface of the first semiconductor chip and the bonding surface of the second semiconductor chip, and a traveling speed of the bonding wave decreases in a portion where the bonding force is weak. That is, in the bonding surface of the second semiconductor chip, the traveling speed of the bonding wave is slower in the weak bonding portion than in the insulating layer between the insulating layer and the weak bonding portion.

Similarly to the bonding metal pad 47, the weak bonding portion 85 is provided in the insulating layer 46 of the multilayer wiring layer 45 in a state where a bonding surface side is exposed from the bonding surface 40a. Then, the bonding surface 40a is substantially flat where a step between the weak bonding portion 85 and the bonding metal pad 47, and the insulating layer 46 is as small as possible. The weak bonding portion 85 and the insulating layer 46 are bonded to the bonding surface 20a of the first semiconductor chip 20 by direct bonding.

As illustrated in FIGS. 83 and 84, the weak bonding portion 85 is provided in the bonding surface 40a of the second semiconductor chip 40 on a side of a peripheral edge portion Cs. In the seventh embodiment, the weak bonding portion is provided, although not limited to this configuration, in the bonding surface 40a of the second semiconductor chip 40 on sides of four sides (40a₁, 40a₂, 40a₃, and 40a₄), and has an annular planar pattern continuously extending along the four sides (40a₁, 40a₂, 40a₃, and 40a₄), for example. Then, the weak bonding portion 85 overlaps with the sides (40a₁, 40a₂, 40a₃, and 40a₄) of the bonding surface 40a of the second semiconductor chip 40 in plan view, and is exposed from a side surface of the second semiconductor chip 40, that is, from a side surface of the multilayer wiring layer 45.

Here, in a manufacturing process, the bonding surface 40a of the second semiconductor chip 40 is directly bonded to the bonding surface 20a of the wafer stacked body 60 (the bonding surface 20a of the first semiconductor chip 20) as illustrated in FIG. 29 of the above-described first embodiment. In this direct bonding, the bonding surface 40a of the second semiconductor chip 40 is crimped (pressure-bonded) to the bonding surface 20a of the wafer stacked body 60 (the bonding surface 20a of the first semiconductor chip 20) such that a bonding wave is radially generated from a center portion toward a peripheral portion in a two-dimensional plane of the second semiconductor chip 40.

At this time, in the case of the conventional second semiconductor chip, as will be described with reference to FIG. 84 of the seventh embodiment, the bonding wave arrives at the sides (40a₁, 40a₂, 40a₃, and 40a₄) of the bonding surface 40a of the second semiconductor chip 40. Then, the bonding wave that has arrived at the side of the bonding surface 40a increases in traveling speed, travels along the side of the bonding surface 40a, and precedes the corner portion Cr of the bonding surface 40a, which is an arrival position of the radially expanding bonding wave. For this reason, in the conventional second semiconductor chip, voids are easily generated at corner portions of the bonding surface. In the quadrangular second semiconductor chip, there is a difference between a distance from the center portion to the side of the semiconductor chip and a distance from the center portion to the corner portion of the semiconductor chip in plan view, so that generation of voids becomes remarkable at the corner portion of the second semiconductor chip.

In contrast, as illustrated in FIG. 84, the bonding surface 40a of the second semiconductor chip 40 of the seventh embodiment includes the insulating layer 46 included in the multilayer wiring layer 45 and the weak bonding portion 85 having a weaker bonding force with respect to the bonding surface 20a of the first semiconductor chip 20 than the insulating layer 46. Then, the weak bonding portion 85 is provided on the peripheral edge portion Cs side (on the side 40a₁ side, the side 40a side, the side 40a₃ side, and the side 40a₄ side) of the bonding surface 40a. Therefore, it is possible to delay the arrival of the bonding wave at the peripheral edge portion Cs of the bonding surface 40a. Furthermore, the weak bonding portion 85 extends along the sides (40a₁, 40a₂, 40a₃, and 40a₄) of the bonding surface 40a. Therefore, the traveling speed of the bonding wave traveling along the sides of the bonding surface 40a can be reduced. As a result, in the manufacturing process, it is possible to suppress voids generated at the corner portions Cr of the second semiconductor chip 40 due to the arrival time difference between the bonding wave traveling along the sides (40a₁, 40a₂, 40a₃, and 40a₄) of the bonding surface 40 and the radially expanding bonding wave.

Therefore, the solid-state imaging device 1G according to the seventh embodiment can improve a manufacturing yield.

### Modification of Seventh Embodiment

### Modification 7-1

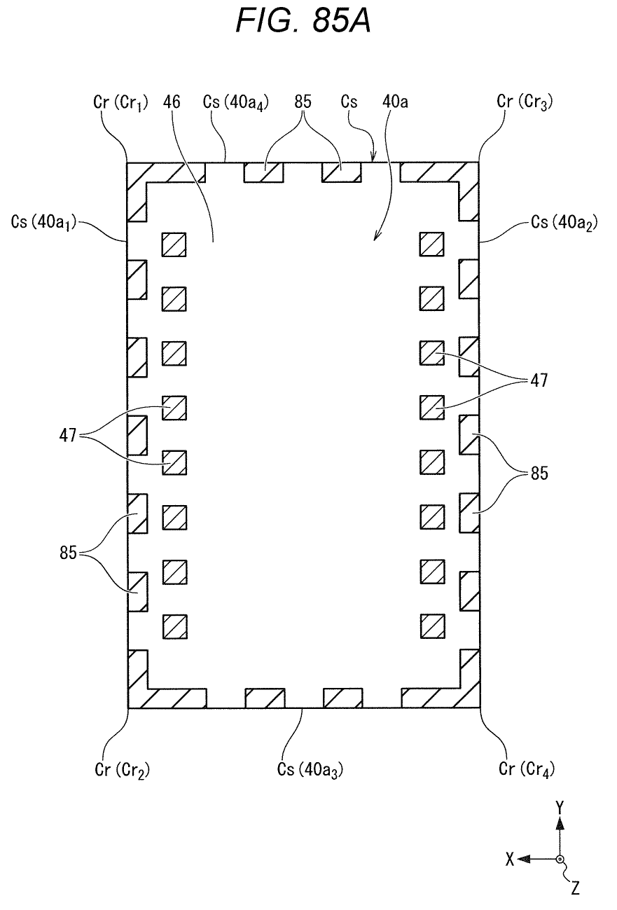

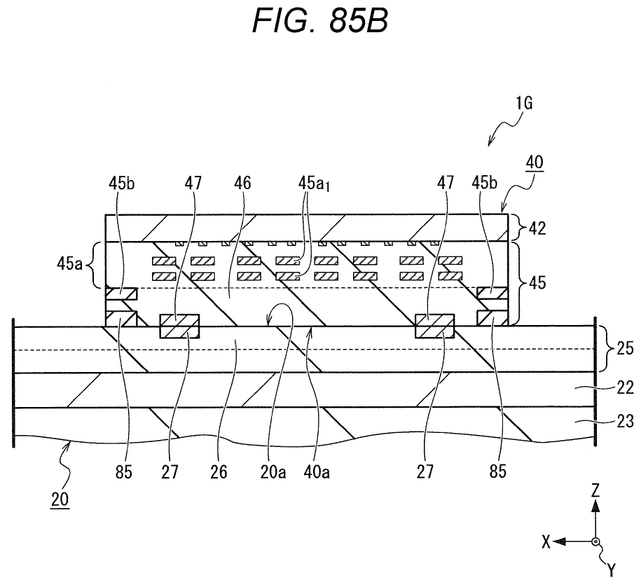

FIG. 85A is a longitudinal cross-sectional view schematically illustrating a configuration example of the solid-state imaging device according to Modification 7-1 of the seventh embodiment of the present technology.

As illustrated in FIG. 85A, in Modification 7-1, the weak bonding portions 85 are interspersed along the sides of the bonding surface of the second semiconductor chip. Also in Modification 7-1, effects similar to those of the above-described seventh embodiment can be obtained.

### Modification 7-2

FIG. 85B is a longitudinal cross-sectional view schematically illustrating a configuration example of the solid-state imaging device according to Modification 7-2 of the seventh embodiment of the present technology.

As illustrated in FIG. 85B, Modification 7-2 is obtained by combining the above-described seventh embodiment with the warp suppression film 45b of the above-described first embodiment. According to Modification 2, the warp of the second semiconductor chip 40 can be suppressed, and generation of voids caused by the bonding wave can be suppressed, as compared with the above-described seventh embodiment.

### Other Modifications

In the above-described seventh embodiment, the case where the porous weak bonding portion 85 is provided in the bonding surface 40a of the second semiconductor chip 40 on the peripheral edge portion Cs side has been described, but a dummy pad may be used as the weak bonding portion 85. In this case, a material (for example, Cu or the like) having a weaker bonding force with the bonding surface 20a of the first semiconductor chip 20 than the insulating layer 46 of the second semiconductor chip 40 is selected as the dummy pad.

### Eighth Embodiment

In an eighth embodiment, a technique for suppressing generation of voids caused by bonding waves will be described.

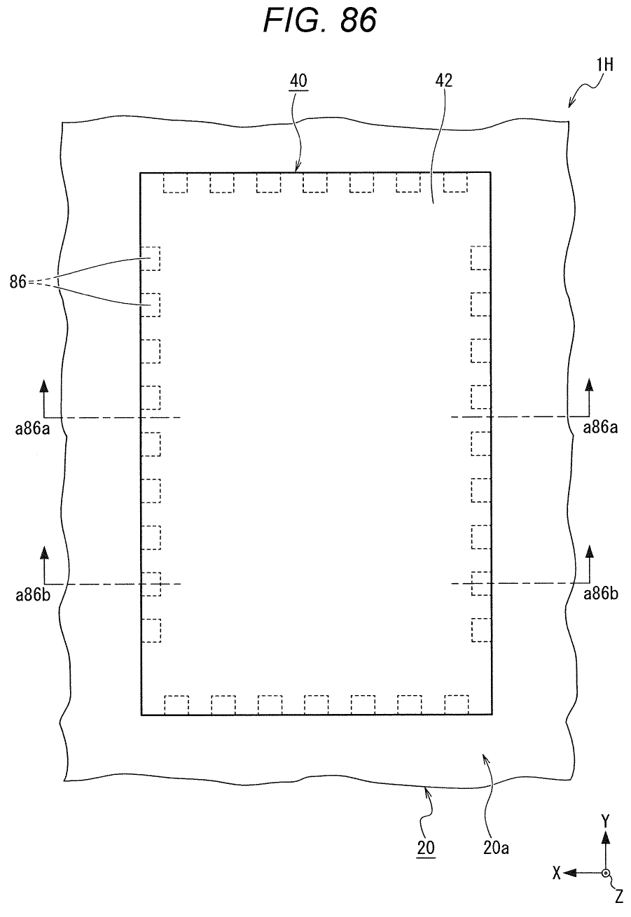

FIG. 86 is a plan view of a main part schematically illustrating a configuration example of a solid-state imaging device according to the eighth embodiment of the present technology.

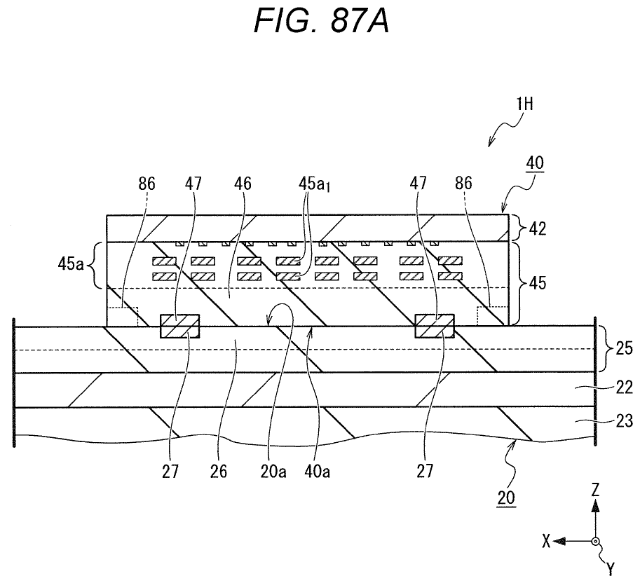

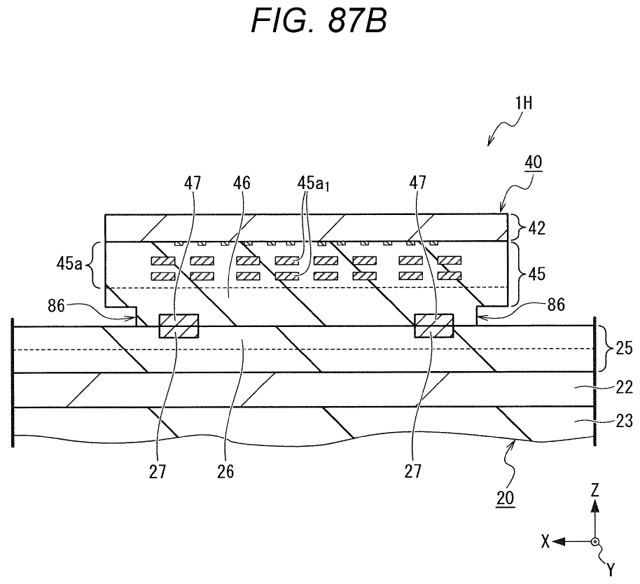

FIG. 87A is a longitudinal cross-sectional view schematically illustrating a longitudinal cross-sectional structure taken along line a86a-a86a in FIG. 86.

FIG. 87B is a longitudinal cross-sectional view schematically illustrating a longitudinal cross-sectional structure taken along line a86b-a86b in FIG. 86.

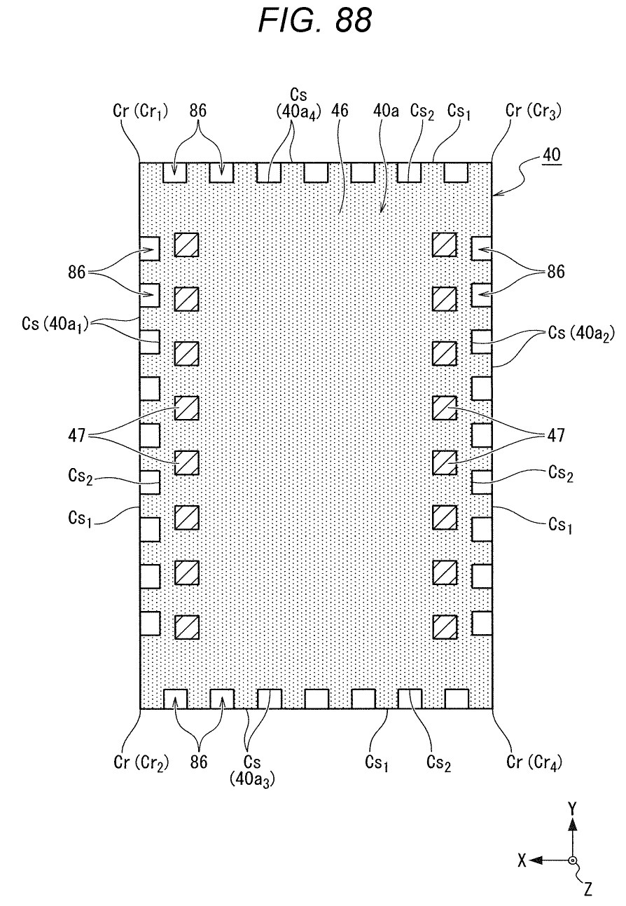

FIG. 88 is a plan view schematically illustrating a bonding surface side of a second semiconductor chip.

Note that FIG. 86 corresponds to FIG. 7 of the above-described first embodiment.

Furthermore, in FIG. 88, to make the drawing easy to see, dotted hatching is applied to a region of a bonding surface.

As illustrated in FIGS. 86 to 88, a solid-state imaging device 1H according to the eighth embodiment of the present technology basically has a configuration similar to the solid-state imaging device 1G according to the above-described seventh embodiment, and a configuration of a second semiconductor chip 40 is different.

That is, as illustrated in FIGS. 86 to 88, in the semiconductor chip 40 of the eighth embodiment, a peripheral edge portion Cs (a side 40a₁, a side 40a₂, a side 40a₃, and a side 40a₄) of the bonding surface 40a meanders. Then, the semiconductor chip 40 of the eighth embodiment does not include a weak bonding portion 85 illustrated in FIG. 88 of the above-described seventh embodiment. Furthermore, the semiconductor chip 40 of the twenty-eighth embodiment has a recess 86 extending inward from a side surface of the semiconductor chip 40.

In the semiconductor chip 40 of the eighth embodiment, as illustrated in FIG. 88, the peripheral edge portion Cs has a meandering shape in which a first peripheral edge portion Cs₁ and a second peripheral edge portion Cs₂ located inside the first peripheral edge portion Cs₁ are repeatedly arranged in one direction in plan view. Then, the peripheral edge portion Cs of the bonding surface 40a reflects a planar shape of the recess.

As illustrated in FIG. 88, the recess 86 of the second semiconductor chip 40 is repeatedly arranged in an extending direction of the peripheral edge portion Cs of the bonding surface 40a in plan view. Then, as illustrated in FIGS. 87A and 87B, the recess 86 of the semiconductor chip 40 extends from the bonding surface 40a toward a side of a back surface 42b of the semiconductor chip 40. In the eighth embodiment, one end side of the recess 86 is included in the bonding surface 40a of the semiconductor chip 40, and the other end side is separated from the back surface 42b of the semiconductor chip 40. The recess 86 is configured in, for example, a hexahedral shape, and among the six surfaces, a surface on the bonding surface 40a side and a surface on the side surface side of the semiconductor chip 40 are open surfaces, and the remaining four surfaces are surrounded by an insulating layer 45.

In the semiconductor chip 40 of the eighth embodiment, the peripheral edge portion Cs of the bonding surface 40a meanders. Therefore, a practical length of the peripheral edge portion can be made longer than a distance obtained by connecting two corner portions located on opposite sides to each other at one side of the bonding surface with a straight line without increasing a planar size of the second semiconductor chip 40.

Thereby, in a manufacturing process, when the bonding surface 40a of the second semiconductor chip 40 is crimped (pressure-bonded) to the bonding surface 20a of the wafer stacked body 60 so that the bonding wave is generated from a center portion toward a peripheral portion in a two-dimensional plane of the second semiconductor chip 40, as illustrated in FIG. 29, the bonding wave travels along the sides (40a₁, 40a₂, 40a₃, and 40a₄) of the bonding surface 40a of the second semiconductor chip 40, and arrival of the bonding wave at the corner portions of the bonding surface can be delayed, and voids generated in the corner portions Cr of the second semiconductor chip 40 due to an arrival time difference between the bonding wave traveling along the sides (40a₁, 40a₂, 40a₃, and 40a₄) of the bonding surface 40 and the radially expanding bonding wave can be suppressed.

Therefore, the solid-state imaging device 1G according to the eighth embodiment can improve a manufacturing yield, similarly to the solid-state imaging device 1F according to the above-described seventh embodiment.

### Modification of Eighth Embodiment

### Modification 8-1

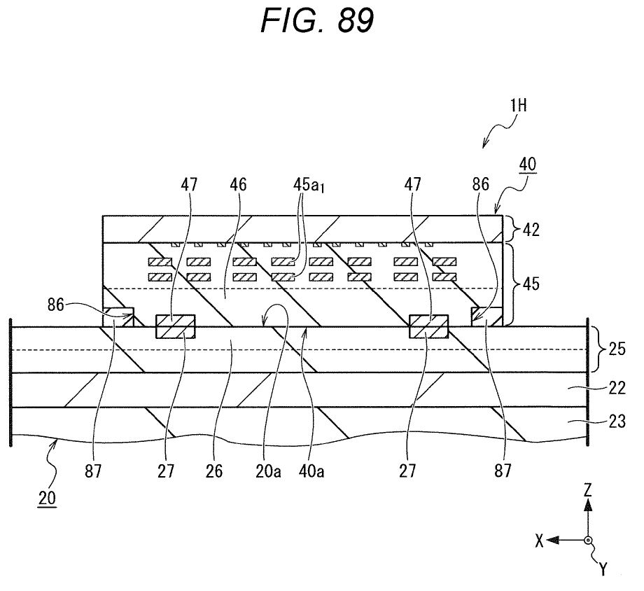

FIG. 89 is a longitudinal cross-sectional view schematically illustrating a configuration example of the solid-state imaging device according to Modification 8-1 of the eighth embodiment of the present technology.

As illustrated in FIG. 89, in Modification 8-1, the recess 86 is filled with an insulating material 87. As the insulating material 87, an organic material such as a silicon oxide film or a silicon nitride film, or an organic material such as a resin can be used. The insulating material 87 is formed in the recess 86 after the bonding surface 20a of the wafer stacked body 60 (the bonding surface 20a of the first semiconductor chip 20) and the bonding surface 40a of the second semiconductor chip 40 are bonded by direct bonding. Also in Modification 8-1, effects similar to those of the above-described eighth embodiment can be obtained.

### Ninth Embodiment

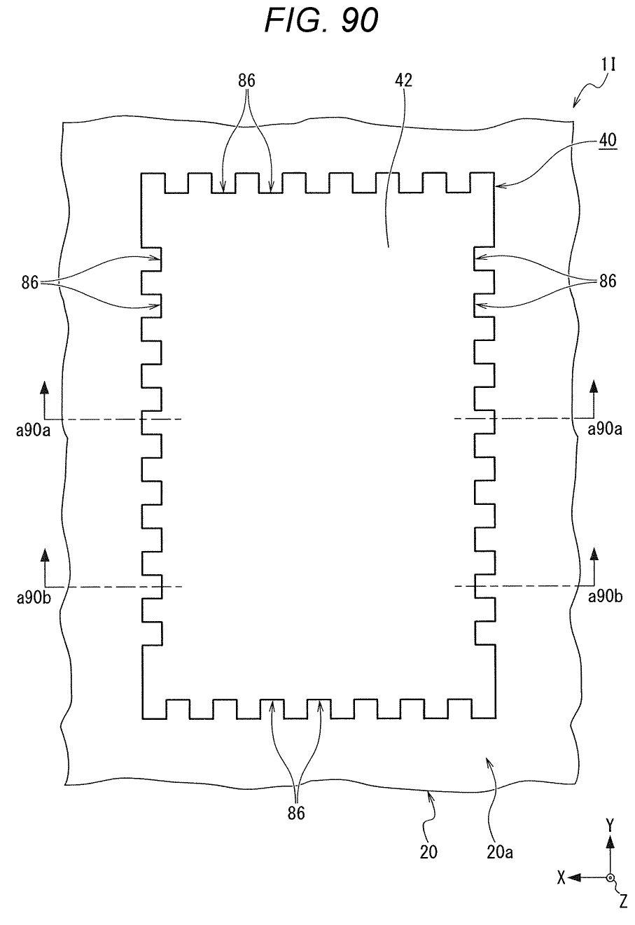

FIG. 90 is a plan view of a main part schematically illustrating a configuration example of a solid-state imaging device according to a ninth embodiment of the present technology.

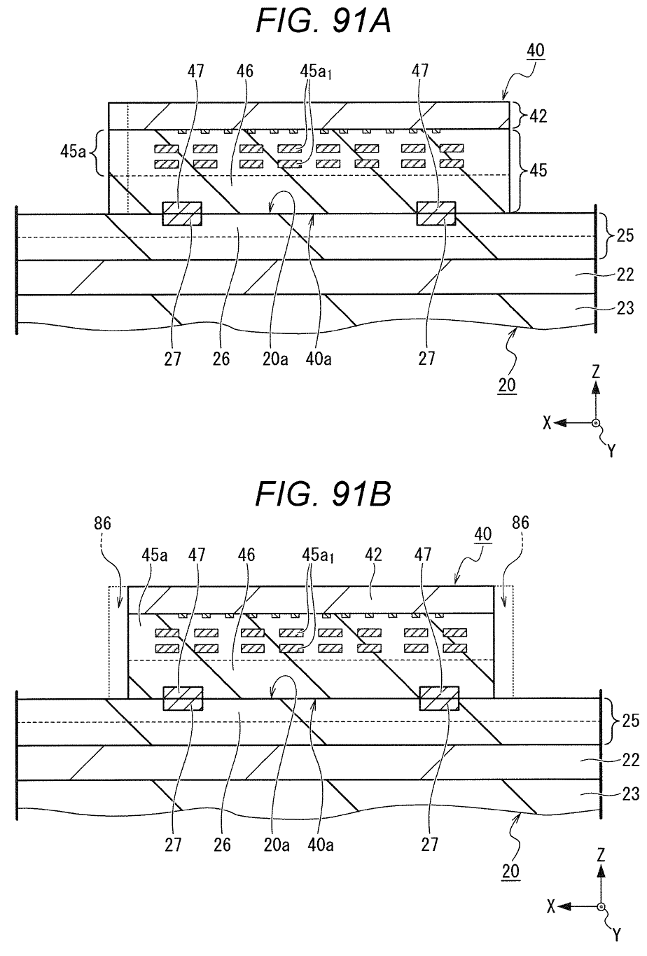

FIG. 91A is a longitudinal cross-sectional view schematically illustrating a longitudinal cross-sectional structure taken along line a90a-a90a in FIG. 90.

FIG. 91B is a longitudinal cross-sectional view schematically illustrating a longitudinal cross-sectional structure taken along line a90b-a90b in FIG. 90.

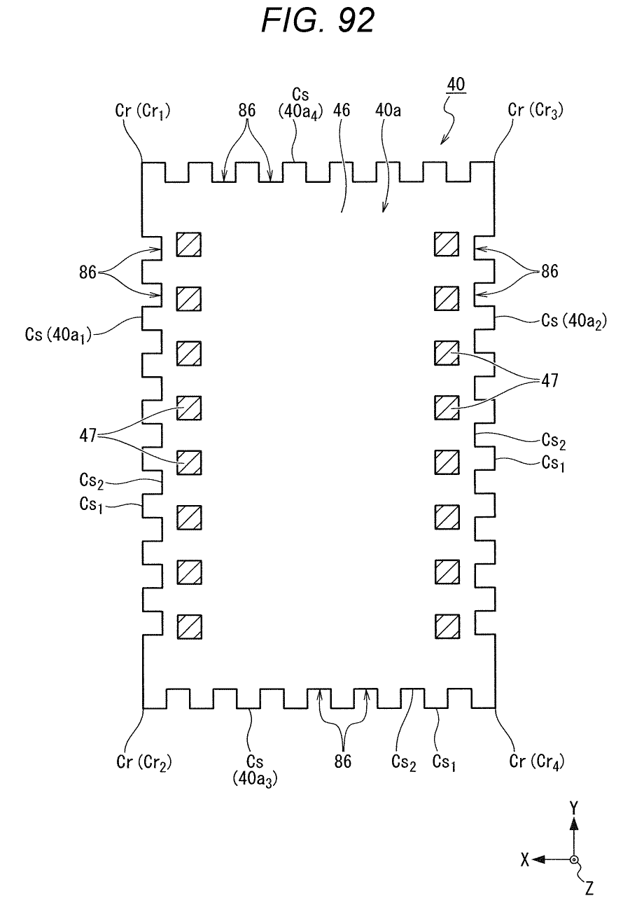

FIG. 92 is a plan view schematically illustrating a bonding surface side of a second semiconductor chip.

Note that FIG. 90 corresponds to FIG. 7 of the above-described first embodiment.

As illustrated in FIGS. 90 to 92, a solid-state imaging device 1I according to the ninth embodiment of the present technology basically has a configuration similar to the solid-state imaging device 1H according to the above-described eighth embodiment, and a configuration of a recess 86 of a second semiconductor chip 40 is different.

That is, as illustrated in FIGS. 90 to 92, the recess 86 of the ninth embodiment extends from a bonding surface 40a to a back surface 42b of the second semiconductor chip 40 and is included in each of the bonding surface 40a and the back surface 42b.

The solid-state imaging device 1I according to the ninth embodiment can also produce effects similar to those produced by the solid-state imaging device 1H according to the above-described eighth embodiment.

### Tenth Embodiment

In a tenth embodiment, a technique of suppressing generation of voids by disposing a weak bonding region having a weak bonding force and a strong bonding region having a strong bonding force on a bonding surface and controlling a bonding wave will be described.

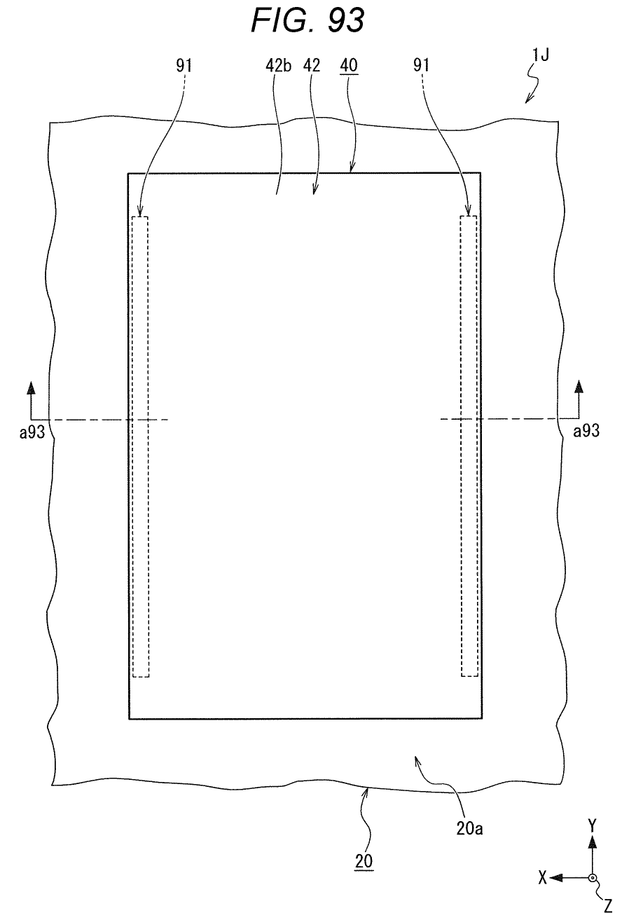

FIG. 93 is a plan view of a main part schematically illustrating a configuration example of a solid-state imaging device according to the tenth embodiment of the present technology.

FIG. 94 is a longitudinal cross-sectional view schematically illustrating a longitudinal cross-sectional structure taken along cutting line a93-a93 in FIG. 93.

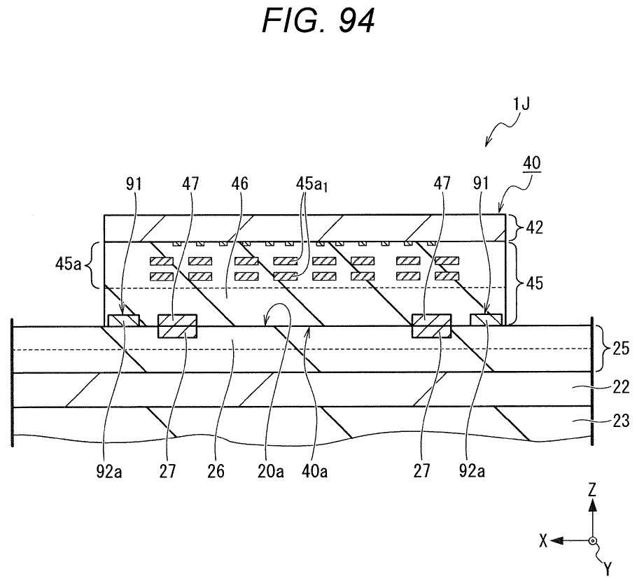

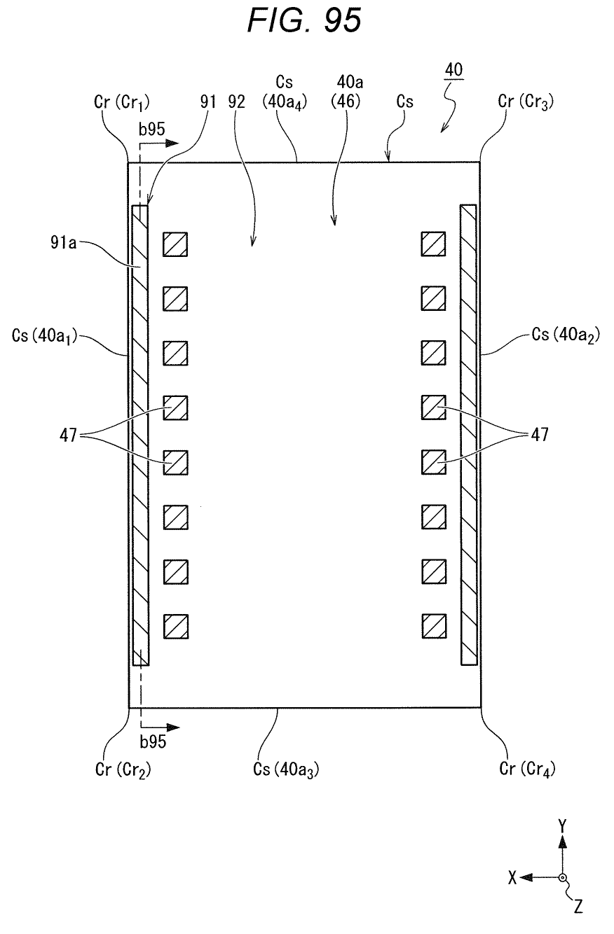

FIG. 95 is a plan view schematically illustrating a bonding surface side of a second semiconductor chip.

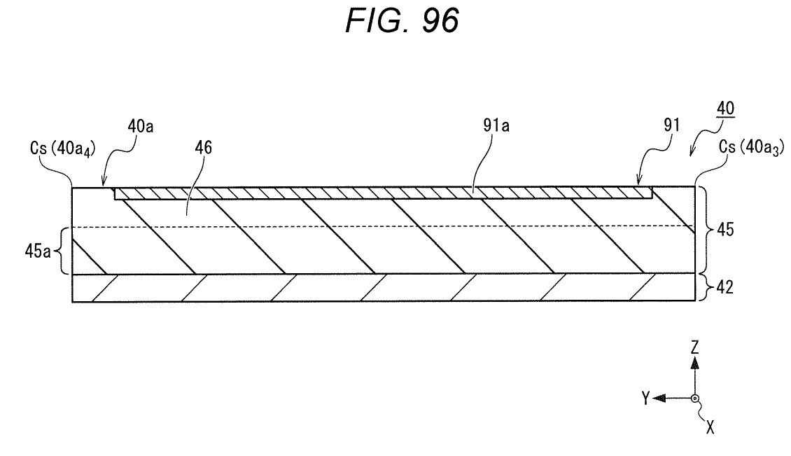

FIG. 96 is a longitudinal cross-sectional view schematically illustrating a longitudinal cross-sectional structure taken along cutting line b95-b95 in FIG. 95.

FIG. 97 is a plan view schematically illustrating a bonding surface side of a first semiconductor chip.

As illustrated in FIGS. 93 to 97, a solid-state imaging device 1J according to the tenth embodiment of the present technology basically has a configuration similar to the solid-state imaging device 1A according to the above-described first embodiment, and a configuration of a second semiconductor chip 40 is different.

That is, at least one of a bonding surface 20a of a first semiconductor chip 20 or a bonding surface 40a of the second semiconductor chip 40 includes a weak bonding region 91 and a strong bonding region 92 having relatively different bonding forces from the other bonding surfaces, and the one weak bonding region 91 is provided in one bonding surface on a peripheral edge portion side. In the tenth embodiment, as illustrated in FIGS. 93 to 97, the bonding surface 40 of the second semiconductor chip 40 includes the weak bonding region 91 and the strong bonding region 92.

Then, as illustrated in FIG. 95, the weak bonding regions 91 are arranged on two long sides (40a₁ and 40a₂) located on opposite sides to each other in an X direction among four sides (40a₁, 40a₂, 40a₃, and 40a₄) of the bonding surface 40a of the second semiconductor chip 40, and extends along the respective long sides (40a₁ and 40a₂).

Note that FIG. 95 illustrates an example in which the weak bonding region 91 is not in contact with a peripheral edge portion Cs in plan view, but the present embodiment is not limited thereto. For example, the weak bonding region 91 may be in contact with the peripheral edge portion Cs in plan view.

Then, the weak bonding region 91 includes a continuously extending solid conductive film 91a. The conductive film 91a is configured by a metal material such as Cu, W, Al, or Ru, and has a bonding surface (surface) having hydrophobicity. The conductive film 91a whose bonding surface has hydrophobicity has a weaker bonding force with the bonding surface 20a of the first semiconductor chip 20 than an insulating layer 46 of a multilayer wiring layer 45. The strong bonding region 92 includes the insulating layer 46 and a bonding metal pad 47. That is, the weak bonding region 91 has a weaker bonding force with the bonding surface of the first semiconductor chip 20 than the strong bonding region 92.

As described above, the bonding surface 40a of the second semiconductor chip 40 includes the weak bonding region 91 and the strong bonding region 92 having relatively different bonding forces with the bonding surface 20a of the first semiconductor chip 20, and the weak bonding region 91 is disposed in the bonding surface 40a of the first semiconductor chip 40 on the sides of the sides (42a₁ and 42a₂), so that it is possible to delay arrival of the bonding wave to the peripheral edge portion Cs (the side 42a₁ and the side 42a₂) of the bonding surface 40a. Furthermore, the weak bonding region 91 extends along the sides (40a₁ and 40a₂) of the bonding surface 40a. Therefore, a traveling speed of the bonding wave traveling along the side of the bonding surface 40a can be reduced. As a result, in a manufacturing process, it is possible to suppress voids generated at the corner portions Cr of the second semiconductor chip 40 due to an arrival time difference between the bonding wave traveling along the sides (40a₁ and 40a₂) of the bonding surface 40 and a radially expanding bonding wave.

Therefore, the solid-state imaging device 1J according to the tenth embodiment can improve a manufacturing yield.

### Modification of Tenth Embodiment

### Modification 10-1

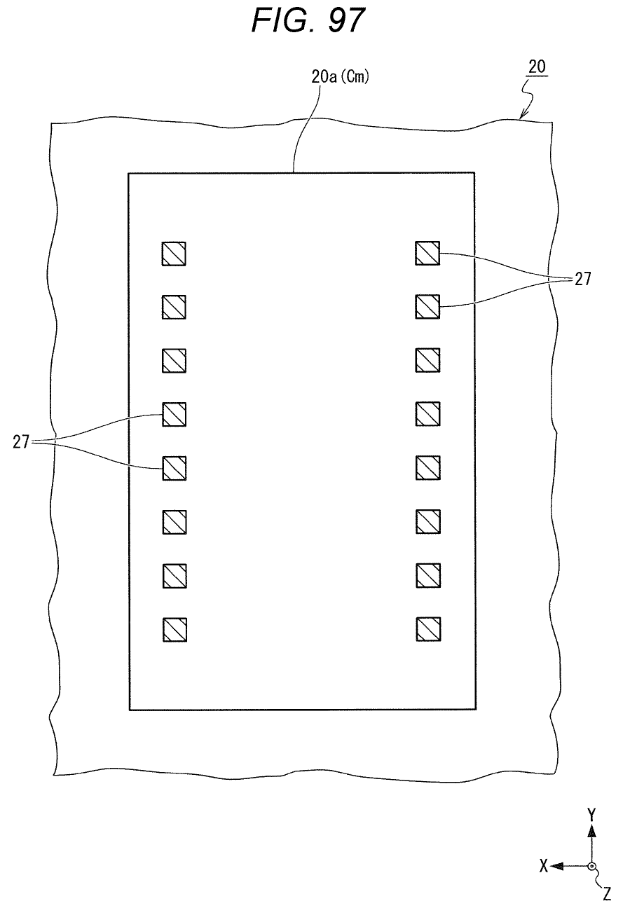

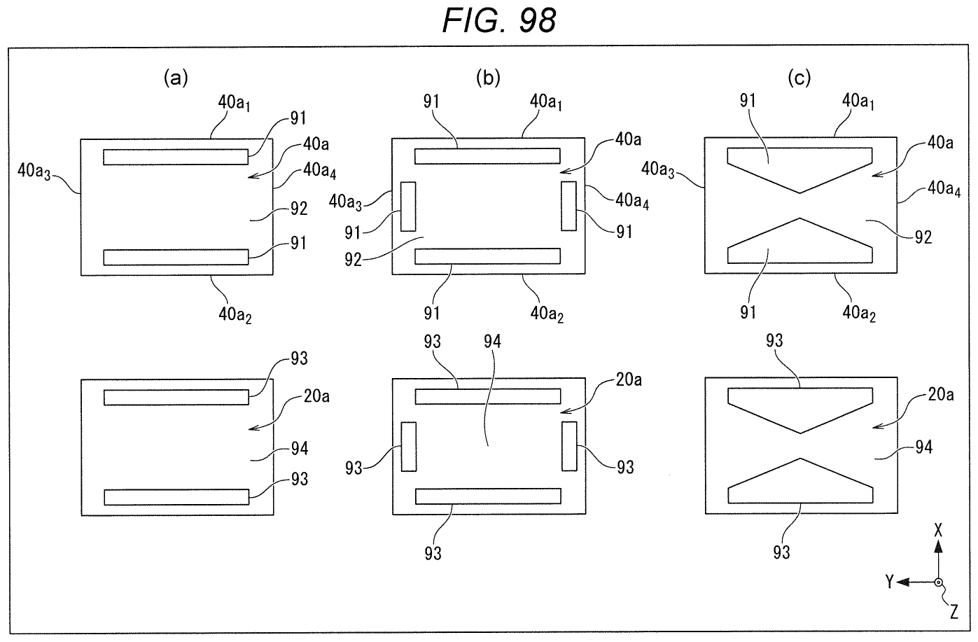

FIG. 98 is diagrams illustrating types of arrangement patterns in which weak bonding regions 91 and 93 are arranged on the respective bonding surfaces 20a and 40a of the first semiconductor chip 20 and the second semiconductor chip 40. In Modification 10-1, the bonding surface 20a of the first semiconductor chip 20 includes a weak bonding region 93 and a strong bonding region 94 having relatively different bonding forces with the bonding surface 40a of the second semiconductor chip 40. Furthermore, the bonding surface 40a of the second semiconductor chip 40 includes the weak bonding region 91 and the strong bonding region 92 having relatively different bonding forces with the bonding surface 20a of the first semiconductor chip 20.

FIG. 98(a) illustrates an example in which, in the first semiconductor chip 20 and the second semiconductor chip 40, the weak bonding regions 91 and 93 are respectively arranged in the bonding surfaces 20a and 40a on the sides of the two long sides.

FIG. 98(b) illustrates an example in which, in the first semiconductor chip 20 and the second semiconductor chip 40, the weak bonding regions 91 and 93 are respectively arranged on the sides of the two long sides and the two short sides of the bonding surfaces 20a and 40a, respectively.

FIG. 98(c) illustrates an example in which, in the first semiconductor chip 20 and the second semiconductor chip 40, the weak bonding regions 91 and 93 are respectively arranged in the bonding surfaces 20a and 40a on the sides of the two long sides. The weak bonding regions 91 and 93 in this example are planar patterns having portions where widths along the sides gradually increase from centers toward the sides of the bonding surfaces 20a and 40a.

Also in Modification 10-1 illustrated in FIGS. 98(a), 98(b), and 98(c), similar effects to those of the solid-state imaging device 1J according to the above-described tenth embodiment can be obtained.

### Modification 10-2

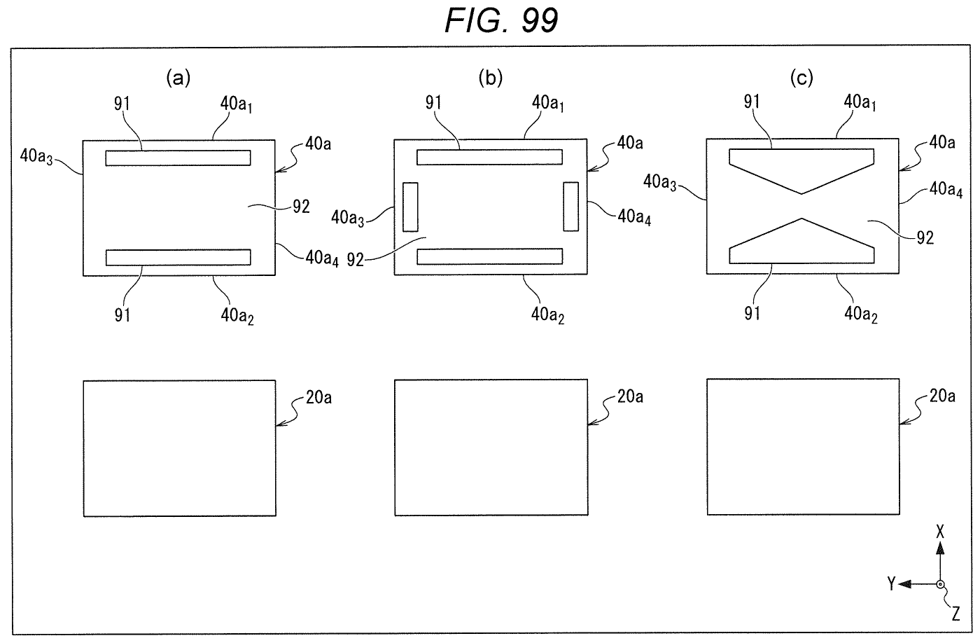

FIG. 99 is diagrams illustrating types of arrangement patterns in which the weak bonding region 91 is arranged on the bonding surface 40a of the second semiconductor chip 40, of the first semiconductor chip 20 and the second semiconductor chip 40.

The arrangement patterns of the weak bonding region 91 in FIGS. 99(a), 99(b), and 99(c) are similar to those in FIGS. 98(a), 98(b), and 98(c) described above.

Also in Modification 10-2 illustrated in FIGS. 99(a), 99(b), and 99(c), similar effects to those of the solid-state imaging device 1J according to the above-described tenth embodiment can be obtained.

### Modification 10-3

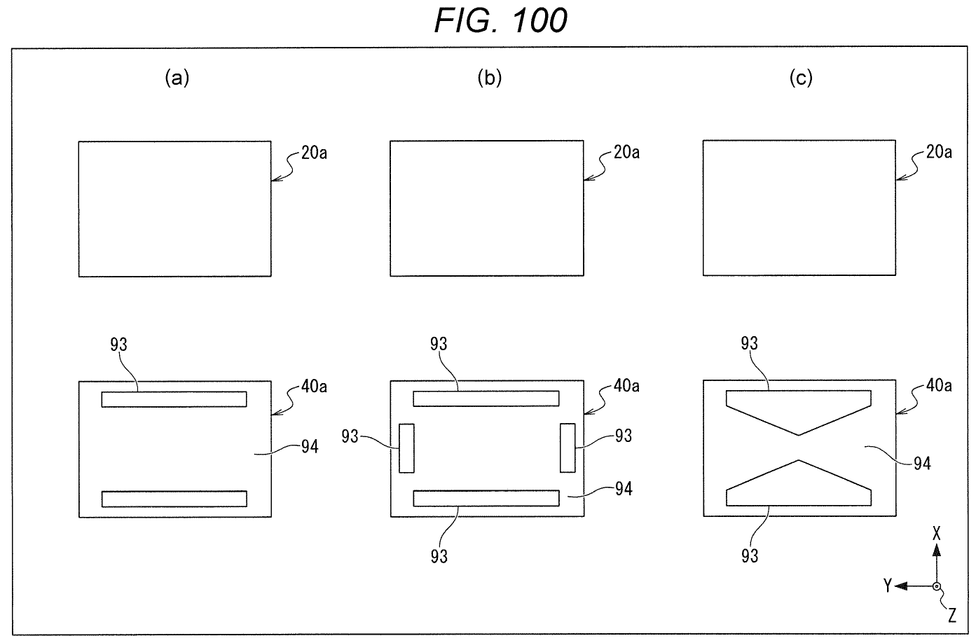

FIG. 100 is diagrams illustrating types of arrangement patterns in which the weak bonding region 93 is arranged on the bonding surface 20a of the first semiconductor chip 20, of the first semiconductor chip 20 and the second semiconductor chip 40.

The arrangement patterns of the weak bonding region 93 in FIGS. 100(a), 100(b), and 100(c) are similar to those in FIGS. 98(a), 98(b), and 98(c) described above.

Also in Modification 10-3 illustrated in FIGS. 100(a), 100(b), and 100(c), similar effects to those of the solid-state imaging device 1J according to the above-described tenth embodiment can be obtained.

### Modification 10-4

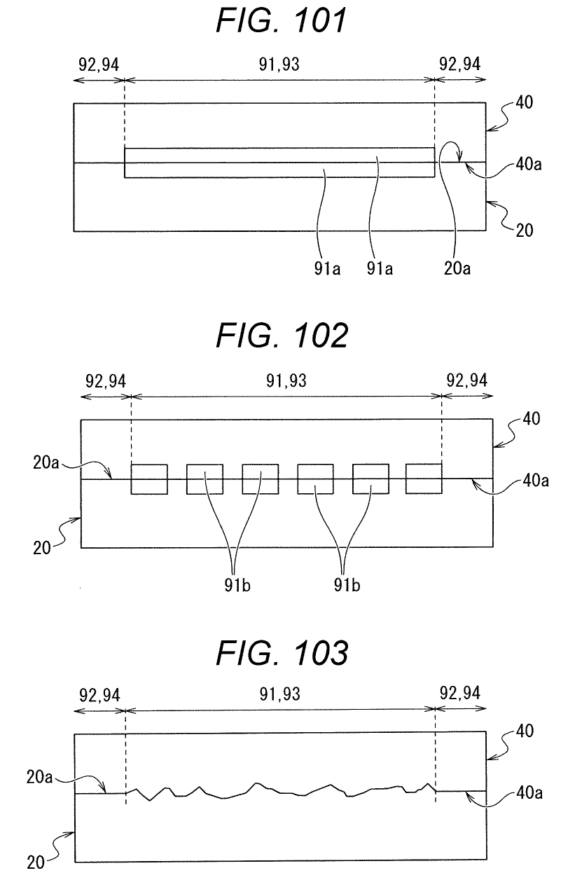

In Modification 10-4 illustrated in FIG. 101, similarly to the above-described tenth embodiment, the weak bonding regions 91 and 93 of both the first semiconductor chip 20 and the second semiconductor chip 40 are configured by solid conductive films 91a. Also in this Modification 10-4, effects similar to those of the solid-state imaging device 1J according to the above-described tenth embodiment can be obtained.

### Modification 10-5

In Modification 10-5 illustrated in FIG. 102, the weak bonding regions 91 and 93 of both the first semiconductor chip 20 and the second semiconductor chip 40 include a plurality of conductive films 91b repeatedly arranged at predetermined intervals in an extending direction of the sides of the bonding surfaces 20a and 40a. Also in this Modification 10-5, effects similar to those of the solid-state imaging device 1J according to the above-described tenth embodiment can be obtained.

### Modification 10-6

In Modification 10-6 illustrated in FIG. 103, surface roughness of the weak bonding regions 91 and 93 of both the first semiconductor chip 20 and the second semiconductor chip 40 is made rougher than surface roughness of the strong bonding regions 92 and 93. In Modification 10-6, the entire surface roughness of each of the weak bonding regions 91 and 93 is made rougher than that of the strong bonding regions 92 and 94. The bonding forces of the bonding surfaces 20a and 40a depend on the surface roughness, and the bonding force of the rougher bonding surface is smaller. Also in this Modification 10-5, effects similar to those of the solid-state imaging device 1J according to the above-described tenth embodiment can be obtained.

### Modification 10-7

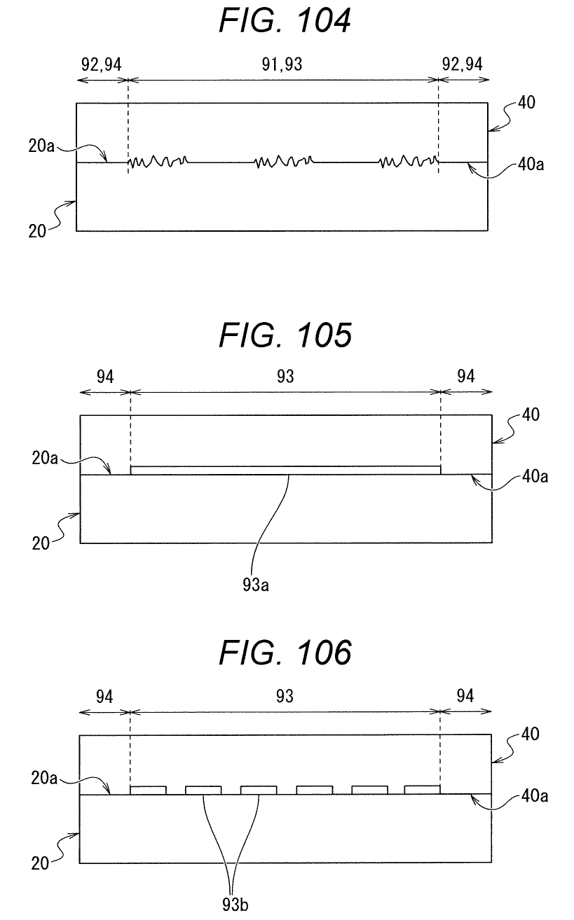

In Modification 10-7 illustrated in FIG. 104, the surface roughness of the weak bonding regions 91 and 93 of both the first semiconductor chip 20 and the second semiconductor chip 40 is made rougher than the surface roughness of the strong bonding regions 92 and 93. In Modification 10-7, part of the surface roughness of each of the weak bonding regions 91 and 93 is made rougher than that of the strong bonding regions 92 and 94.

### Modification 10-8

In Modification 10-8 illustrated in FIG. 105, a recess 93a extending along the extending direction of a side is provided in the bonding surface 20a of the first semiconductor chip 20, of the first semiconductor chip 20 and the second semiconductor chip 40, to configure the weak bonding region 93 in the bonding surface 20a of the first semiconductor chip 20. Also in this Modification 10-7, effects similar to those of the solid-state imaging device 1J according to the above-described tenth embodiment can be obtained.

Note that, in Modification 10-8, the recess 93a is provided in the bonding surface 20a of the first semiconductor chip 20, but the recess 93a may be provided in the bonding surface 40a of the second semiconductor chip 40 to form the weak bonding region in the second semiconductor chip 40. Furthermore, the recess 93a may be formed in each of the bonding surfaces 20a and 40a of the first semiconductor chip 20 and the second semiconductor chip 40 to form the weak bonding region in each of the bonding surfaces 20a and 40.

### Modification 10-9

In Modification 10-9 illustrated in FIG. 106, a recess 93b extending along the extending direction of the side of the bonding surface is repeatedly arranged at predetermined intervals in the bonding surface 20a of the first semiconductor chip 20, of the first semiconductor chip 20 and the second semiconductor chip 40, to configure the weak bonding region in the bonding surface 20a of the first semiconductor chip 20. Also in Modification 10-8, effects similar to those of the solid-state imaging device 1J according to the above-described tenth embodiment can be obtained.

Note that, in Modification 10-9, the recess 93b is provided in the bonding surface 20a of the first semiconductor chip 20, but the recess 93b may be provided in the bonding surface 40a of the second semiconductor chip 40 to form the weak bonding region in the second semiconductor chip 40. Furthermore, the recess 93b may be formed in each of the bonding surfaces 20a and 40a of the first semiconductor chip 20 and the second semiconductor chip 40 to form the weak bonding region in each of the bonding surfaces 20a and 40.

### Modification 10-10

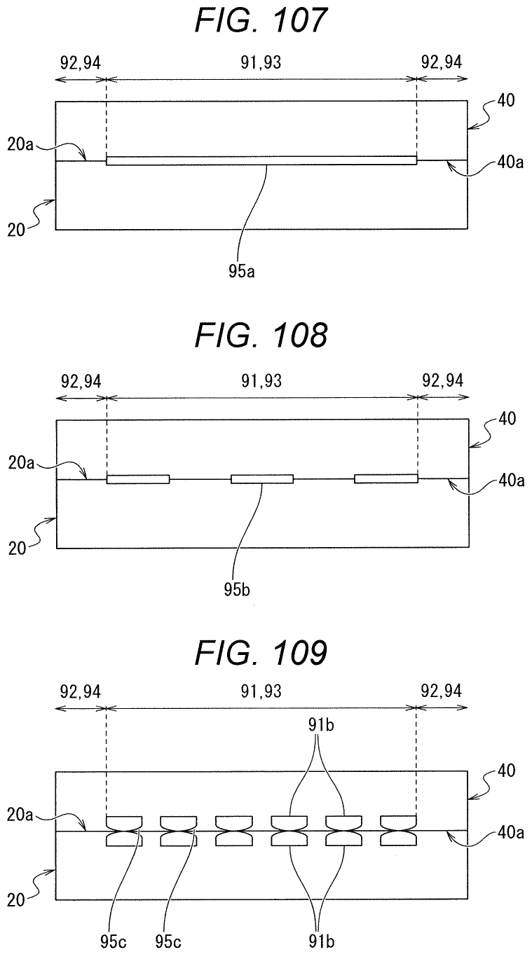

In Modification 10-10 illustrated in FIG. 107, the respective bonding surfaces 20a and 20b of the first semiconductor chip 20 and the second semiconductor chip 40 are made hydrophobic, and the weak bonding regions 91 and 93 are formed in the respective bonding surfaces 20a and 40a in a hydrophobic region 95a extending along the extending direction of the sides. Also in this Modification 10-10, effects similar to those of the solid-state imaging device 1J according to the above-described tenth embodiment can be obtained.

Note that the hydrophobic weak bonding region may be formed in any one of the bonding surfaces 20a and 40a of the first semiconductor chip 20 and the second semiconductor chip 40.

### Modification 10-11

In Modification 10-9 illustrated in FIG. 108, the respective bonding surfaces 20a and 20b of the first semiconductor chip 20 and the second semiconductor chip 40 are made hydrophobic, and the weak bonding regions 91 and 93 are formed in the respective bonding surfaces 20a and 40a in the hydrophobic regions 95b interspersed along the extending direction of the sides. Also in this Modification 10-11, effects similar to those of the solid-state imaging device 1J according to the above-described tenth embodiment can be obtained.

Note that the hydrophobic weak bonding region may be formed in any one of the bonding surfaces 20a and 40a of the first semiconductor chip 20 and the second semiconductor chip 40.

### Modification 10-12

In Modification 10-12 illustrated in FIG. 109, a vacant space is provided between the conductive film 91b on the first semiconductor chip 20 side and the conductive film 91b on the second semiconductor chip 40 side in Modification 10-5 described above. Also in this Modification 10-10, effects similar to those of the solid-state imaging device 1J according to the above-described tenth embodiment can be obtained.

### Modification 10-13

In Modification 10-13 illustrated in FIG. 110, the weak bonding regions 91 and 93 and the strong bonding regions 92 and 94 are configured by changing density of island-shaped conductive films 91b in the bonding surfaces 20a and 20b of the first semiconductor chip 20 and the second semiconductor chip 40. Also in this Modification 10-13, effects similar to those of the solid-state imaging device 1J according to the above-described tenth embodiment can be obtained.

### Modification 10-14

In Modification 10-14 illustrated in FIG. 111, Modification 10-5 illustrated in FIG. 102 and Modification 10-7 illustrated in FIG. 104 are combined to form the weak bonding region and the strong bonding region in each of the respective bonding surfaces 20a and 20b of the first semiconductor chip 20 and the second semiconductor chip 40. Also in this Modification 10-13, effects similar to those of the solid-state imaging device 1J according to the above-described tenth embodiment can be obtained.

### Modification 10-15

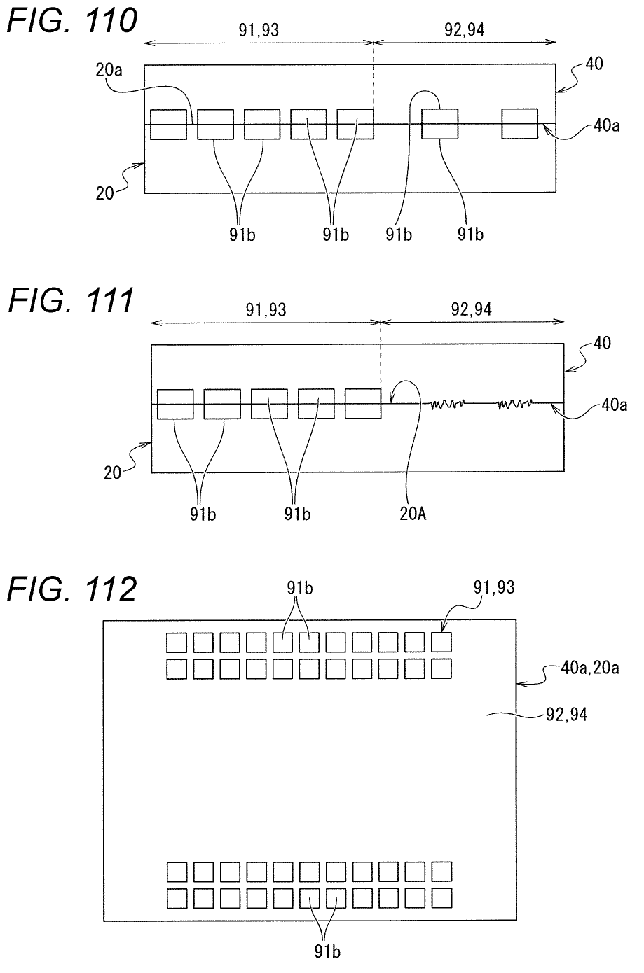

In Modification 10-15 illustrated in FIG. 112, island-shaped conductive films 91b are arranged in two lines to form the weak bonding regions 91 and 93. Also in this Modification 10-15, effects similar to those of the solid-state imaging device 1J according to the above-described tenth embodiment can be obtained.

### Modification 10-16

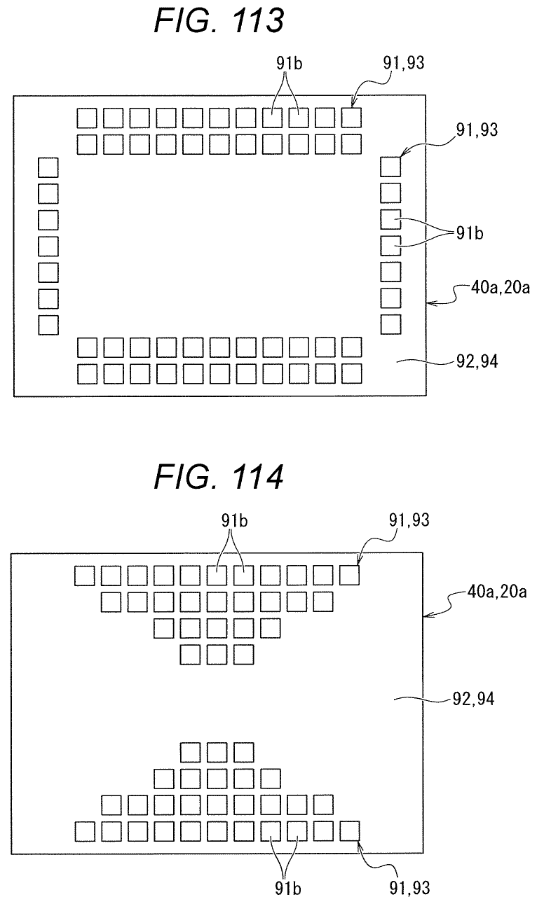

In Modification 10-16 illustrated in FIG. 113, the numbers of lines of the island-shaped conductive films 91b are changed on the long side and the short side. Also in this Modification 10-16, effects similar to those of the solid-state imaging device 1J according to the above-described tenth embodiment can be obtained.

### Modification 10-17

In Modification 10-17 illustrated in FIG. 114, the weak bonding regions in FIG. 98(c) are configured by arranging the island-shaped conductive films in a plurality of lines. Also in this Modification 10-17, effects similar to those of the solid-state imaging device 1J according to the above-described tenth embodiment can be obtained.

### Eleventh Embodiment

### «Application Example to Electronic Devices»

The present technology (technology of the present disclosure) can be applied to various electronic devices including an imaging device such as a digital still camera or a digital video camera, a mobile phone having an imaging function, or other devices having an imaging function, for example.

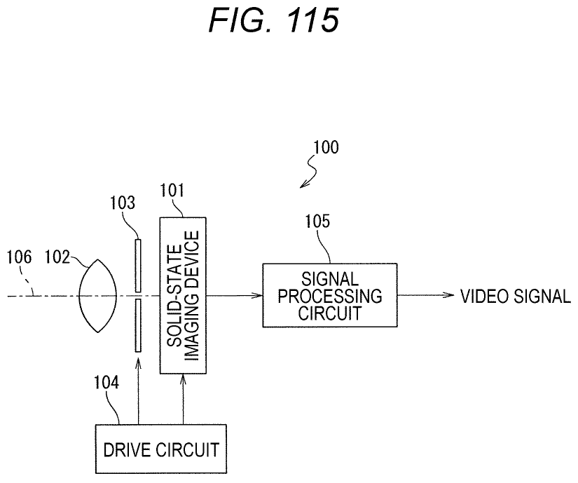

FIG. 115 is a diagram illustrating a schematic configuration of an electronic device (for example, a camera) according to a second embodiment of the present technology.

As illustrated in FIG. 115, an electronic device 100 includes a solid-state imaging device 101, an optical lens 102, a shutter device 103, a drive circuit 104, and a signal processing circuit 105. The electronic device 100 is an embodiment in a case where the solid-state imaging device 1A according to the first embodiment of the present technology is used for an electronic device (e.g., a camera) as the solid-state imaging device 101.

The optical lens 102 forms an image of image light (incident light 106) from a subject on an imaging surface of the solid-state imaging device 101. As a result, signal charges are accumulated in the solid-state imaging device 101 over a certain period. The shutter device 103 controls a light irradiation period and a light shielding period for the solid-state imaging device 101. The drive circuit 104 supplies a drive signal for controlling a transfer operation of the solid-state imaging device 101 and a shutter operation of the shutter device 103. A signal of the solid-state imaging device 101 is transferred by the drive signal (timing signal) supplied from the drive circuit 104. The signal processing circuit 105 performs various types of signal processing for a signal (pixel signal) output from the solid-state imaging device 101. A video signal for which the signal processing has been performed is stored into a storage medium such as a memory, or is output to a monitor.

With such a configuration, in the electronic device 100 according to the second embodiment, a manufacturing yield is improved in the solid-state imaging device 101, and thus a cost can be reduced.

Note that the electronic device 100 to which the solid-state imaging device of each of the embodiments described above can be applied is not limited to a camera, and the solid-state imaging device can also be applied to other electronic devices. For example, the solid-state imaging device may be applied to an imaging device such as a camera module for a mobile device such as a mobile phone or a tablet terminal.

Furthermore, the present technology can be applied to any photodetection device including not only the above-described solid-state imaging device as the image sensor but also a ranging sensor that is also called time of flight (ToF) sensor and measures a distance, and the like. The ranging sensor is a sensor that emits irradiation light toward an object, detects reflected light that is the irradiation light reflected from a surface of the object, and calculates a distance to the object on the basis of a flight time from the emission of the irradiation light to reception of the reflected light. The above-described structure of the second semiconductor chip can be adopted as the structure of the second semiconductor chip of the ranging sensor.

### Other Embodiments

In the above-described embodiment, an example in which the present technology is applied to the solid-state imaging device 1A referred to as a back-illuminated complementary metal oxide semiconductor (CMOS) image sensor has been described. However, the present technology can also be applied to a front-illuminated image sensor and other semiconductor devices.

Furthermore, in the above-described first embodiment, the case where the bonding surface 20a of the second semiconductor chip 40 is bonded to the bonding surface 20a of the wafer stacked body 60 in the process of manufacturing the solid-state imaging device 1A has been described. However, the present technology is not limited to the above-described first embodiment. For example, in the process of manufacturing the solid-state imaging device 1A, the present technology can also be applied to a case where the bonding surface 40a of the second semiconductor chip 40 is bonded to the bonding surface 20a of the divided first semiconductor chip 20 by surface activation bonding.

Furthermore, in the above-described first embodiment, the case of using the first semiconductor chip 20 provided with the two semiconductor layers 22 and 32 has been described, but the present technology can also be applied to a case of using a first semiconductor chip provided with a single semiconductor layer.

Furthermore, in the above-described first embodiment, the case where the two second semiconductor chips 40 are bonded has been described, but the present technology can also be applied to a case where one or three or more second semiconductor chips 40 are bonded. Furthermore, the present technology can also be applied to a case where second semiconductor chips having different planar sizes are bonded.

Note that the present technology may also have the following configurations.

(1)

A semiconductor device including: a base member having a first bonding surface; and a semiconductor chip having a second bonding surface having a quadrangular shape, in which
the second bonding surface of the semiconductor chip and the first bonding surface of the base member are bonded by direct bonding,
the semiconductor chip includes a multilayer wiring layer including the second bonding surface, and a semiconductor layer provided on an opposite side to a side of the second bonding surface of the multilayer wiring layer, and
the multilayer wiring layer includes a warp suppression film that extends along at least one side of the second bonding surface and suppresses warp of the semiconductor chip.
   (2)

The semiconductor device according to (2) above, in which the warp suppression film suppresses warp in which the side of the second bonding surface of the semiconductor chip has a convex surface.

(3)

The semiconductor device according to (2) or (2) above, in which the warp suppression film is thicker than wiring of the multilayer wiring layer.

(4)

The semiconductor device according to any one of (1) to (3) above, in which the warp suppression film is individually provided on each of two side sides located on opposite sides of the second bonding surface.

(5)

The semiconductor device according to any one of (1) to (3) above, in which the warp suppression film is provided on four side sides of the second bonding surface.

(6)

The semiconductor device according to any one of (1) to (5) above, in which the warp suppression film is configured by any of a silicon nitride film, a metal film, an alloy film, or a resin film.

(7)

The semiconductor device according to any one of (1) to (6) above, in which
the first bonding surface includes a first insulating layer included in the multilayer wiring layer and first bonding metal pads interspersed with the first insulating layer,
the second bonding surface includes a second insulating layer and second bonding metal pads interspersed with the second insulating layer, and
the first bonding metal pad and the second bonding metal pad are bonded by direct bonding.
   (8)

The semiconductor device according to (7) above, in which the warp suppression film is disposed outside the second metal pad in plan view.

(9)

The semiconductor device according to any one of (1) to (8) above, in which the base member includes the semiconductor layer provided with a photoelectric conversion unit.

(10)

The semiconductor device according to any one of (1) to (9) above, in which
the base member is a first semiconductor chip,
the semiconductor chip is a second semiconductor chip, and
the first semiconductor chip is larger in planar size than the second semiconductor chip.
   (11)

A semiconductor device including:
a base member having a first bonding surface; and
a semiconductor chip having a second bonding surface having a quadrangular shape, the second bonding surface being directly bonded to the first bonding surface of the base member, in which
the semiconductor chip includes
a multilayer wiring layer including the second bonding surface,
a semiconductor layer provided on an opposite side to a side of the second bonding surface of the multilayer wiring layer, and
a warp suppression portion that is provided in the multilayer wiring layer and suppresses warp of the semiconductor chip, and
the warp suppression portion is selectively provided on a peripheral edge portion side of the second bonding surface in plan view.
   (12)

The semiconductor device according to (11) above, in which the warp suppression portion extends along two sides including at least a corner portion of the second bonding surface in plan view.

(13)

The semiconductor device according to (12) above, in which, in the warp suppression portion, a first width connecting a side of the corner portion and an inner side of a first portion adjacent to the corner portion of the second bonding surface in plan view is wider than a second width connecting a side of the side and an inner side of a second portion adjacent to the side of the second bonding surface in plan view.

(14)

A photodetection device according to (11) or (12) above, in which the warp suppression portion is selectively provided on a corner portion side of the second bonding surface in plan view.

(15)

A photodetection device according to any one of (11) to (14) above, in which the warp suppression portion is exposed from a side surface of the multilayer wiring layer.

(16)

The semiconductor device according to any one of (11) to (14) above, in which the warp suppression film is provided over the second bonding surface and a side surface of the multilayer wiring layer.

(17)

The semiconductor device according to any one of (11) to (15) above, in which the warp suppression portion is provided in at least one of an inner layer of the multilayer wiring layer or the second bonding surface.

(18)

The semiconductor device according to (11) above, in which the warp suppression portion is provided in the second bonding surface of the multilayer wiring layer and is directly bonded to the first bonding surface of the base member.

(19)

The semiconductor device according to any one of (11) to (18) above, in which
the first bonding surface includes a first insulating layer included in the wiring layer and first bonding metal pads interspersed with the first insulating layer,
the second bonding surface includes a second insulating layer and second bonding metal pads interspersed with the second insulating layer, and
the first bonding metal pad and the second bonding metal pad are bonded by direct bonding.
   (20)

The semiconductor device according to (19) above, in which the warp suppression portion is disposed outside the second metal pad in plan view.

(21)

The semiconductor device according to any one of (11) to (20) above, in which the base member includes the semiconductor layer provided with a photoelectric conversion unit.

(22)

A semiconductor device including:
a base member having a first bonding surface; and
a semiconductor chip having a second bonding surface having a quadrangular shape, the second bonding surface being directly bonded to the first bonding surface of the base member, in which
the semiconductor chip includes
a multilayer wiring layer including the second bonding surface,
a semiconductor layer provided on an opposite side to a side of the second bonding surface of the multilayer wiring layer, and having, on an opposite side to a side of the multilayer wiring layer, a back surface having a quadrangular shape, and
a warp suppression portion that is provided in the semiconductor layer and suppresses warp of the semiconductor chip, and
the warp suppression portion is selectively provided on a peripheral edge portion side of the back surface of the semiconductor layer in plan view.
   (23)

The semiconductor device according to (22) above, in which the warp suppression portion is a modified layer with disturbed crystallinity.

(24)

The semiconductor device according to any one of (22) to (25) above, in which the modified layer extends inward from the peripheral edge portion side of the back surface of the semiconductor layer in plan view.

(25)

The semiconductor device according to (22) above, in which
the back surface of the semiconductor layer includes a first portion having a first thickness and a second portion having a second thickness thicker than the first thickness, and
the warp suppression portion is the second portion.
   (26)

The semiconductor device according to (27) above, in which the second portion extends inward from the peripheral edge portion side of the back surface of the semiconductor layer in plan view.

(27)

A semiconductor device including:
a base member having a first bonding surface; and
a semiconductor chip having a second bonding surface having a quadrangular shape, the second bonding surface being directly bonded to the first bonding surface of the base member, in which
the semiconductor chip includes
a multilayer wiring layer including the second bonding surface, and
a semiconductor layer provided on an opposite side to a side of the second bonding surface of the multilayer wiring layer,
the second bonding surface includes an insulating layer included in the multilayer wiring layer and a weak bonding portion having weaker bonding force with the first bonding surface than the insulating layer, and
the weak bonding portion is provided on a peripheral edge portion side of the second bonding surface.
   (28)

The semiconductor device according to (27) above, in which the weak bonding portion extends along a side of the second bonding surface.

(29)

The semiconductor device according to (27) above, in which the weak bonding portions are interspersed along a side of the second bonding surface.

(30)

The semiconductor device according to any one of (27) to (29) above, in which the weak bonding portion includes a porous film.

(31)

A semiconductor device including:
a base member having a first bonding surface; and
a semiconductor chip having a second bonding surface having a quadrangular shape, the second bonding surface being directly bonded to the first bonding surface of the base member, in which
a peripheral edge portion of the second bonding surface meanders.
   (32)

The semiconductor device according to (31) above, in which the peripheral edge portion of the second bonding surface has a planar shape in which a first peripheral edge portion and a second peripheral edge portion located inside the first peripheral edge portion are repeatedly arranged in one direction in plan view.

(33)

The semiconductor device according to any one of (31) or (32) above, in which
the semiconductor chip has a recess extending inward from a side surface of the semiconductor chip, and
a planar shape of the recess is reflected in the peripheral edge portion of the second bonding surface.
   (34)

The semiconductor device according to (33) above, in which the recess is embedded with an insulating material.

(35)

The semiconductor device according to any one of (30) to (33) above, in which
the semiconductor chip has a back surface on an opposite side to the second bonding surface, and
the recess extends from the second bonding surface to a side of the back surface of the semiconductor chip.
   (36)

A semiconductor device including:
a base member having a first bonding surface having a quadrangular shape; and
a semiconductor chip having a second bonding surface having a quadrangular shape, the second bonding surface being directly bonded to the first bonding surface of the base member, in which
at least one bonding surface of the first bonding surface or the second bonding surface includes a weak bonding region and a strong bonding region having bonding forces relatively different from the other bonding surfaces, and the one weak bonding region is provided in the one bonding surface on a peripheral edge portion side.
   (37)

An electronic device including:
a semiconductor device;
an optical lens configured to form an image of image light from a subject on an imaging surface of the semiconductor device; and
a signal processing circuit configured to perform signal processing for a signal output from the semiconductor layer, in which
the semiconductor device includes
a base member having a first bonding surface, and a semiconductor chip having a second bonding surface having a quadrangular shape,
the second bonding surface of the semiconductor chip and the first bonding surface of the base member are bonded by direct bonding,
the semiconductor chip includes a multilayer wiring layer including the second bonding surface, and a semiconductor layer provided on an opposite side to a side of the second bonding surface of the multilayer wiring layer, and
the multilayer wiring layer includes a warp suppression film that extends along at least one side of the second bonding surface and suppresses warp of the semiconductor chip.

The scope of the present technology is not limited to the exemplary embodiments illustrated in the drawings and described above, but includes also all embodiments that produce effects equivalent to the effects that the present technology intends to produce. Moreover, the scope of the present technology is not limited to the combinations of the features of the invention defined by the claims, and may be defined by any desired combination of specific features among all the disclosed features.

### REFERENCE SIGNS LIST

1A Solid-state imaging device
2 Chip stacked body
2A Pixel array unit
2B Peripheral portion
3 Pixel
4 Vertical drive circuit
5 Column signal processing circuit
6 Horizontal drive circuit
7 Output circuit
8 Control circuit
10 Pixel drive line
11 Vertical signal line
13 Logic circuit
14 Bonding pad
15 Pixel circuit (readout circuit)
16 Photoelectric conversion unit
20 First semiconductor chip (base member)
20a Bonding surface (first bonding surface)
21 First substrate unit
22 Semiconductor layer
23 Multilayer wiring layer
24 Bonding metal pad
25 Multilayer wiring layer
26 Insulating layer (first insulating layer)
27 Bonding metal pad (first bonding metal pad)
27f Dummy pad
28 Contact electrode
31 Second substrate unit
32 Semiconductor layer
33 Multilayer wiring layer
34 Bonding metal pad
35 Photoelectric conversion region
36 Optical filter layer
37 Microlens
38 Bonding opening
40 Second semiconductor chip
40a Bonding surface (second bonding surface)
40a₁, 40a₂, 40a₃, 40a₄ Side
42 Semiconductor layer
42b Back surface
45 Multilayer wiring layer
45a Multistage stacked portion
45a₁ Wiring
45b, 45c, 45d, 45e, 45f Warp suppression film
45b₁ First portion
45b₁₁ Opening
45b₁₂ Film portion
45b₂ Second portion
46 Insulating layer (second insulating layer)
47 Bonding metal pad
51 Sealing body
60 Wafer stacked body
61, 62 Semiconductor wafer
64 Scribe line (dicing line)
65 Chip formation region
68 Vacant space
79 Dicing sheet
81 Modified layer
82 Stepped portion
82a Thick portion (second portion)
82b Thin portion (first portion)
85 Weak bonding portion
86 Recess
87 Insulating material
100 Electronic device
101 Solid-state imaging device
102 Optical lens
103 Shutter device
104 Drive circuit
105 Signal processing circuit
106 Incident light
AMP Amplification transistor
FD Charge holding region
FDG Switching transistor
PD Photoelectric conversion element
RST Reset transistor
SEL Selection transistor
TR Transfer transistor
Cm Chip mounting region
Cs, Cv Peripheral edge portion
Cs₁ First peripheral edge portion
Cs₂ Second peripheral edge portion
Cr, Cw Corner portion

1. A semiconductor device comprising: a base member having a first bonding surface; and a semiconductor chip having a second bonding surface having a quadrangular shape, wherein
the second bonding surface of the semiconductor chip and the first bonding surface of the base member are bonded by direct bonding,
the semiconductor chip includes a multilayer wiring layer including the second bonding surface, and a semiconductor layer provided on an opposite side to a side of the second bonding surface of the multilayer wiring layer, and
the multilayer wiring layer includes a warp suppression film that extends along at least one side of the second bonding surface and suppresses warp of the semiconductor chip.

2. The semiconductor device according to claim 1, wherein the warp suppression film suppresses warp in which the side of the second bonding surface of the semiconductor chip has a convex surface.

3. The semiconductor device according to claim 1, wherein the warp suppression film is thicker than wiring of the multilayer wiring layer.

4. The semiconductor device according to claim 1, wherein the warp suppression film is individually provided on each of two side sides located on opposite sides of the second bonding surface.

5. The semiconductor device according to claim 1, wherein the warp suppression film is provided on four side sides of the second bonding surface.

6. The semiconductor device according to claim 1, wherein the warp suppression film is configured by any of a silicon nitride film, a metal film, an alloy film, or a resin film.

7. The semiconductor device according to claim 1, wherein
the first bonding surface includes a first insulating layer included in the wiring layer and first bonding metal pads interspersed with the first insulating layer,
the second bonding surface includes a second insulating layer and second bonding metal pads interspersed with the second insulating layer, and
the first bonding metal pad and the second bonding metal pad are bonded by direct bonding.

8. The semiconductor device according to claim 7, wherein the warp suppression film is disposed outside the second metal pad in plan view.

9. The semiconductor device according to claim 1, wherein the base member includes the semiconductor layer provided with a photoelectric conversion unit.

10. The semiconductor device according to claim 1, wherein
the base member is a first semiconductor chip,
the semiconductor chip is a second semiconductor chip, and
the first semiconductor chip is larger in planar size than the second semiconductor chip.

11. A semiconductor device comprising:
a base member having a first bonding surface; and
a semiconductor chip having a second bonding surface having a quadrangular shape, the second bonding surface being directly bonded to the first bonding surface of the base member, wherein
the semiconductor chip includes
a multilayer wiring layer including the second bonding surface,
a semiconductor layer provided on an opposite side to a side of the second bonding surface of the multilayer wiring layer, and
a warp suppression portion that is provided in the multilayer wiring layer and suppresses warp of the semiconductor chip, and
the warp suppression portion is selectively provided on a peripheral edge portion side of the second bonding surface in plan view.

12. The semiconductor device according to claim 11, wherein the warp suppression portion extends along two sides including at least a corner portion of the second bonding surface in plan view.

13. The semiconductor device according to claim 12, wherein, in the warp suppression portion, a first width connecting a side of the corner portion and an inner side of a first portion adjacent to the corner portion of the second bonding surface in plan view is wider than a second width connecting a side of the side and an inner side of a second portion adjacent to the side of the second bonding surface in plan view.

14. A photodetection device according to claim 11, wherein the warp suppression portion is selectively provided on a corner portion side of the second bonding surface in plan view.

15. A photodetection device according to claim 11, wherein the warp suppression portion is exposed from a side surface of the multilayer wiring layer.

16. The semiconductor device according to claim 11, wherein the warp suppression film is provided over the second bonding surface and a side surface of the multilayer wiring layer.

17. The semiconductor device according to claim 11, wherein the warp suppression portion is provided in at least one of an inner layer of the multilayer wiring layer or the second bonding surface.

18. The semiconductor device according to claim 11, wherein the warp suppression portion is provided in the second bonding surface of the multilayer wiring layer and is directly bonded to the first bonding surface of the base member.

19. The semiconductor device according to claim 11, wherein
the first bonding surface includes a first insulating layer included in the wiring layer and first bonding metal pads interspersed with the first insulating layer,
the second bonding surface includes a second insulating layer and second bonding metal pads interspersed with the second insulating layer, and
the first bonding metal pad and the second bonding metal pad are bonded by direct bonding.

20. The semiconductor device according to claim 19, wherein the warp suppression portion is disposed outside the second metal pad in plan view.

21. The semiconductor device according to claim 11, wherein the base member includes the semiconductor layer provided with a photoelectric conversion unit.

22. A semiconductor device comprising:
a base member having a first bonding surface; and
a semiconductor chip having a second bonding surface having a quadrangular shape, the second bonding surface being directly bonded to the first bonding surface of the base member, wherein
the semiconductor chip includes
a multilayer wiring layer including the second bonding surface,
a semiconductor layer provided on an opposite side to a side of the second bonding surface of the multilayer wiring layer, and having, on an opposite side to a side of the multilayer wiring layer, a back surface having a quadrangular shape, and
a warp suppression portion that is provided in the semiconductor layer and suppresses warp of the semiconductor chip, and
the warp suppression portion is selectively provided on a peripheral edge portion side of the back surface of the semiconductor layer in plan view.

23. The semiconductor device according to claim 22, wherein the warp suppression portion is a modified layer with disturbed crystallinity.

24. The semiconductor device according to claim 22, wherein the modified layer has a lower density than the semiconductor layer.

25. The semiconductor device according to claim 22, wherein
the back surface of the semiconductor layer includes a first portion having a first thickness and a second portion having a second thickness thicker than the first thickness, and
the warp suppression portion is the second portion.

26. The semiconductor device according to claim 25, wherein the second portion extends inward from the peripheral edge portion side of the back surface of the semiconductor layer in plan view.

27. A semiconductor device comprising:
a base member having a first bonding surface; and
a semiconductor chip having a second bonding surface having a quadrangular shape, the second bonding surface being directly bonded to the first bonding surface of the base member, wherein
the semiconductor chip includes
a multilayer wiring layer including the second bonding surface, and
a semiconductor layer provided on an opposite side to a side of the second bonding surface of the multilayer wiring layer,
the second bonding surface includes an insulating layer included in the multilayer wiring layer and a weak bonding portion having weaker bonding force with the first bonding surface than the insulating layer, and
the weak bonding portion is provided on a peripheral edge portion side of the second bonding surface.

28. The semiconductor device according to claim 27, wherein the weak bonding portion extends along a side of the second bonding surface.

29. The semiconductor device according to claim 27, wherein the weak bonding portions are interspersed along a side of the second bonding surface.

30. The semiconductor device according to claim 27, wherein the weak bonding portion includes a porous film.

31. A semiconductor device comprising:
a base member having a first bonding surface; and
a semiconductor chip having a second bonding surface having a quadrangular shape, the second bonding surface being directly bonded to the first bonding surface of the base member, wherein
a peripheral edge portion of the second bonding surface meanders.

32. The semiconductor device according to claim 31, wherein the peripheral edge portion of the second bonding surface has a meandering shape in which a first peripheral edge portion and a second peripheral edge portion located inside the first peripheral edge portion are repeatedly arranged in one direction in plan view.

33. The semiconductor device according to claim 31, wherein
the semiconductor chip has a recess extending inward from a side surface of the semiconductor chip, and
a planar shape of the recess is reflected in the peripheral edge portion of the second bonding surface.

34. The semiconductor device according to claim 33, wherein the recess is embedded with an insulating material.

35. The semiconductor device according to claim 31, wherein
the semiconductor chip has a back surface on an opposite side to the second bonding surface, and
the recess extends from the second bonding surface to a side of the back surface of the semiconductor chip.

36. A semiconductor device comprising:
a base member having a first bonding surface having a quadrangular shape; and
a semiconductor chip having a second bonding surface having a quadrangular shape, the second bonding surface being directly bonded to the first bonding surface of the base member, wherein
at least one bonding surface of the first bonding surface or the second bonding surface includes a weak bonding region and a strong bonding region having bonding forces relatively different from the other bonding surfaces, and the one weak bonding region is provided in the one bonding surface on a peripheral edge portion side.

37. An electronic device comprising:
a semiconductor device;
an optical lens configured to form an image of image light from a subject on an imaging surface of the semiconductor device; and
a signal processing circuit configured to perform signal processing for a signal output from the semiconductor layer, wherein
the semiconductor device includes
a base member having a first bonding surface, and a semiconductor chip having a second bonding surface having a quadrangular shape,
the second bonding surface of the semiconductor chip and the first bonding surface of the base member are bonded by direct bonding,
the semiconductor chip includes a multilayer wiring layer including the second bonding surface, and a semiconductor layer provided on an opposite side to a side of the second bonding surface of the multilayer wiring layer, and
the multilayer wiring layer includes a warp suppression film that extends along at least one side of the second bonding surface and suppresses warp of the semiconductor chip.
